(19) United States
(12) Patent Application Publication
(10) Pub. No.: US 2025/0380461 A1
(43) Pub. Date: Dec. 11, 2025

(54) MEMORY DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Hitoshi KUNITAKE, Machida (JP); Masashi OOTA, Isehara (JP); Satoru SAITO, Yamato (JP)

(21) Appl. No.: 19/108,498

(22) PCT Filed: Sep. 25, 2023
(86) PCT No.: PCT/IB2023/059426

§ 371 Date: Mar. 4, 2025

(30) Foreign Application Priority Data
Sep. 30, 2022 (JP) 2022-157669

(51) Int. Cl. H10D 30/67; H10B 12/00; H10D 1/68; H10D 30/01

(52) U.S. Cl. CPC H10D 30/6755; H10B 12/033; H10B 12/31; H10D 1/716; H10D 30/031

(57) ABSTRACT

Included are a first insulator over a substrate, an oxide semiconductor covering at least part of the first insulator, a first conductor and a second conductor over the oxide semiconductor, a second insulator over the first conductor, a third insulator over the second conductor, a third conductor over the second insulator, a fourth conductor over the third insulator, a fourth insulator placed over the third conductor and the fourth conductor and having a first opening overlapping with an area between the first conductor, the second insulator, and the third conductor and the second conductor, the third insulator, and the fourth conductor, a fifth insulator placed in the first opening, a fifth conductor placed over the fifth insulator, a sixth conductor placed in a second opening formed in the fourth insulator and being in contact with a top surface of the third conductor, and a seventh conductor placed in a third opening formed in the fourth insulator, the third insulator, and the fourth conductor and being in contact with a top surface of the second conductor. A height of the first insulator is longer than a width of the first insulator, and a top surface of the first insulator is in contact with the fifth insulator.

### TECHNICAL FIELD

One embodiment of the present invention relates to a semiconductor device using an oxide semiconductor, a memory device, and an electronic device. Another embodiment of the present invention relates to methods for manufacturing the above-described semiconductor device and memory device.

Note that one embodiment of the present invention is not limited to the above-described technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

Note that in this specification and the like, a semiconductor device refers to a general device that can function by utilizing semiconductor characteristics. A semiconductor element such as a transistor, a semiconductor circuit, an arithmetic device, and a memory device are each an embodiment of a semiconductor device. It can be sometimes said that a display device (a liquid crystal display device, a light-emitting display device, and the like), a projection device, a lighting device, an electro-optical device, a power storage device, a memory device, a semiconductor circuit, an imaging device, an electronic device, and the like include a semiconductor device.

### BACKGROUND ART

In recent years, the development of semiconductor devices has progressed, and LSIs, CPUs, memories, and the like are mainly used as the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor, and an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. Furthermore, for example, Patent Document 2 discloses a memory device that can retain stored contents for a long time by utilizing a feature of a low leakage current of the transistor using an oxide semiconductor.

In recent years, demand for an integrated circuit with higher density has risen with reductions in size and weight of electronic devices. Furthermore, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor using an oxide semiconductor film and a second transistor using an oxide semiconductor film. Furthermore, for example, Patent Document 4 discloses a technique to achieve an integrated circuit with higher density by placing a channel of a transistor using an oxide semiconductor film in the vertical direction.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota et. al, “3D-Stacked CAAC—In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide a memory device that can be miniaturized or highly integrated. Another object of one embodiment of the present invention is to provide a memory device with a large memory capacity. Another object is to provide a memory device that operates at high speed. Another object is to provide a memory device having favorable electrical characteristics. Another object is to provide a memory device with a small variation in electrical characteristics of transistors. Another object is to provide a memory device with high reliability. Another object is to provide a memory device with a high on-state current. Another object is to provide a memory device with low power consumption. Another object is to provide a novel memory device. Another object is to provide a method for manufacturing a novel memory device.

Note that the description of these objects does not preclude the existence of other objects. One embodiment of the present invention does not necessarily need to achieve all of these objects. Other objects can be derived from the description of the specification, the drawings, and the claims.

### Means for Solving the Problems

One embodiment of the present invention is a memory device which includes: a first insulator over a substrate; an oxide semiconductor covering at least part of the first insulator; a first conductor and a second conductor over the oxide semiconductor; a second insulator over the first conductor; a third insulator over the second conductor; a third conductor over the second insulator; a fourth conductor over the third insulator; a fourth insulator placed over the third conductor and the fourth conductor and having a first opening overlapping with an area between the first conductor, the second insulator, and the third conductor and the second conductor, the third insulator, and the fourth conductor; a fifth insulator placed in the first opening and over the first insulator and the oxide semiconductor; a fifth conductor placed in the first opening and over the fifth insulator; a sixth conductor placed in a second opening formed in the fourth insulator and being in contact with a top surface of the third conductor; and a seventh conductor placed in a third opening formed in the fourth insulator, the third insulator, and the fourth conductor and being in contact with a top surface of the second conductor. A height of the first insulator is longer than a width of the first insulator in a cross-sectional view in a channel width direction, and a top surface of the first insulator is in contact with the fifth insulator in a region overlapping with neither the first conductor nor the second conductor.

In the above, in the cross-sectional view in the channel width direction, the height of the first insulator is preferably larger than or equal to 2 times and smaller than or equal to 20 times the width of the first insulator.

In the above, the first conductor preferably functions as one of a source electrode and a drain electrode of a transistor, the second conductor preferably functions as the other of the source electrode and the drain electrode of the transistor, and the fifth conductor preferably functions as a gate electrode of the transistor.

In the above, the first conductor preferably functions as one of a pair of electrodes of a capacitor, the third conductor preferably functions as the other of the pair of electrodes of the capacitor, and the second insulator preferably functions as a dielectric of the capacitor.

In the above, the second insulator preferably has a stacked structure in which a zirconium oxide film, an aluminum oxide film, and a zirconium oxide film are stacked in this order.

In the above, a sixth insulator is preferably placed between the seventh conductor and the fourth insulator, and the seventh conductor and the fourth conductor are preferably insulated from each other by the sixth insulator.

In the above-described memory device, in the cross-sectional view in the channel width direction, the oxide semiconductor and the fifth conductor preferably face each other with the fifth insulator therebetween along one side surface of the first insulator; and in the cross-sectional view in the channel width direction, the oxide semiconductor and the fifth conductor preferably face each other with the fifth insulator therebetween along the other side surface of the first insulator.

In the above-described memory device, in the cross-sectional view in the channel width direction, the first conductor and the third conductor preferably face each other with the second insulator therebetween along one side surface of the first insulator; and in the cross-sectional view in the channel width direction, the first conductor and the third conductor preferably face each other with the second insulator therebetween along the other side surface of the first insulator.

In the above, the oxide semiconductor preferably includes any one or more selected from In, Ga, and Zn.

### Effect of the Invention

With one embodiment of the present invention, a memory device that can be miniaturized or highly integrated can be provided. With one embodiment of the present invention, a memory device with a large memory capacity can be provided. A memory device that operates at high speed can be provided. A memory device with high reliability can be provided. A memory device with a small variation in electrical characteristics of transistors can be provided. A memory device having favorable electrical characteristics can be provided. A memory device with a high on-state current can be provided. A memory device with low power consumption can be provided. A novel memory device can be provided. A method for manufacturing a novel memory device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a plan view illustrating an example of a memory device. FIG. 1B to FIG. 1D are cross-sectional views illustrating the example of the memory device.

FIG. 2 is a cross-sectional view illustrating an example of a memory device.

FIG. 3A and FIG. 3B are cross-sectional views illustrating examples of a memory device.

FIG. 4A and FIG. 4B are cross-sectional views each illustrating an example of a memory device.

FIG. 5A and FIG. 5B are cross-sectional views illustrating an example of a memory device.

FIG. 6A is a plan view illustrating an example of a memory device. FIG. 6B to FIG. 6D are cross-sectional views illustrating the example of the memory device.

FIG. 7A is a plan view illustrating an example of a memory device. FIG. 7B to FIG. 7D are cross-sectional views illustrating the example of the memory device.

FIG. 8A is a plan view illustrating an example of a memory device. FIG. 8B and FIG. 8C are cross-sectional views illustrating the example of the memory device.

FIG. 9A is a plan view illustrating an example of a memory device. FIG. 9B to FIG. 9D are cross-sectional views illustrating the example of the memory device.

FIG. 10A is a plan view illustrating an example of a memory device. FIG. 10B to FIG. 10D are cross-sectional views illustrating the example of the memory device.

FIG. 11A and FIG. 11B are cross-sectional views illustrating the example of the memory device.

FIG. 12A is a plan view illustrating an example of a method for manufacturing a memory device.

FIG. 12B to FIG. 12D are cross-sectional views illustrating the example of the method for manufacturing the memory device.

FIG. 13A is a plan view illustrating the example of the method for manufacturing the memory device. FIG. 13B to FIG. 13D are cross-sectional views illustrating the example of the method for manufacturing the memory device.

FIG. 14A is a plan view illustrating the example of the method for manufacturing the memory device. FIG. 14B to FIG. 14D are cross-sectional views illustrating the example of the method for manufacturing the memory device.

FIG. 15A is a plan view illustrating the example of the method for manufacturing the memory device. FIG. 15B to FIG. 15D are cross-sectional views illustrating the example of the method for manufacturing the memory device.

FIG. 16A is a plan view illustrating the example of the method for manufacturing the memory device. FIG. 16B to FIG. 16D are cross-sectional views illustrating the example of the method for manufacturing the memory device.

FIG. 17A is a plan view illustrating the example of the method for manufacturing the memory device. FIG. 17B to FIG. 17D are cross-sectional views illustrating the example of the method for manufacturing the memory device.

FIG. 18A is a plan view illustrating the example of the method for manufacturing the memory device. FIG. 18B to FIG. 18D are cross-sectional views illustrating the example of the method for manufacturing the memory device.

FIG. 19A is a plan view illustrating the example of the method for manufacturing the memory device. FIG. 19B to FIG. 19D are cross-sectional views illustrating the example of the method for manufacturing the memory device.

FIG. 20A is a plan view illustrating the example of the method for manufacturing the memory device. FIG. 20B to FIG. 20D are cross-sectional views illustrating the example of the method for manufacturing the memory device.

FIG. 21A is a plan view illustrating the example of the method for manufacturing the memory device. FIG. 21B to FIG. 21D are cross-sectional views illustrating the example of the method for manufacturing the memory device.

FIG. 22A is a plan view illustrating the example of the method for manufacturing the memory device. FIG. 22B to FIG. 22D are cross-sectional views illustrating the example of the method for manufacturing the memory device.

FIG. 23 is a block diagram illustrating an example of a memory device.

FIG. 24A and FIG. 24B are a schematic diagram and a circuit diagram illustrating an example of a memory device.

FIG. 25A and FIG. 25B are schematic diagrams each illustrating an example of a memory device.

FIG. 26 is a circuit diagram illustrating an example of a memory device.

FIG. 27 is a cross-sectional view illustrating an example of a memory device.

FIG. 28 is a cross-sectional view illustrating an example of a memory device.

FIG. 29A and FIG. 29B are diagrams illustrating an example of a semiconductor device.

FIG. 30A and FIG. 30B are diagrams illustrating examples of electronic components.

FIG. 31A and FIG. 31B are diagrams illustrating examples of electronic devices, and FIG. 31C to FIG. 31E are diagrams illustrating an example of a large computer.

FIG. 32 is a diagram illustrating an example of space equipment.

FIG. 33 is a diagram illustrating an example of a storage system applicable to a data center.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same reference numerals are used in common for the same portions or portions having similar functions in different drawings, and repeated description thereof is omitted. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in the drawings.

Furthermore, especially in a plan view (also referred to as a “top view”), a perspective view, or the like, the description of some components is omitted for easy understanding of the invention in some cases. The description of some hidden lines and the like is also omitted in some cases.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be interchanged with each other depending on the case or circumstances. For example, the term “conductive layer” can be replaced with the term “conductive film”. As another example, the term “insulating film” can be replaced with the term “insulating layer”. The term “conductor” can be interchanged with the term “conductive layer” or the term “conductive film” depending on the case or the circumstances. The term “insulator” can be interchanged with the term “insulating layer” or the term “insulating film” depending on the case or the circumstances.

In this specification and the like, the expression “parallel” indicates a state where two straight lines are placed at an angle greater than or equal to −10° and less than or equal to 10°. Accordingly, the case where the angle is greater than or equal to −5° and less than or equal to 5° is also included. Furthermore, the expression “substantially parallel” indicates a state where two straight lines are placed at an angle greater than or equal to −30° and less than or equal to 30°. Moreover, the expression “perpendicular” indicates a state where two straight lines are placed at an angle greater than or equal to 80° and less than or equal to 100°. Accordingly, the case where the angle is greater than or equal to 85° and less than or equal to 95° is also included. Furthermore, the expression “substantially perpendicular” indicates a state where two straight lines are placed at an angle greater than or equal to 60° and less than or equal to 120°.

The term “opening” includes a groove and a slit, for example. A region where an opening is formed is referred to as an opening portion in some cases.

In the drawings used in embodiments of this specification, a sidewall of an insulator in an opening portion in the insulator is illustrated as being perpendicular or substantially perpendicular to a substrate surface or a formation surface, but the sidewall may have a tapered shape.

Note that in this specification and the like, the tapered shape refers to a shape such that at least part of a side surface of a component is inclined to a substrate surface or a formation surface. For example, the tapered shape refers to a shape including a region where the angle formed by the inclined side surface and the substrate surface or the formation surface (hereinafter, such an angle is also referred to as a taper angle in some cases) is less than 90°. Note that the side surface of the component and the substrate surface are not necessarily completely flat and may be substantially flat with a slight curvature or substantially flat with slight unevenness.

Note that in this specification and the like, the expression “level or substantially level” indicates a structure having the same level from a reference surface (e.g., a flat surface such as a substrate surface) in a cross-sectional view. For example, in a manufacturing process of a memory device, planarization treatment (typically, CMP treatment) is performed, whereby the surface of a single layer or the surfaces of a plurality of layers is/are exposed in some cases. In this case, the surfaces on which the CMP treatment is performed are at the same level from a reference surface. Note that a plurality of layers may be at different levels depending on a treatment apparatus, a treatment method, or a material of the treated surfaces in the CMP treatment. This case is also regarded as being “level or substantially level” in this specification and the like. For example, the expression “level or substantially level” includes the case where two layers (here, given as a first layer and a second layer) having different levels with respect to the reference surface are included, and the difference between the top-surface level of the first layer and the top-surface level of the second layer is less than or equal to 20 nm.

Note that in this specification and the like, the expression “side end portions are aligned or substantially aligned” means that outlines of stacked layers at least partly overlap with each other in a plan view. For example, the case of processing the upper layer and the lower layer with use of the same mask pattern or mask patterns that are partly the same is included. However, in some cases, the outlines do not exactly overlap with each other and the outline of the upper layer is positioned inside the outline of the lower layer or the outline of the upper layer is positioned outside the outline of the lower layer; such a case is also represented by the expression “side end portions are aligned or substantially aligned”.

### Embodiment 1

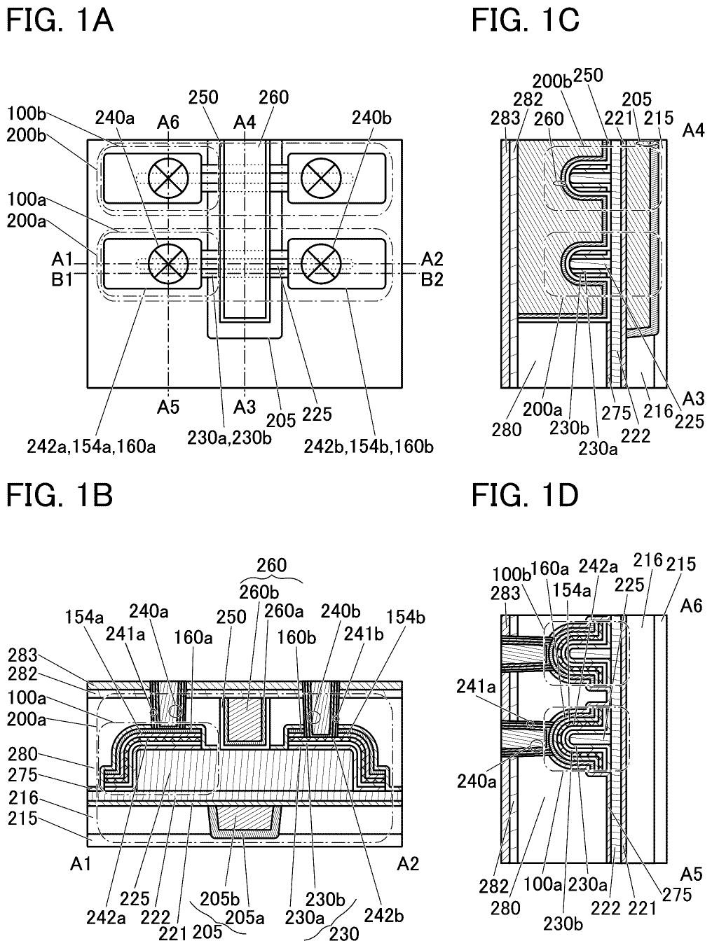

In this embodiment, a memory device including an oxide semiconductor layer and a method for manufacturing the memory device will be described with reference to FIG. 1 to FIG. 22.

### Structure Example of Memory Device

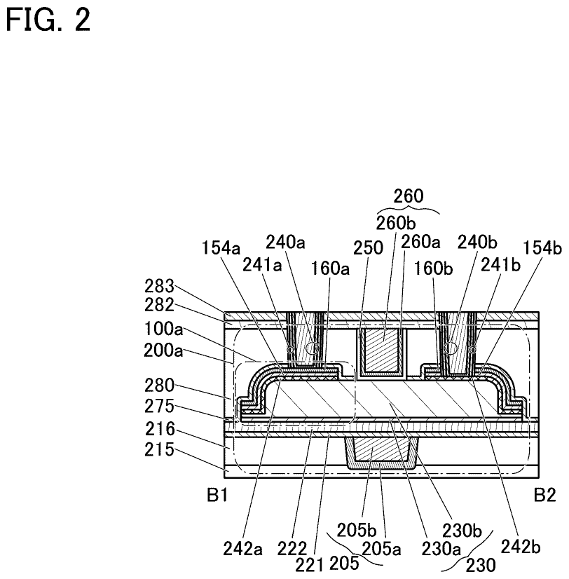

A structure example of a memory device is described with reference to FIG. 1 to FIG. 8. FIG. 1A to FIG. 1D and FIG. 2 are a top view and cross-sectional views of the memory device including a transistor 200a, a transistor 200b, a capacitor 100a, and a capacitor 100b above a substrate (not illustrated). In the memory device here, the transistor 200a and the capacitor 100a, and the transistor 200b and the capacitor 100b each function as a 1T (transistor) 1C (capacitor) memory cell. Note that since the transistor 200b has a structure similar to that of the transistor 200a, the components are denoted by the same hatching patterns as those of the transistor 200a and are not especially denoted by reference numerals. Since the capacitor 100b has a structure similar to that of the capacitor 100a, the components are denoted by the same hatching patterns as those of the capacitor 100a and are not especially denoted by reference numerals. In the following, the transistor 200a and the transistor 200b are collectively described as a transistor 200, in some cases. The capacitor 100a and the capacitor 100b are collectively described as a capacitor 100, in some cases.

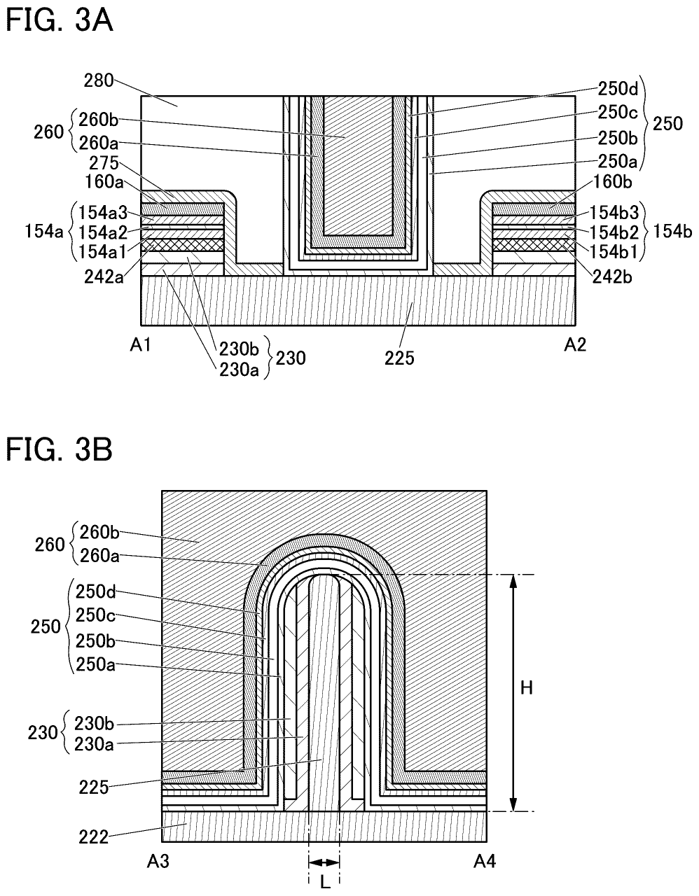

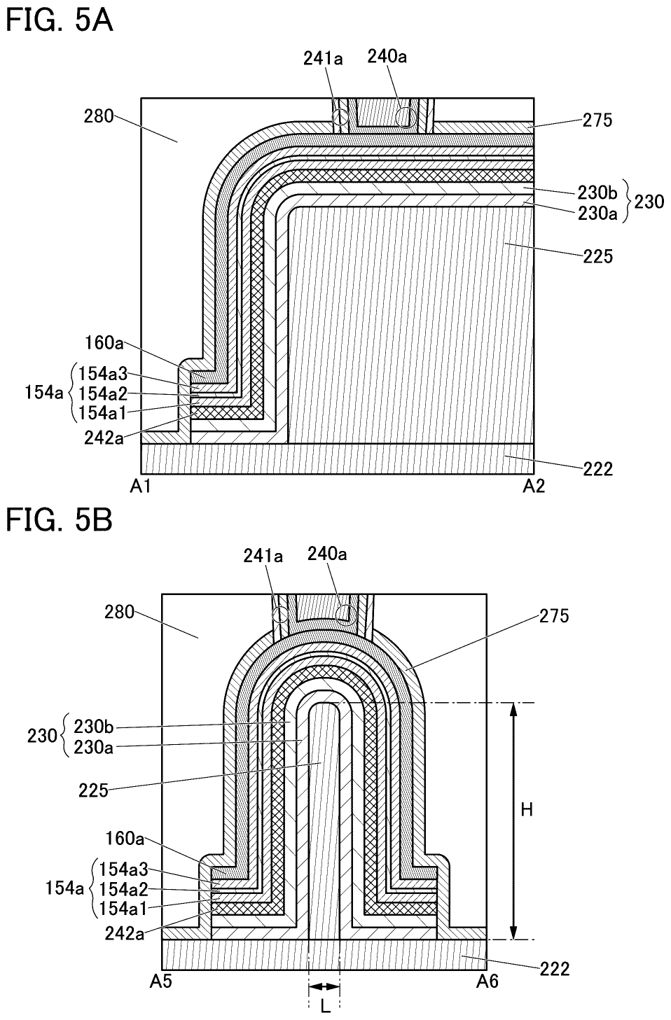

FIG. 1A is a top view of the memory device. FIG. 1B to FIG. 1D and FIG. 2 are cross-sectional views of the memory device. Here, FIG. 1B is a cross-sectional view of a portion indicated by a dashed-dotted line A1-A2 in FIG. 1A, and is also a cross-sectional view of the transistor 200a in the channel length direction. FIG. 2 is a cross-sectional view of a portion indicated by a dashed-dotted line B1-B2 in FIG. 1A, and is also a cross-sectional view of the transistor 200a in the channel length direction. FIG. 1C is a cross-sectional view of a portion indicated by a dashed-dotted line A3-A4 in FIG. 1A, and is also a cross-sectional view of the transistor 200a and the transistor 200b in the channel width direction. FIG. 1D is a cross-sectional view of a portion indicated by a dashed-dotted line A5-A6 in FIG. 1A, and is also a cross-sectional view of the capacitor 100a and the capacitor 100b. Here, the dashed-dotted line A1-A2 and the dashed-dotted line B1-B2 are orthogonal to the dashed-dotted line A3-A4 and the dashed-dotted line A5-A6. The dashed-dotted line A1-A2 and the dashed-dotted line B1-B2 are parallel to each other, and the dashed-dotted line A3-A4 and the dashed-dotted line A5-A6 are parallel to each other. Note that some components are omitted in the top view in FIG. 1A for clarity of the drawing. FIG. 3A is an enlarged view of a conductor 260 and its vicinity in FIG. 1B. FIG. 3B is an enlarged view of an insulator 225 and its vicinity in FIG. 1C. FIG. 5A is an enlarged view of an insulator 154a and its vicinity in FIG. 1B. FIG. 5B is an enlarged view of the insulator 225 and its vicinity in FIG. 1D.

The memory device of this embodiment includes a conductor 205 (a conductor 205a and a conductor 205b) provided to be embedded in an insulator 216 over a substrate (not illustrated), an insulator 221 over the insulator 216 and the conductor 205, an insulator 222 over the insulator 221, the insulator 225 over the insulator 222, an oxide 230 (an oxide 230a and an oxide 230b) that is placed over the insulator 222 and covers at least part of the insulator 225, a conductor 242a and a conductor 242b over the oxide 230, the insulator 154a over the conductor 242a, an insulator 154b over the conductor 242b, a conductor 160a over the insulator 154a, a conductor 160b over the insulator 154b, an insulator 250 over the insulator 225 and the oxide 230, and the conductor 260 (a conductor 260a and a conductor 260b) over the insulator 250. Hereinafter, the conductor 242a and the conductor 242b are collectively referred to as a conductor 242 in some cases. In addition, the insulator 154a and the insulator 154b are collectively referred to as an insulator 154 in some cases. Furthermore, the conductor 160a and the conductor 160b are collectively referred to as a conductor 160 in some cases.

An insulator 275 is provided over the conductor 160, and an insulator 280 is provided over the insulator 275. The insulator 250 and the conductor 260 are placed in an opening provided in the insulator 280 and the insulator 275. An insulator 282 is provided over the insulator 280 and the conductor 260. An insulator 283 is provided over the insulator 282. An insulator 215 is provided below the insulator 216 and the conductor 205.

An insulator 241a is provided in contact with an inner wall of an opening formed in the insulator 280 and the like, and a conductor 240a is provided in contact with the side surface of the insulator 241a. The bottom surface of the conductor 240a is in contact with the top surface of the conductor 160a. An insulator 241b is provided in contact with an inner wall of an opening formed in the insulator 280 and the like, and a conductor 240b is provided in contact with the side surface of the insulator 241b. The bottom surface of the conductor 240b is in contact with the top surface of the conductor 242b. Hereinafter, the conductor 240a and the conductor 240b are collectively described as a conductor 240 in some cases. The insulator 241a and the insulator 241b are collectively described as an insulator 241 in some cases.

The oxide 230 includes a region functioning as a channel formation region of the transistor 200. The conductor 260 includes a region functioning as a first gate electrode (an upper gate electrode) of the transistor 200. The insulator 250 includes a region functioning as a first gate insulator of the transistor 200. The conductor 205 includes a region functioning as a second gate electrode (a lower gate electrode) of the transistor 200. The insulator 222 and the insulator 221 each include a region functioning as a second gate insulator of the transistor 200.

The conductor 242a includes a region functioning as one of a source electrode and a drain electrode of the transistor 200. The conductor 242b includes a region functioning as the other of the source electrode and the drain electrode of the transistor 200. The conductor 240b functions as a plug connected to the conductor 242b.

The capacitor 100 includes the conductor 242a, the insulator 154a, and the conductor 160a. The conductor 242a functions as one of a pair of electrodes of the capacitor 100 (also referred to as a lower electrode), the conductor 160a functions as the other of the pair of electrodes of the capacitor 100 (also referred to as an upper electrode), and the insulator 154a functions as a dielectric of the capacitor 100. The conductor 240a functions as a plug connected to the conductor 160a. The capacitor 100 forms a MIM (Metal-Insulator-Metal) capacitor.

The oxide 230 preferably includes the oxide 230a covering the insulator 225 and the oxide 230b over the oxide 230a, in a region overlapping with the conductor 242 or the like. Here, the oxide 230a is in contact with the top surface and the side surface of the insulator 225 and the top surface of the insulator 222. As illustrated in FIG. 1D and the like, the oxide 230a and the oxide 230b are provided to cover the insulator 225 having a high aspect ratio. Thus, the oxide 230a and the oxide 230b are preferably deposited by a deposition method that offers good coverage, such as an ALD method.

In a region not overlapping with the conductor 242 or the like (the region can also be referred to as a region sandwiched between the conductor 242a and the conductor 242b), the oxide 230 preferably includes the oxide 230a in contact with the side surface of the insulator 225 and the oxide 230b in contact with the side surface of the oxide 230a, as illustrated in FIG. 3B. Here, the oxide 230a is in contact with the side surface of the insulator 225, the side surface and the bottom surface of the oxide 230b, and the top surface of the insulator 222. Furthermore, the oxide 230a and the oxide 230b are not in contact with at least part of the top surface of the insulator 225, and the top surface of the insulator 225 is in contact with the bottom surface of the insulator 250 as illustrated in FIG. 1B, FIG. 1C, and the like. Although the oxide 230a and the oxide 230b do not appear to be formed between the conductor 242a and the conductor 242b in FIG. 1B, the oxide 230a and the oxide 230b are formed in the vicinity of the side surface of the insulator 225 as illustrated in FIG. 2. That is, each of the oxide 230a and the oxide 230b has a shape such that each of the oxide 230a and the oxide 230b is folded in half to form the portion on the A5 side and the portion on the A6 side that are connected as one with the insulator 225 in between in the region overlapping with the conductor 242 and such that the portion on the A3 side and the portion on the A4 side are separated by the insulator 225 in the region between the conductor 242a and the conductor 242b. In other words, the insulator 225 is substantially covered with the oxide 230; an opening is formed in the oxide 230 in the region between the conductor 242a and the conductor 242b, and the insulator 225 is exposed at the region without being covered with the oxide 230.

As described above, in the region between the conductor 242a and the conductor 242b, the oxide 230a and the oxide 230b are provided in a sidewall shape along the side surface of the insulator 225 having a high aspect ratio. Thus, the oxide 230a and the oxide 230b are preferably deposited by a deposition method that offers favorable coverage, such as an ALD method. In the cross section in the channel width direction of the region between the conductor 242a and the conductor 242b, the oxide 230a and the oxide 230b are formed on each of the side surface of the insulator 225 on the A3 side and the side surface of the insulator 225 on the A4 side. With this structure, the channel formation region of the transistor 200 can be formed along the side surface of the insulator 225 on the A3 side and the side surface of the insulator 225 on the A4 side, so that the channel width per unit area can be increased. The transistor 200 having such an increased channel width can have a favorable on-state current, favorable field-effect mobility, and favorable frequency characteristics. Thus, with the use of the memory device of this embodiment as memory cells, the writing speed can be improved.

Including the oxide 230a under the oxide 230b makes it possible to inhibit diffusion of impurities into the oxide 230b from components formed below the oxide 230a.

Although an example in which the oxide 230 has a two-layer structure of the oxide 230a and the oxide 230b is described in this embodiment, one embodiment of the present invention is not limited thereto. The oxide 230 may have a single-layer structure of the oxide 230b or a stacked-layer structure of three or more layers, for example.

The oxide 230b includes the channel formation region of the transistor 200 and a source region and a drain region provided to sandwich the channel formation region. At least part of the channel formation region faces the conductor 260. The source region overlaps with the conductor 242a, and the drain region overlaps with the conductor 242b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the carrier concentration of the channel formation region is preferably lower than or equal to 1×10¹⁸ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration of the channel formation region is not particularly limited and can be, for example, 1×10⁻⁹ cm⁻³.

In order to reduce the carrier concentration in the oxide 230b, the impurity concentration in the oxide 230b is reduced so that the density of defect states is reduced. In this specification and the like, a state with a low impurity concentration and a low density of defect states is referred to as a highly purified intrinsic or substantially highly purified intrinsic state. Note that an oxide semiconductor (or a metal oxide) having a low carrier concentration is sometimes referred to as a highly purified intrinsic or substantially highly purified intrinsic oxide semiconductor (or metal oxide).

In order to obtain stable electrical characteristics of the transistor 200, reducing the impurity concentration in the metal oxide 230b is effective. In order to reduce the impurity concentration in the oxide 230b, it is preferable that the impurity concentration in an adjacent film be also reduced. Examples of impurities include hydrogen, nitrogen, an alkali metal, an alkaline earth metal, iron, nickel, and silicon. Note that an impurity in the oxide 230b refers to, for example, an element other than the main components of the oxide 230b. For example, an element with a concentration lower than 0.1 atomic % can be regarded as an impurity.

Note that the channel formation region, the source region, and the drain region may each be formed not only in the oxide 230b but also in the oxide 230a.

In the oxide 230, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

A metal oxide functioning as a semiconductor (hereinafter also referred to as an oxide semiconductor) is preferably used for the oxide 230 (the oxide 230a and the oxide 230b).

The metal oxide functioning as a semiconductor preferably has a band gap larger than or equal to 2 eV, further preferably larger than or equal to 2.5 eV. With the use of a metal oxide having a larger band gap, the off-state current of the transistor can be reduced. Such a transistor including a metal oxide in a channel formation region is referred to as an OS transistor. The off-state current of the OS transistor is low, so that power consumption of the memory device can be adequately reduced. The OS transistor has excellent frequency characteristics, which enables the memory device to operate at high speed.

The oxide 230 preferably includes a metal oxide (an oxide semiconductor). Examples of the metal oxide that can be used for the oxide 230 include indium oxide, gallium oxide, and zinc oxide. The metal oxide preferably includes at least indium (In) or zinc (Zn). The metal oxide preferably includes two or three elements selected from indium, an element M, and zinc. Note that the element Mis a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably any one or more kinds of the above elements, further preferably one or more kinds selected from aluminum, gallium, tin, and yttrium, still further preferably gallium. In this specification and the like, a metal element and a metalloid element may be collectively referred to as a “metal element”, and a “metal element” in this specification and the like may refer to a metalloid element.

For the oxide 230, it is possible to use, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), indium gallium aluminum zinc oxide (In—Ga—Al—Zn oxide, also referred to as IGAZO or IAGZO), or the like. Alternatively, it is possible to use indium tin oxide including silicon, gallium tin oxide (Ga—Sn oxide), aluminum tin oxide (A1-Sn oxide), or the like.

When the proportion of the number of indium atoms in the total number of atoms of all the metal elements included in the metal oxide is increased, the field-effect mobility of the transistor can be increased.

Note that the metal oxide may include, instead of or in addition to indium, one or more kinds of metal elements with larger period numbers in the periodic table. The larger the overlap between orbits of metal elements is, the more likely it is that the metal oxide will have high carrier conductivity. Thus, a transistor including a metal element with a larger period number in the periodic table can have high field-effect mobility in some cases. Examples of the metal element with a larger period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may include one or more kinds of nonmetallic elements. A transistor including the metal oxide including a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the proportion of the number of atoms of the element M in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be improved.

As described above, electrical characteristics and reliability of a transistor vary depending on the composition of the metal oxide used for the oxide 230. Therefore, by changing the composition of the metal oxide in accordance with the electrical characteristics and reliability required for the transistor, the memory device can have both excellent electrical characteristics and high reliability.

The oxide 230 preferably has a stacked-layer structure of a plurality of oxide layers with different chemical compositions. For example, the atomic ratio of the element M to a metal element that is a main component in the metal oxide used for the oxide 230a is preferably greater than the atomic ratio of the element M to a metal element that is a main component in the metal oxide used for the oxide 230b. Moreover, the atomic ratio of the element M to In in the metal oxide used for the oxide 230a is preferably greater than the atomic ratio of the element M to In in the metal oxide used for the oxide 230b. With this structure, impurities and oxygen can be inhibited from diffusing into the oxide 230b from the components formed below the oxide 230a.

Furthermore, the atomic ratio of In to the element M in the metal oxide used for the oxide 230b is preferably greater than the atomic ratio of In to the element M in the metal oxide used for the oxide 230a. With this structure, the transistor 200 can have a high on-state current and excellent frequency characteristics.

When the oxide 230a and the oxide 230b include a common element as the main component besides oxygen, the density of defect states at the interface between the oxide 230a and the oxide 230b can be decreased. The density of defect states at the interface between the oxide 230a and the oxide 230b can be decreased. Thus, the influence of interface scattering on carrier conduction is reduced, and the transistor 200 can have a high on-state current and high frequency characteristics.

Specifically, as the oxide 230a, a metal oxide with a composition of In:M:Zn=1:3:2 [atomic ratio] or in the neighborhood thereof, a composition of In:M:Zn=1:3:4 [atomic ratio] or in the neighborhood thereof, a composition of In:M:Zn=1:1:1 [atomic ratio] or in the neighborhood thereof, or a composition of In:M:Zn=1:1:0.5 [atomic ratio] or in the neighborhood thereof can be used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, a composition of In:M:Zn=4:2:3 [atomic ratio] or in the neighborhood thereof, or, a composition of In:Zn=4:1 [atomic ratio] without the element M or in the neighborhood thereof can be used. Note that a composition in the neighborhood includes the range of ±30% of an intended atomic ratio. Gallium is preferably used as the element M. In the case where a single layer of the oxide 230b is provided as the oxide 230, a metal oxide that can be used for the oxide 230a may be used for the oxide 230b. The compositions of the metal oxides that can be used for the oxide 230a and the oxide 230b are not limited to the above. For example, the composition of the metal oxide that can be used for the oxide 230a may be applied to the oxide 230b. Similarly, the composition of the metal oxide that can be used for the oxide 230b may be applied to the oxide 230a. Metal oxides having any of the above compositions may be stacked in one or both of the oxide 230a and the oxide 230b.

When the metal oxide is deposited by a sputtering method, the above atomic ratio is not limited to the atomic ratio of the deposited metal oxide and may be the atomic ratio of a sputtering target used for depositing the metal oxide.

The oxide 230b preferably has crystallinity. It is particularly preferable to use a CAAC-OS (c-axis aligned crystalline oxide semiconductor) for the oxide 230b.

The CAAC-OS is a metal oxide having a dense structure with high crystallinity and small amounts of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as a CAAC-OS, is used for the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in the manufacturing process (what is called thermal budget).

A transistor using an oxide semiconductor is likely to have its electrical characteristics changed by impurities and oxygen vacancies in a region where a channel is formed in the oxide semiconductor, which might reduce the reliability. In some cases, a defect that is an oxygen vacancy into which hydrogen in the vicinity of the oxygen vacancy has entered (hereinafter sometimes referred to as VoH) is formed, which generates an electron serving as a carrier. Therefore, when the channel formation region in the oxide semiconductor includes oxygen vacancies, the transistor is likely to have normally-on characteristics (characteristics with which, even when no voltage is applied to the gate electrode, the channel exists and a current flows through the transistor). Therefore, impurities, oxygen vacancies, and VoH are preferably reduced as much as possible in the channel formation region in the oxide semiconductor. In other words, the channel formation region in the oxide semiconductor is preferably an i-type (intrinsic) or substantially i-type region with a reduced carrier concentration.

As a countermeasure against the above, an insulator including oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the memory device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably an i-type or substantially i-type region with a reduced carrier concentration, whereas the source region and the drain region are preferably n-type regions with high carrier concentrations. That is, the amounts of oxygen vacancies and VoH in the channel formation region of the oxide semiconductor are preferably reduced. Supply of an excess amount of oxygen to the source region and the drain region and excessive reduction in the amount of VoH in the source region and the drain region are preferably inhibited. Furthermore, a structure in which a reduction in the conductivity of the conductor 260, the conductor 242a, the conductor 242b, and the like is inhibited is preferable. For example, oxidation of the conductor 260, the conductor 242a, the conductor 242b, and the like is preferably inhibited. Note that hydrogen in the oxide semiconductor can form VoH; thus, the hydrogen concentration needs to be reduced in order to reduce the amount of VoH.

The memory device of this embodiment thus has a structure in which the hydrogen concentration in the channel formation region is reduced, oxidation of the conductor 242a, the conductor 242b, and the conductor 260 is inhibited, and a reduction in the hydrogen concentration in the source region and the drain region is inhibited.

The insulator 250 in contact with the channel formation region of the oxide 230b preferably has a function of capturing or fixing hydrogen. Thus, the hydrogen concentration in the channel formation region of the oxide 230b can be reduced. Accordingly, VoH in the channel formation region can be reduced, so that the channel formation region can be an i-type or substantially i-type region.

Here, as illustrated in FIG. 3A, the insulator 250 preferably has a stacked-layer structure of an insulator 250a in contact with the oxide 230, an insulator 250b over the insulator 250a, an insulator 250c over the insulator 250b, and an insulator 250d over the insulator 250c. In this case, the insulator 250a and the insulator 250c preferably have a function of capturing or fixing hydrogen.

An example of the insulator having a function of capturing or fixing hydrogen is a metal oxide having an amorphous structure. For the insulator 250a and the insulator 250c, for example, a metal oxide such as magnesium oxide or an oxide including one or both of aluminum and hafnium is preferably used. In such a metal oxide having an amorphous structure, an oxygen atom has a dangling bond and sometimes has a property of capturing or fixing hydrogen with the dangling bond. That is, the metal oxide having an amorphous structure has high capability of capturing or fixing hydrogen.

A high permittivity (high-k) material is preferably used for the insulator 250a and the insulator 250c. An example of the high-k material is an oxide including one or both of aluminum and hafnium. With the use of the high-k material for the insulator 250a and the insulator 250c, a gate potential applied during the operation of the transistor can be reduced while the physical thickness of the gate insulator is maintained. In addition, the equivalent oxide thickness (EOT) of the insulator functioning as the gate insulator can be reduced.

For the insulator 250a and the insulator 250c, an oxide including one or both of aluminum and hafnium is preferably used, and an oxide that has an amorphous structure and includes one or both of aluminum and hafnium is further preferably used.

In this embodiment, an aluminum oxide film is used for the insulator 250a. The aluminum oxide preferably has an amorphous structure. Here, when the insulator 250a is provided in contact with the oxide 230b, hydrogen included in the oxide 230b and the like can be captured and fixed more effectively.

In this embodiment, hafnium oxide is used for the insulator 250c. Here, when the insulator 250c is provided between the insulator 250b and the insulator 250d, hydrogen included in the insulator 250b and the like can be captured and fixed more effectively.

An insulator having a thermally stable structure, such as silicon oxide or silicon oxynitride, is preferably used for the insulator 250b. Note that in this specification and the like, oxynitride refers to a material that includes more oxygen than nitrogen in its composition, and nitride oxide refers to a material that includes more nitrogen than oxygen in its composition. For example, silicon oxynitride refers to a material that includes more oxygen than nitrogen in its composition, and silicon nitride oxide refers to a material that includes more nitrogen than oxygen in its composition.

In order to inhibit oxidation of the conductor 242a, the conductor 242b, and the conductor 260, an oxygen-barrier insulator is preferably provided in the vicinity of each of the conductor 242a, the conductor 242b, and the conductor 260. In the memory device described in this embodiment, the insulator corresponds to the insulator 250a, the insulator 250d, the insulator 250c, and the insulator 275, for example.

Note that in this specification and the like, a barrier insulator refers to an insulator having a barrier property. In this specification and the like, “having a barrier property” means having a property of hindering the permeation of a target substance (also referred to as having a low permeability). For example, an insulator having a barrier property hardly allows a target substance to diffuse into the insulator. As another example, an insulator having a barrier property has a function of capturing or fixing (also referred to as gettering) a target substance in the insulator.

Examples of the oxygen-barrier insulator include an oxide including one or both of aluminum and hafnium, magnesium oxide, gallium oxide, indium gallium zinc oxide, silicon nitride, and silicon nitride oxide. Examples of the oxide including one or both of aluminum and hafnium include aluminum oxide, hafnium oxide, an oxide including aluminum and hafnium (hafnium aluminate), and an oxide including hafnium and silicon (hafnium silicate). For example, each of the insulator 250a, the insulator 250c, the insulator 250d, and the insulator 275 preferably has a single-layer structure or a stacked-layer structure of the oxygen-barrier insulator.

The insulator 250a preferably has an oxygen-barrier property. It is preferable that the insulator 250a be less likely to transmit oxygen than at least the insulator 280. The insulator 250a is provided in contact with the top surface of the insulator 250, the top surface and the side surface of the oxide 230b, the side surface of the oxide 230a, and the top surface of the insulator 222. When the insulator 250a has an oxygen-barrier property, release of oxygen from the channel formation region of the oxide 230b caused by heat treatment or the like can be inhibited. This can reduce formation of oxygen vacancies in the oxide 230a and the oxide 230b.

By the provision of the insulator 250a, oxygen can be inhibited from being excessively supplied from the insulator 280 to the oxide 230a and the oxide 230b and an appropriate amount of oxygen can be supplied to the oxide 230a and the oxide 230b. Thus, it is possible to inhibit excessive oxidation of the source region and the drain region and a decrease in the on-state current or field-effect mobility of the transistor 200.

The oxide including one or both of aluminum and hafnium has a barrier property against oxygen and thus can be suitably used for the insulator 250a.

The insulator 250d preferably has a barrier property against oxygen. The insulator 250d is provided between the conductor 260 and the channel formation region of the oxide 230 and between the insulator 280 and the conductor 260. Such a structure can inhibit diffusion of oxygen included in the channel formation region of the oxide 230 into the conductor 260 and formation of oxygen vacancies in the channel formation region of the oxide 230. Moreover, oxygen included in the oxide 230 and oxygen included in the insulator 280 can be inhibited from diffusing into the conductor 260 and oxidizing the conductor 260. It is preferable that oxygen be less likely to pass through the insulator 250d than at least through the insulator 280. For example, a silicon nitride film is preferably used for the insulator 250d. In this case, the insulator 250d is an insulator that includes at least nitrogen and silicon.

The insulator 250d preferably has a barrier property against hydrogen. Accordingly, diffusion of impurities included in the conductor 260, such as hydrogen, into the oxide 230b can be prevented.

It is preferable that the insulator 275 also have an oxygen barrier property. The insulator 275 is provided between the insulator 280 and the conductor 160a, between the insulator 280 and the conductor 160b, between the insulator 280 and the conductor 240a, and between the insulator 280 and the conductor 240b. The insulator 275 is provided in contact with the top surface of the conductor 160, the side surface of the conductor 160, the side surface of the insulator 154, the side surface of the conductor 242, the side surface of the oxide 230, and the top surface of the insulator 222. With this structure, oxygen contained in the insulator 280 can be inhibited from diffusing into the conductor 160 and the conductor 242. Thus, the conductor 160 and the conductor 242 can be inhibited from being oxidized by oxygen contained in the insulator 280, so that an increase in resistivity can be inhibited. It is preferable that the insulator 275 be less likely to transmit oxygen than at least the insulator 280. For example, silicon nitride is preferably used for the insulator 275. In this case, the insulator 275 is an insulator that contains at least nitrogen and silicon.

In order to inhibit a reduction in the hydrogen concentration in the source region and the drain region in the oxide 230, a hydrogen-barrier insulator is preferably provided in the vicinity of each of the source region and the drain region. In the memory device described in this embodiment, the hydrogen-barrier insulator is, for example, the insulator 275.

Examples of a hydrogen-barrier insulator include oxides such as aluminum oxide, hafnium oxide, and tantalum oxide and nitrides such as silicon nitride. For example, the insulator 275 preferably has a single-layer structure or a stacked-layer structure of the hydrogen-barrier insulator.

Provision of the insulator 275 as described above can inhibit hydrogen in the source region and the drain region from diffusing to the outside, so that a reduction in the hydrogen concentrations of the source region and the drain region can be inhibited. Thus, the source region and the drain region can be n-type regions.

With the above-described structure, the channel formation region can be an i-type or substantially i-type region, and the source region and the drain region can be n-type regions. Thus, a memory device with favorable electrical characteristics can be provided. The memory device with the above-described structure can have favorable electrical characteristics even when miniaturized or highly integrated. Miniaturization of the transistor 200 can improve the frequency characteristics. Specifically, the cutoff frequency can be improved.

The insulator 250a to the insulator 250d function as part of the gate insulator. The insulator 250a to the insulator 250d are provided in the opening formed in the insulator 280 and the like, together with the conductor 260. The thicknesses of the insulator 250a to the insulator 250d are each preferably small for miniaturization of the transistor 200. The thickness of each of the insulator 250a to the insulator 250d is preferably larger than or equal to 0.1 nm and smaller than or equal to 10 nm, further preferably larger than or equal to 0.1 nm and smaller than or equal to 5.0 nm, still further preferably larger than or equal to 0.5 nm and smaller than or equal to 5.0 nm, yet further preferably larger than or equal to 1.0 nm and smaller than 5.0 nm, yet still further preferably larger than or equal to 1.0 nm and smaller than or equal to 3.0 nm. Note that at least part of each of the insulator 250a to the insulator 250d includes a region having the above-described thickness.

To form the insulator 250a to the insulator 250d having a small thickness as described above, an atomic layer deposition (ALD) method is preferably used for deposition. Furthermore, in the case where the insulator 250a to the insulator 250d are provided in the opening in the insulator 280 and the like, an ALD method is preferably employed. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables deposition at a lower temperature.

An ALD method, which enables atomic layers to be deposited one by one, has advantages such as deposition of an extremely thin film, deposition on a component with a high aspect ratio, deposition of a film with a small number of defects such as pinholes, deposition with excellent coverage, and low-temperature deposition. Therefore, the insulator 250 can be deposited on the side surface of the opening portion formed in the insulator 280, the side end portions of the conductors 242a and 242b, and the like, with a small thickness like the above-described thickness and good coverage.

Note that some precursors used in an ALD method include carbon or the like. Thus, in some cases, a film provided by an ALD method includes impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

Although the case where the insulator 250 has a four-layer structure of the insulator 250a to the insulator 250d is described above, the present invention is not limited thereto. The insulator 250 can have a structure including at least one of the insulator 250a to the insulator 250d. When the insulator 250 is formed of one, two, or three layer(s) of the insulator 250a to the insulator 250d, the manufacturing process of the memory device can be simplified and the productivity can be increased.

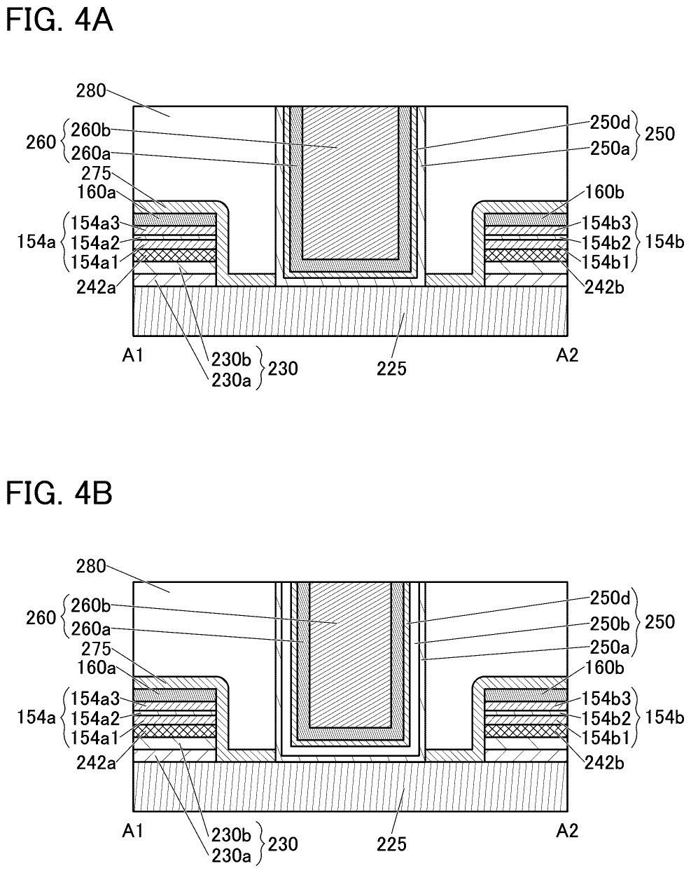

For example, as illustrated in FIG. 4A, the insulator 250 may have a two-layer structure. In that case, the insulator 250 preferably has a stacked-layer structure of the insulator 250a and the insulator 250d over the insulator 250a. A high-k material can be used for at least one of the insulator 250a and the insulator 250d. Thus, the equivalent oxide thicknesses (EOT) of the insulator 250a and the insulator 250d can be reduced while the thicknesses thereof are kept large enough to prevent a leakage current.

For example, as illustrated in FIG. 4B, the insulator 250 may have a three-layer structure. In that case, the insulator 250 preferably has a stacked-layer structure of the insulator 250a, the insulator 250b over the insulator 250a, and the insulator 250d over the insulator 250b. That is, the insulator 250b is further provided in the structure illustrated in FIG. 4A.

In this embodiment, in addition to the above-described structure, a structure that inhibits entry of hydrogen into the transistor 200 and the like is preferably employed. For example, one or both of upper and lower insulators having a function of inhibiting diffusion of hydrogen is/are preferably provided to cover the transistor 200 and the like. In the memory device described in this embodiment, the insulator corresponds to the insulator 283, the insulator 282, the insulator 222, and the insulator 221, for example. The insulator 215 provided below the transistor 200 may have a structure similar to the structure of one or both of the insulator 282 and the insulator 283. In such a case, the insulator 215 may have a stacked-layer structure of the insulator 282 and the insulator 283; the insulator 282 may be the lower layer and the insulator 283 may be the upper layer, or the insulator 282 may be the upper layer and the insulator 283 may be the lower layer.

One or more of the insulator 283, the insulator 282, the insulator 222, and the insulator 221 preferably function as a barrier insulator that inhibits diffusion of impurities such as water or hydrogen into the transistor 200 and the like from the substrate side or from above the transistor 200 and the like. Thus, one or more of the insulator 283, the insulator 282, the insulator 222, and the insulator 221 preferably include an insulating material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), or a copper atom (i.e., the insulating material through which the impurities are less likely to pass). Alternatively, it is preferable to include an insulating material having a function of inhibiting diffusion of oxygen (e.g., at least one of an oxygen atom, an oxygen molecule, and the like) (i.e., the insulating material through which the oxygen is less likely to pass).

Each of the insulator 283, the insulator 282, the insulator 222, and the insulator 221 preferably includes an insulator having a function of preventing diffusion of oxygen and impurities such as water and hydrogen. Examples of the insulator include aluminum oxide, magnesium oxide, hafnium oxide, zirconium oxide, oxide including aluminum and hafnium (hafnium aluminate), oxide including hafnium and zirconium (hafnium zirconium oxide), gallium oxide, indium gallium zinc oxide, silicon nitride, and silicon nitride oxide. For example, silicon nitride, which has a higher hydrogen barrier property, is preferably used for the insulator 283 and the insulator 221. For example, the insulator 282 preferably includes aluminum oxide or the like, which has a function of capturing and fixing hydrogen well. For example, hafnium oxide, which has high capability of capturing or fixing hydrogen and is a high permittivity (high-k) material, is preferably used for the insulator 222.

Such a structure can inhibit impurities such as water and hydrogen from diffusing into the transistor 200 or the like from an interlayer insulating film or the like placed above the insulator 283. Furthermore, impurities such as water and hydrogen can be inhibited from diffusing into the transistor 200 or the like from an interlayer insulating film or the like placed below the insulator 221. Moreover, hydrogen included in the insulator 280, the insulator 250, and the like can be captured and fixed in the insulator 282 or the insulator 222. Provision of the insulator 282 and the insulator 283 can inhibit oxygen included in the insulator 280 and the like from diffusing to the components above the transistor 200 or the like. Provision of the insulator 222 and the insulator 221 can prevent oxygen included in the oxide 230 and the like from diffusing to a region below the transistor 200 or the like. With such a structure where the transistor 200 is surrounded by upper and lower insulators having a function of inhibiting diffusion of oxygen and impurities such as water and hydrogen, excess oxygen and hydrogen can be prevented from diffusing into the oxide semiconductor. Thus, the memory device can have improved electrical characteristics and reliability.

Furthermore, silicon nitride, which has a high hydrogen-barrier property, is preferably used for the insulator 275 and the insulator 250d, for example. Aluminum oxide, which has high capability of capturing or fixing hydrogen, is preferably used for the insulator 250a, for example. Hafnium oxide, which has high capability of capturing or fixing hydrogen, is preferably used for the insulator 250c, for example.

The insulator 225 is formed over and in contact with the top surface of the insulator 222. As illustrated in FIG. 3B and the like, the insulator 225 has a shape with a high aspect ratio in the cross-sectional view in the channel width direction. Here, the aspect ratio of the insulator 225 in the cross-sectional view in the channel width direction refers to the ratio between a length L of the insulator 225 in the A3-A4 direction (also referred to as a width L of the insulator 225) and a length H of the insulator 225 in a direction perpendicular to the formation surface (e.g., the insulator 222) of the insulator 225 (also referred to as a height H of the insulator 225). In the insulator 225, the height H of the insulator 225 is at least larger than the width L of the insulator 225. The height H of the insulator 225 is larger than one time, preferably larger than or equal to two times, further preferably larger than or equal to five times, still further preferably larger than or equal to ten times the width L of the insulator 225. The height H of the insulator 225 is preferably smaller than or equal to 20 times the width L of the insulator 225.

In the region overlapping with the conductor 242 or the like, the oxide 230a, the oxide 230b, the conductor 242, the insulator 154, and the conductor 160 are provided to cover the insulator 225 having such a high aspect ratio. Thus, as illustrated in FIG. 5B, in the capacitor 100, the conductor 242a, the insulator 154a, and the conductor 160a are provided so as to be folded in half with the insulator 225 in between. Thus, in a cross-sectional view in the channel width direction, the conductor 242a and the conductor 160a face each other with the insulator 154a therebetween, above the insulator 225, along the side surface of the insulator 225 on the A5 side, and along the side surface of the insulator 225 on the A6 side each. That is, the capacitor 100 can be formed above the insulator 225, along the side surface of the insulator 225 on the A5 side, and along the side surface of the insulator 225 on the A6 side each. Thus, the area of the capacitor 100 is larger, by the side surface of the insulator 225 on the A5 side and the side surface of the insulator 225 on the A6 side, than that of the case where the insulator 225 is not provided.

The capacitor 100 can have a larger capacitance when the area of the capacitor 100 is increased as described above. In the above structure, provision of the insulator 225 enables the capacitance of the capacitor 100 to be increased without an increase in the area occupied by the capacitor. Accordingly, miniaturization or high integration of the memory device can be achieved. Moreover, the memory capacity of the memory device can be increased.

In the region not overlapping with the conductor 242 or the like, the sidewall-shaped oxide 230a and oxide 230b are provided along the side surface of the insulator 225 having such a high aspect ratio. Thus, in the vicinity of the channel formation region of the transistor 200, the oxide 230a and the oxide 230b that are divided into the portion on the A3 side and the portion on the A4 side by the insulator 225 are formed as illustrated in FIG. 3B. Furthermore, the insulator 250 and the conductor 260 are provided to cover the insulator 225, the oxide 230a, and the oxide 230b. Here, the oxide 230a and the oxide 230b are not in contact with the top surface of the insulator 225, and the insulator 250 is in contact with the top surface of the insulator 225. In a cross-sectional view in the channel width direction, the oxide 230 and the conductor 260 are provided to face each other with the insulator 250 therebetween, along the side surface on the A3 side and the side surface on the A4 side each. That is, the oxide 230b formed along each of the side surface of the insulator 225 on the A3 side and the side surface of the insulator 225 on the A4 side functions as a channel formation region. Thus, by increasing the side surface of the insulator 225 on the A3 side and the side surface of the insulator 225 on the A4 side, or by increasing the height H illustrated in FIG. 3B for example, the channel width of the transistor 200 can be increased.

The transistor 200 can have a favorable on-state current, favorable field-effect mobility, and favorable frequency characteristics when the channel width is increased as described above. Hence, a memory device that can operate at high speed can be provided. In the above structure, provision of the insulator 225 enables the channel width to be increased without an increase in the area occupied by the transistor 200. Accordingly, miniaturization or high integration of the memory device can be achieved. Moreover, the memory capacity of the memory device can be increased.

For the insulator 225, an insulating material that can be used for the insulator 222, the insulator 280, the insulator 250, or the like is used. Since the insulator 225 has a shape with a high aspect ratio, the insulator 225 is preferably formed in a sidewall shape along the side surface of a sacrificial layer (a later-described insulator 223). Accordingly, the insulator 225 is preferably formed by an ALD method that offers good coverage. For example, hafnium oxide deposited by a thermal ALD method can be used for the insulator 225.

When the insulator 225 is formed in a sidewall shape in contact with the side surface of the sacrificial layer in this manner, the insulator 225 of the transistor 200a and the capacitor 100a and the insulator 225 of the transistor 200b and the capacitor 100b can be formed at the same time as illustrated in FIG. 1A or the like. When the two insulators 225 are formed at the same time, the distance between the two insulators 225 can be set in accordance with the size of the sacrificial layer. Thus, the distance between the insulators 225 can be shortened, and the area occupied by the transistor 200a, the transistor 200b, the capacitor 100a, and the capacitor 100b can be reduced, leading to high integration of the memory device.

Note that the insulator 225 is not limited to only an insulating material in a strict sense. For example, a metal oxide with a relatively high insulating property can also be used. For example, a metal oxide that can be used as the oxide 230a may be used.

An upper portion of the insulator 225 may have a curved shape. Such a curved shape can prevent formation of defects such as voids in the oxide 230a, the oxide 230b, the conductor 242, the insulator 154, and the conductor 160 in the vicinity of the upper portion of the insulator 225. As illustrated in FIG. 3B, it is preferable that upper portions of the oxide 230a and the oxide 230b also have a curved shape in a region not overlapping with the conductor 242. Although the upper portion of the insulator 225 has a symmetrical structure with a curved shape on both the A3 side (the A5 side) and the A4 side (the A6 side) in FIG. 3B, FIG. 5B, and the like, the present invention is not limited thereto. For example, the upper portion of the insulator 225 may have an asymmetrical structure with a curved shape only on the A3 side (the A5 side).

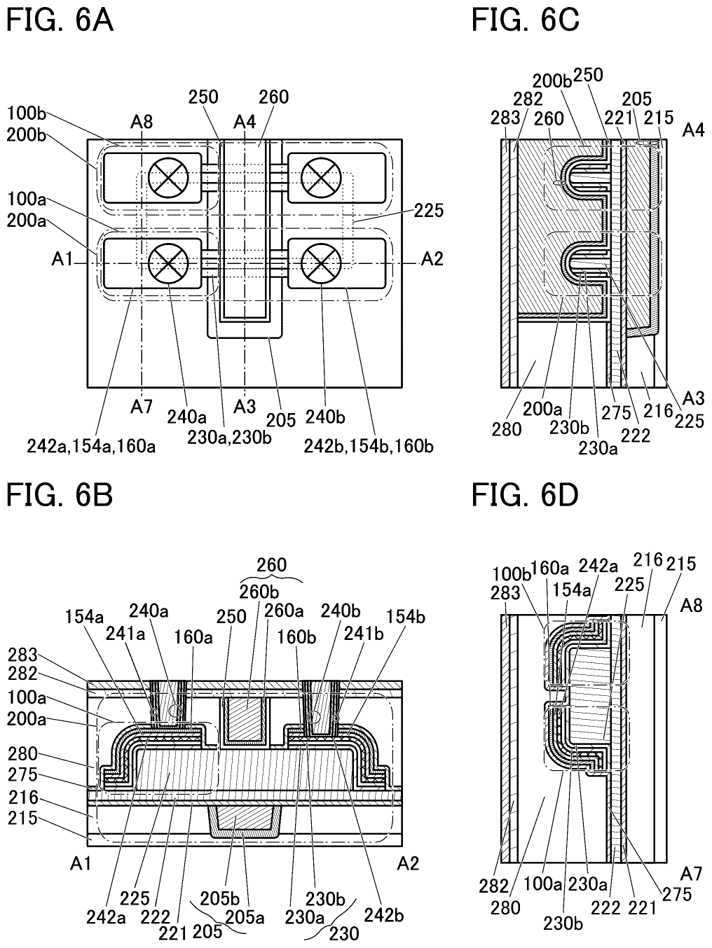

Although the insulator 225 is extended in the A1-A2 direction as illustrated in FIG. 1A and the like, the present invention is not limited thereto. For example, as illustrated in FIG. 6A to FIG. 6D, the insulator 225 may be provided perimetrically (also expressed as “in a frame shape” or “in a closed-curve shape”). FIG. 6A is a top view of the memory device. FIG. 6B to FIG. 6D are cross-sectional views of the memory device. Here, FIG. 6B is a cross-sectional view of a portion indicated by a dashed-dotted line A1-A2 in FIG. 6A. FIG. 6C is a cross-sectional view of a portion indicated by a dashed-dotted line A3-A4 in FIG. 6A. FIG. 6D is a cross-sectional view of a portion indicated by a dashed-dotted line A7-A8 in FIG. 6A. Note that some components are omitted in the top view in FIG. 6A for clarity of the drawing.

As illustrated in the cross section A7-A8 in FIG. 6D, the insulator 225 is a single component in the transistor 200a and the transistor 200b. Thus, the insulator 275 is in contact with the top surface of the insulator 225 between the transistor 200a and the transistor 200b. As described above, the insulator 225 is preferably formed in a sidewall shape in contact with the side surface of the sacrificial layer. In the memory device illustrated in FIG. 6A to FIG. 6D, a sacrificial layer is provided in a region surrounded by the insulator 225, whereby the insulator 225 is formed.

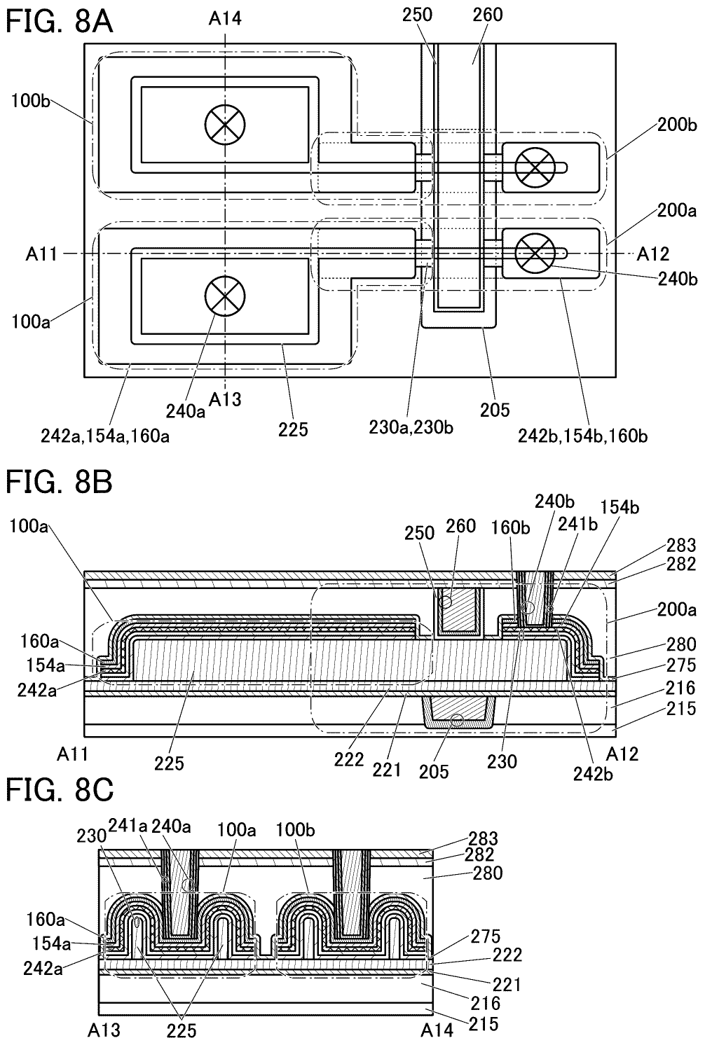

As illustrated in FIG. 8A to FIG. 8C, the insulator 225 may be extended to increase the area of the capacitor 100. FIG. 8A is a top view of the above memory device. FIG. 8B and FIG. 8C are cross-sectional views of the memory device. Here, FIG. 8B is a cross-sectional view of a portion indicated by the dashed-dotted line A11-A12 in FIG. 8A. FIG. 8C is a cross-sectional view of a portion indicated by the dashed-dotted line A13-A14 in FIG. 8A. Note that for clarity of the drawing, some components are omitted in the top view of FIG. 8A. For clarity of the drawing, the insulator 225 is shown by a solid line in the top view of FIG. 8A.

In the structure illustrated in FIG. 8A to FIG. 8C, the area of the capacitor 100 is increased by extending the insulator 225 perimetrically in a region where the capacitor 100 is formed. As illustrated in FIG. 8C, a region where the conductor 242a, the insulator 154a, and the conductor 160a overlap with the insulator 225 is larger than that in the structure illustrated in FIG. 1A to FIG. 1D. Thus, the size of the capacitor 100 formed along the side surface of the insulator 225 is increased, so that the capacitance of the capacitor 100 can be significantly increased as compared with the area of the capacitor 100 in the top view.

In the transistor 200, the conductor 205 is placed to overlap with the oxide 230 and the conductor 260. Here, the conductor 205 is preferably provided to be embedded in an opening portion formed in the insulator 216. Moreover, the conductor 205 is preferably provided to extend in the channel width direction as illustrated in FIG. 1A and FIG. 1C. With such a structure, the conductor 205 functions as a wiring when a plurality of transistors are provided.

As illustrated in FIG. 1B and FIG. 1C, the conductor 205 preferably includes the conductor 205a and the conductor 205b. The conductor 205a is provided in contact with the bottom surface and the sidewall of the opening portion. The conductor 205b is provided to fill a depressed portion that is defined by the conductor 205a and formed along the opening portion. Here, the top surface of the conductor 205 is level or substantially level with the top surface of the insulator 216.

Here, the conductor 205a preferably includes a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, and the like), and a copper atom. Alternatively, it is preferable to include a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen included in the conductor 205b can be prevented from diffusing into the oxide 230 through the insulator 216 and the like. When a conductive material having a function of inhibiting diffusion of oxygen is used for the conductor 205a, the conductivity of the conductor 205b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 205a can have a single-layer structure or a stacked-layer structure of the above conductive material. For example, the conductor 205a preferably includes titanium nitride. The conductor 205b is preferably formed using a conductive material including tungsten, copper, or aluminum as its main component. For example, the conductor 205b preferably includes tungsten.

The conductor 205 can function as the second gate electrode. In that case, by changing a potential applied to the conductor 205 not in conjunction with but independently of a potential applied to the conductor 260, the threshold voltage (Vₜₕ) of the transistor 200 can be controlled. In particular, by applying a negative potential to the conductor 205, Vₜₕ of the transistor 200 can be higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electrical resistivity of the conductor 205 is designed in consideration of the potential applied to the conductor 205, and the thickness of the conductor 205 is set in accordance with the electrical resistivity. The thickness of the insulator 216 is substantially equal to that of the conductor 205. Here, the conductor 205 and the insulator 216 are preferably as thin as possible in the allowable range of the design of the conductor 205. When the thickness of the insulator 216 is reduced, the absolute amount of impurities such as hydrogen included in the insulator 216 can be reduced, inhibiting diffusion of the impurities into the oxide 230.

Although the stacked-layer structure of the conductor 205a and the conductor 205b is described above, the present invention is not limited to this structure. The conductor 205 may have a single-layer structure or a stacked-layer structure of three or more layers. For example, in the case where the conductor 205 has a three-layer structure, a conductor that includes the same material as the conductor 205a can be further provided over the conductor 205b of the above-described stacked-layer structure of the conductors 205a and 205b. In that case, the level of the top surface of the conductor 205b may be lower than the level of the uppermost portion of the conductor 205a, and the aforementioned conductor may be formed to fill the depressed portion formed by the conductor 205a and the conductor 205b.

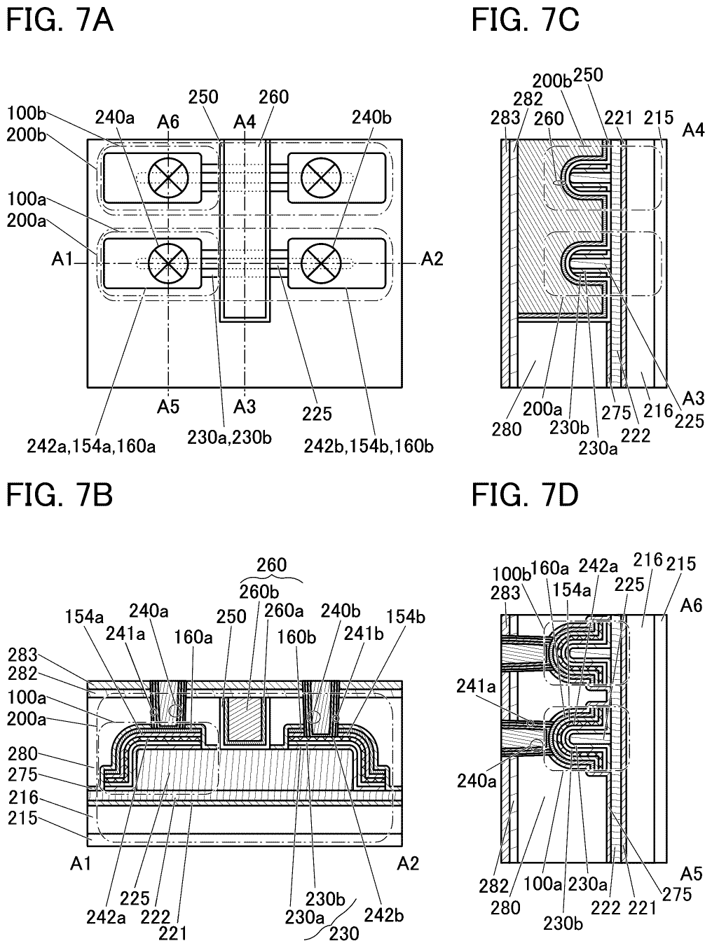

As illustrated in FIG. 7A to FIG. 7D, the memory device of this embodiment may have a structure in which the conductor 205 is not provided. Here, in the transistor 200, the oxide 230 is in contact with both the side surface of the insulator 225 on the A3 side and the side surface of the insulator 225 on the A4 side as illustrated in FIG. 3B. Thus, portions of the conductor 260 positioned to face each other with the insulator 225 in between have an effect on the oxide 230 that is similar to the effect of the conductor 205 in some cases. Thus, as illustrated in FIG. 7A to FIG. 7D, part of the conductor 260 functions as the second gate electrode in some cases even when the conductor 205 is not provided.

A conductive material that is less likely to be oxidized or a conductive material having a function of inhibiting diffusion of oxygen is preferably used for each of the conductor 242a, the conductor 242b, and the conductor 260. Examples of the conductive material include a conductive material including nitrogen and a conductive material including oxygen. Thus, a decrease in the conductivity of the conductor 242a, the conductor 242b, and the conductor 260 can be inhibited. In the case where a conductive material including metal and nitrogen is used for the conductor 242a, the conductor 242b, and the conductor 260, the conductor 242a, the conductor 242b, and the conductor 260 are conductors that include at least metal and nitrogen.

The conductor 242a and the conductor 242b are placed apart from each other and over and in contact with the oxide 230b. As illustrated in FIG. 5A, FIG. 5B, and the like, the conductor 242 is provided to cover the insulator 225 having a high aspect ratio. Thus, the conductor 242 is preferably deposited by a deposition method that offers good coverage, such as an ALD method or a CVD method. Here, as illustrated in FIG. 5B, in the cross section in the channel width direction, the conductor 242 is formed to be folded in half with the insulator 225 in between. With such a structure, the capacitor 100 can be formed along a portion above the insulator 225 and the side surface on the A5 side and the side surface on the A6 side of the insulator 225; thus, the capacitance per unit area can be increased.

A conductive material that is less likely to be oxidized or a conductive material having a function of inhibiting diffusion of oxygen is preferably used for each of the conductor 242a and the conductor 242b since the conductor 242a and the conductor 242b are in contact with the oxide 230b. Thus, a decrease in the conductivity of the conductors 242a and 242b can be inhibited. Oxygen can be prevented from being extracted from the oxide 230b, that is, an excessive amount of oxygen vacancies can be inhibited from being formed. For the conductors 242a and 242b, a material that is likely to absorb (extract) hydrogen is preferably used, in which case the hydrogen concentration in the oxide 230 can be reduced.

For the conductor 242, a metal nitride is preferably used; for example, a nitride including tantalum, a nitride including titanium, a nitride including molybdenum, a nitride including tungsten, a nitride including tantalum and aluminum, or a nitride including titanium and aluminum is preferably used. In one embodiment of the present invention, a nitride including tantalum is particularly preferable. As another example, ruthenium, ruthenium oxide, ruthenium nitride, an oxide including strontium and ruthenium, or an oxide including lanthanum and nickel may be used. These materials are preferable because they are each a conductive material that is less likely to be oxidized or a material that maintains the conductivity even after absorbing oxygen.

Note that hydrogen included in the oxide 230b or the like diffuses into the conductor 242a or the conductor 242b in some cases. In particular, when a nitride including tantalum is used for the conductor 242a and the conductor 242b, hydrogen included in the oxide 230b or the like is likely to diffuse into the conductor 242a or the conductor 242b, and the diffused hydrogen is bonded to nitrogen included in the conductor 242a or the conductor 242b in some cases. That is, hydrogen included in the oxide 230b or the like is absorbed by the conductor 242a or the conductor 242b in some cases.

The conductor 242 may have a stacked-layer structure. In that case, a layer of a conductive material having high conductivity may be formed over a layer of the above-described conductive material that is unlikely to be oxidized. As the conductive material having high conductivity, a conductive material that can be used for the conductor 205b may be used. For example, the conductor 242 can have a two-layer structure of a tantalum nitride film and a tungsten film over the tantalum nitride film. This can increase the on-state current of the transistor 200 and improve the operation speed of the memory device of this embodiment.

To inhibit a reduction in the conductivity of the conductor 242a and the conductor 242b, an oxide having crystallinity, such as a CAAC-OS, is preferably used for the oxide 230b. Specifically, a metal oxide including indium, zinc, and one or more selected from gallium, aluminum, and tin is preferably used. When a CAAC-OS is used, oxygen extraction from the oxide 230b by the conductor 242a or the conductor 242b can be inhibited. Furthermore, it is possible to inhibit a reduction in the conductivity of the conductor 242a and the conductor 242b.

As illustrated in FIG. 1B and FIG. 1C, the conductor 260 is placed in the opening formed in the insulator 280 and the insulator 275. The conductor 260 is provided in the opening to cover the top surface of the insulator 225, the top surface of the insulator 222, the side surface of the oxide 230a, the side surface of the oxide 230b, and the top surface of the oxide 230b, with the insulator 250 therebetween. The top surface of the conductor 260 is placed to be level with or substantially level with the uppermost portion of the insulator 250 and the top surface of the insulator 280.

Note that the sidewall of the opening in which the conductor 260 and the insulator 250 are placed may be perpendicular or substantially perpendicular to the top surface of the insulator 222 or may have a tapered shape. The tapered shape of the sidewall can improve the coverage with the insulator 250 and the like provided in the opening in the insulator 280, whereby defects such as voids can be reduced.

The conductor 260 functions as the first gate electrode of the transistor 200. Here, the conductor 260 is preferably provided to extend in the channel width direction as illustrated in FIG. 1A and FIG. 1C. With such a structure, the conductor 260 functions as a wiring when a plurality of transistors are provided.

Note that in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect is less likely to occur can be provided.

When the transistor 200 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can correspond to the entire bulk of the oxide 230. Accordingly, the density of current flowing through the transistor can be increased, which can be expected to increase the on-state current of the transistor or increase the field-effect mobility of the transistor.

FIG. 1B and the like illustrate the conductor 260 having a two-layer structure. Here, the conductor 260 preferably includes the conductor 260a and the conductor 260b placed over the conductor 260a. For example, the conductor 260a is preferably placed to cover the bottom surface and the side surface of the conductor 260b. In this case, a conductive material that is less likely to be oxidized or a conductive material having a function of inhibiting diffusion of oxygen is preferably used for the conductor 260a.

The conductor 260a is preferably formed using a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

When the conductor 260a has a function of inhibiting diffusion of oxygen, the conductivity of the conductor 260b can be inhibited from being lowered because of oxidation due to oxygen included in the insulator 280 or the like. As the conductive material having a function of inhibiting diffusion of oxygen, titanium, titanium nitride, tantalum, tantalum nitride, ruthenium, or ruthenium oxide is preferably used, for example.

As the conductor 260b, a conductor having high conductivity is preferably used. For example, the conductor 260b can be formed using a conductive material including tungsten, copper, or aluminum as its main component. The conductor 260b may have a stacked-layer structure; for example, a stacked-layer structure of titanium or titanium nitride and the above conductive material may be employed.

The insulator 154a and the insulator 154b are placed apart from each other. The insulator 154a is provided over and in contact with the conductor 240a, and the insulator 154b is provided over and in contact with the conductor 240b. As illustrated in FIG. 5A, FIG. 5B, and the like, the insulator 154 is provided to cover the insulator 225 having a high aspect ratio. Thus, the insulator 154 is preferably deposited by a deposition method that offers good coverage, such as an ALD method or a CVD method. Here, as illustrated in FIG. 5B, in the cross section in the channel width direction, the insulator 154 is formed to be folded in half with the insulator 225 in between. With such a structure, the capacitor 100 can be formed along a portion above the insulator 225 and the side surface on the A5 side and the side surface on the A6 side of the insulator 225; thus, the capacitance per unit area can be increased.

For the insulator 154, a high permittivity (high-k) material (material with a high relative permittivity) is preferably used. As the insulator of the high permittivity (high-k) material, an oxide, an oxynitride, a nitride oxide, or a nitride including one or more metal elements selected from aluminum, hafnium, zirconium, gallium, and the like can be used, for example. The above-described oxide, oxynitride, nitride oxide, or nitride may include silicon. Insulating layers each formed of any of the above-described materials can be stacked to be used.

As the insulator of high permittivity (high-k) material, aluminum oxide, hafnium oxide, zirconium oxide, an oxide including aluminum and hafnium, an oxynitride including aluminum and hafnium, an oxide including silicon and hafnium, an oxynitride including silicon and hafnium, an oxide including silicon and zirconium, an oxynitride including silicon and zirconium, an oxide including hafnium and zirconium, an oxynitride including hafnium and zirconium, or the like can be used, for example. Using such a high-k material allows the insulator 154 to be thick enough to inhibit a leakage current and the capacitor 100 to have sufficiently large capacitance.

It is preferable to use stacked insulating layers formed of any of the above-described materials, and it is preferable to use a stacked-layer structure of a high permittivity (high-k) material and a material having a higher dielectric strength than the high permittivity (high-k) material. For example, in the case where the insulator 154 has a structure in which an insulator 154a1, an insulator 154a2, and an insulator 154a3 are stacked in this order as illustrated in FIG. 5A and FIG. 5B, zirconium oxide can be used for the insulator 154al and the insulator 154a3, and aluminum oxide can be used for the insulator 154a2. Alternatively for example, as the insulator 154, an insulating film in which zirconium oxide, aluminum oxide, zirconium oxide, and aluminum oxide are stacked in this order can be used. Alternatively for example, as the insulator 154, an insulating film in which hafnium zirconium oxide, aluminum oxide, hafnium zirconium oxide, and aluminum oxide are stacked in this order can be used. Using such stacked insulators with relatively high dielectric strength, such as aluminum oxide, can increase the dielectric strength and inhibit electrostatic breakdown of the capacitor 100.

The conductor 160a and the conductor 160b are placed apart from each other. The conductor 160a is provided over and in contact with the insulator 154a, and the conductor 160b is provided over and in contact with the insulator 154b. As illustrated in FIG. 5A, FIG. 5B, and the like, the conductor 160 is provided to cover the insulator 225 having a high aspect ratio. Thus, the conductor 160 is preferably deposited by a deposition method that offers good coverage, such as an ALD method or a CVD method. Here, as illustrated in FIG. 5B, in the cross section in the channel width direction, the conductor 160 is formed to be folded in half with the insulator 225 in between. With such a structure, the capacitor 100 can be formed along a portion above the insulator 225 and the side surface on the A5 side and the side surface on the A6 side of the insulator 225; thus, the capacitance per unit area can be increased.

A conductor that can be used as the conductor 205, the conductor 260, or the conductor 242 is used as the conductor 160. Titanium nitride or tantalum nitride can be used as the conductor 160, for example.

Note that the insulator 154b and the conductor 160b do not function as a capacitor but are formed in parallel with the insulator 154a and the conductor 160a, thereby having a structure similar to that of the insulator 154a and the conductor 160a. For example, in the case where the insulator 154a has a structure in which the insulator 154a1, the insulator 154a2, and the insulator 154a3 are stacked in this order, the insulator 154b has a structure in which an insulator 154b1, an insulator 154b2, and an insulator 154b3 are stacked in this order.

The insulator 216 and the insulator 280 each preferably have a lower permittivity than the insulator 222. When a material with a low permittivity is used for an interlayer film, parasitic capacitance generated between wirings can be reduced.

For example, the insulator 216 and the insulator 280 each preferably include one or more of silicon oxide, silicon oxynitride, silicon oxide to which fluorine is added, silicon oxide to which carbon is added, silicon oxide to which carbon and nitrogen are added, and porous silicon oxide. In particular, silicon oxide and silicon oxynitride, which are thermally stable, are preferable. A material such as silicon oxide, silicon oxynitride, or porous silicon oxide is particularly preferably used, in which case a region including oxygen that is released by heating can be easily formed.

The top surfaces of the insulator 216 and the insulator 280 may be planarized.

The concentration of impurities such as water or hydrogen in the insulator 280 is preferably reduced. For example, the insulator 280 preferably includes an oxide including silicon, such as silicon oxide or silicon oxynitride.

The conductor 240a is formed in an opening in the insulator 275, the insulator 280, the insulator 282, and the insulator 283. The bottom surface of the conductor 240a is in contact with the top surface of the conductor 160a. The conductor 240b is formed in an opening in the insulator 154b, the conductor 160b, the insulator 275, the insulator 280, the insulator 282, and the insulator 283. The bottom surface of the conductor 240b is in contact with the top surface of the conductor 242b. Here, the level of the top surface of the conductor 240 and the level of the top surface of the insulator 283 are substantially the same.

For the conductor 240, a conductive material including tungsten, copper, or aluminum as its main component is preferably used. The conductor 240, the conductor 240 may have a stacked-layer structure in which a first conductor is provided in contact with the side surface of the insulator 241 and a second conductor is provided on the inner side of the first conductor. In that case, the above-described material can be used for the second conductor.

In the case where the conductor 240 has a stacked-layer structure, a conductive material having a function of inhibiting passage of impurities such as water and hydrogen is preferably used for a first conductor placed in the vicinity of the insulator 283, the insulator 282, the insulator 280, and the insulator 275. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. With such a structure, impurities such as water and hydrogen included in a layer above the insulator 283 can be inhibited from entering the oxide 230 through the conductor 240a and the conductor 240b.

The insulator 241a is formed in contact with an inner wall of the opening in the insulator 275, the insulator 280, the insulator 282, and the insulator 283. The inner side surface of the insulator 241a is in contact with the conductor 240a. The insulator 241b is formed in contact with an inner wall of the opening in the insulator 154b, the conductor 160b, the insulator 275, the insulator 280, the insulator 282, and the insulator 283. The inner side surface of the insulator 241b is in contact with the conductor 240b.

For the insulator 241, a barrier insulating film that can be used for the insulator 275 or the like may be used. For the insulator 241, for example, an insulator such as silicon nitride, aluminum oxide, or silicon nitride oxide may be used. With the provision of the insulator 241, impurities such as water and hydrogen included in the insulator 280 or the like can be inhibited from entering the oxide 230 through the conductor 240a and the conductor 240b. In particular, silicon nitride is suitable because of its high blocking property against hydrogen. Furthermore, oxygen included in the insulator 280 can be prevented from being absorbed by the conductor 240a and the conductor 240b.

When the insulator 241 has a stacked-layer structure illustrated in FIG. 1B, a first insulator in contact with an inner wall of the opening formed in the insulator 280 and the like and a second insulator on the inner side of the first insulator are preferably formed using a combination of an oxygen-barrier insulating film and a hydrogen-barrier insulating film.

For example, aluminum oxide deposited by a thermal ALD method is used for the first insulator and silicon nitride deposited by a PEALD method is used for the second insulator. With this structure, oxidation of the conductor 240 can be inhibited, and hydrogen can be inhibited from entering the conductor 240.

Note that it is preferable that the conductor 240b not be brought into conduction with the conductor 160b because the conductor 240b functions as a contact plug for one of a source and a drain of the transistor 200. Thus, as illustrated in FIG. 1B and the like, it is preferable that the insulator 241b be provided between the conductor 240b and the conductor 160b.

Although the structure in which the insulator 241 has a stacked-layer structure of two layers is described above, the present invention is not limited thereto. For example, the insulator 241 may have a single-layer structure or a stacked-layer structure of three or more layers. Although the structure in which the conductor 240 has a stacked-layer structure of two layers is described above, the present invention is not limited thereto. For example, the conductor 240 may have a single-layer structure or a stacked-layer structure of three or more layers.

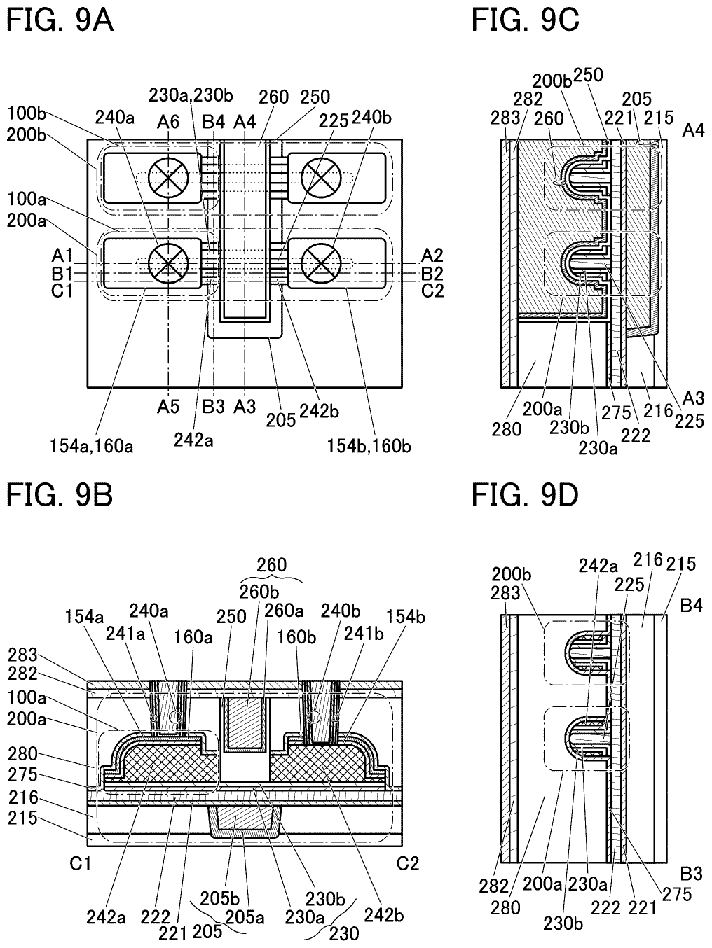

In the above-described structure, the conductor 242a is aligned or substantially aligned with the insulator 154a and the conductor 160a and the conductor 242b is aligned or substantially aligned with the insulator 154b and the conductor 160b in the top view as illustrated in FIG. 1A and the like; however, the present invention is not limited thereto. For example, as illustrated in FIG. 9A to FIG. 9D, part of the conductor 242a and part of the conductor 242b may be formed in a region not overlapping with the conductor 160a, the conductor 160b, or the like. FIG. 9A is a top view of the memory device. FIG. 9B to FIG. 9D are cross-sectional views of the memory device. Here, FIG. 9B is a cross-sectional view of a portion indicated by a dashed-dotted line C1-C2 in FIG. 9A. FIG. 9C is a cross-sectional view of a portion indicated by a dashed-dotted line A3-A4 in FIG. 9A. FIG. 9D is a cross-sectional view of a portion indicated by a dashed-dotted line B3-B4 in FIG. 9A. Note that FIG. 1B can be referred to for a cross-sectional view of a portion indicated by a dashed-dotted line A1-A2 in FIG. 9A, FIG. 2 can be referred to for a cross-sectional view of a portion indicated by a dashed-dotted line B1-B2 in FIG. 9A, and FIG. 1D can be referred to for a cross-sectional view of a portion indicated by a dashed-dotted line A5-A6 in FIG. 9A. For clarity of the drawing, some components are not illustrated in the top view of FIG. 9A.

As illustrated in FIG. 9A, FIG. 9B, and FIG. 9D, part of the conductor 242a and part of the conductor 242b are each formed in a sidewall shape along the side surface of the oxide 230a in a region between the conductor 160a (the conductor 160b) and the insulator 250. Thus, the side surfaces and the bottom surfaces of part of the conductor 242a and part of the conductor 242b are in contact with the oxide 230b. Furthermore, in the region between the conductor 160a (the conductor 160b) and the insulator 250, the conductor 242a (the conductor 242b), the oxide 230b, the oxide 230a, and the insulator 225 are covered with the insulator 275. As illustrated in FIG. 9B, an end portion of the conductor 242a on the C2 side and an end portion of the conductor 242b on the C1 side are in contact with the insulator 250. As illustrated in FIG. 9C, lower portions of the oxide 230a and the oxide 230b may be formed to protrude beyond the side surface of an upper portion of the oxide 230b toward the A3 side or the A4 side.

With the structure illustrated in FIG. 9A to FIG. 9D, the distance between the conductor 242a and the conductor 242b can be reduced, so that the channel length of the transistor 200 can be shortened. Accordingly, the on-state current, field-effect mobility, and frequency characteristics of the transistor 200 can be improved, and a memory device with high operation speed can be provided.

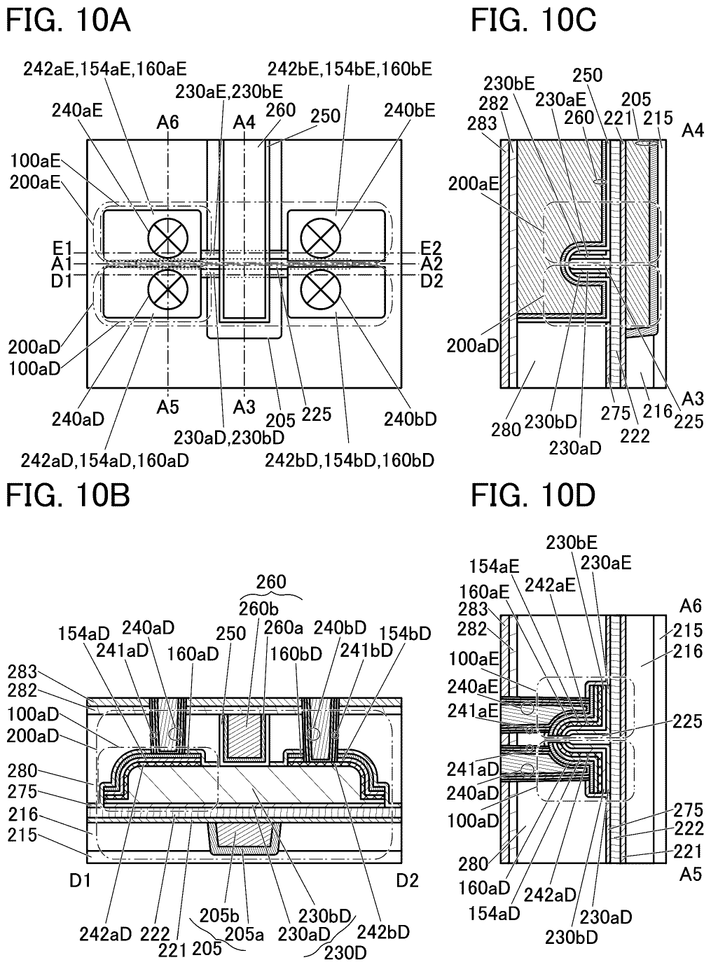

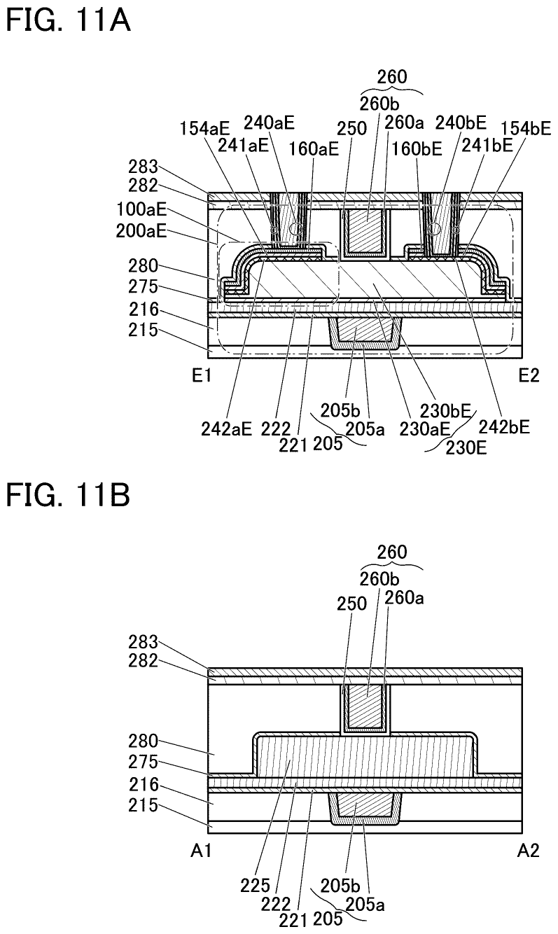

In the above-described structure, as illustrated in FIG. 1D or the like, the oxide 230a, the oxide 230b, the conductor 242a, the conductor 242b, the insulator 154a, the insulator 154b, the conductor 160a, and the conductor 160b are folded in half with the insulator 225 in between in the vicinity of the source or the drain of the transistor 200; however, the present invention is not limited thereto. For example, as illustrated in FIG. 10A to FIG. 10D and FIG. 11A and FIG. 11B, the oxide 230a, the oxide 230b, the conductor 242a, the conductor 242b, the insulator 154a, the insulator 154b, the conductor 160a, and the conductor 160b can each be divided into the portion on the A3 side and the portion on the A4 side with a dashed-dotted line A1-A2 as a boundary. FIG. 10A is a top view of the memory device. FIG. 10B to FIG. 10D and FIG. 11A and FIG. 11B are cross-sectional views of the memory device. Here, FIG. 10B is a cross-sectional view of a portion indicated by a dashed-dotted line D1-D2 in FIG. 10A. FIG. 10C is a cross-sectional view of a portion indicated by a dashed-dotted line A3-A4 in FIG. 10A. FIG. 10D is a cross-sectional view of a portion indicated by a dashed-dotted line A5-A6 in FIG. 10A. FIG. 11A is a cross-sectional view of a portion indicated by a dashed-dotted line E1-E2 in FIG. 10A. FIG. 11B is a cross-sectional view of a portion indicated by the dashed-dotted line A1-A2 in FIG. 10A. For clarity of the drawing, some components are not illustrated in the top view of FIG. 10A.

The memory device illustrated in FIG. 10A to FIG. 10D and FIG. 11A and FIG. 11B includes a transistor 200aD and a capacitor 100aD on the A3 side and a transistor 200aE and a capacitor 100aE on the A4 side, with the dashed-dotted line A1-A2 (the insulator 225) as a boundary. That is, this structure is obtained by dividing the transistor 200a into the transistor 200aD and the transistor 200aE and dividing the capacitor 100a into the capacitor 100aD and the capacitor 100aE in the memory device illustrated in FIG. 1A to FIG. 1D and FIG. 2 without a significant increase in the area. Note that although the components corresponding to the transistor 200b and the capacitor 100b of the memory device illustrated in FIG. 1A to FIG. 1D and FIG. 2 are not illustrated in the memory device illustrated in FIG. 10A to FIG. 10D and FIG. 11A and FIG. 11B, the components corresponding to the transistor 200b and the capacitor 100b can also be provided as in the memory device illustrated in FIG. 1A to FIG. 1D and FIG. 2.

Thus, the components of the memory device illustrated in FIG. 10A to FIG. 10D and FIG. 11A and FIG. 11B are denoted by the reference numerals of the components of the memory device illustrated in FIG. 1A to FIG. 1D and FIG. 2 to each of which D or E is added. That is, the components included in the transistor 200aD and the capacitor 100aD on the A3 side are an oxide 230D (an oxide 230aD and an oxide 230bD), a conductor 242aD, a conductor 242bD, an insulator 154aD, an insulator 154bD, a conductor 160aD, a conductor 160bD, a conductor 240aD, a conductor 240bD, an insulator 241aD, and an insulator 241bD. The components included in the transistor 200aE and the capacitor 100aE on the A4 side are an oxide 230E (an oxide 230aE and an oxide 230bE), a conductor 242aE, a conductor 242bE, an insulator 154aE, an insulator 154bE, a conductor 160aE, a conductor 160bE, a conductor 240aE, a conductor 240bE, an insulator 241aE, and an insulator 241bE. The above description can be referred to for the details of these components.

As illustrated in FIG. 10B and FIG. 10C, over the insulator 225, the oxide 230aD, the oxide 230bD, the conductor 242aD (the conductor 242bD), the insulator 154aD (the insulator 154bD), and the conductor 160aD (the conductor 160bD) are provided apart from the oxide 230aE, the oxide 230bE, the conductor 242aE (the conductor 242bE), the insulator 154aE (the insulator 154bE), and the conductor 160aE (the conductor 160bE). Thus, as illustrated in FIG. 11B, the oxide 230aD, the oxide 230bD, the conductor 242aD, the conductor 242bD, the insulator 154aD, the insulator 154bD, the conductor 160aD, the conductor 160bD, the oxide 230aE, the oxide 230bE, the conductor 242aE, the conductor 242bE, the insulator 154aE, the insulator 154bE, the conductor 160aE, and the conductor 160bE are not formed above at least part of the insulator 225.

As illustrated in FIG. 10B, the oxide 230D (the oxide 230aD and the oxide 230bD) is formed in contact with the side surface of the insulator 225 on the A3 side, and a channel formation region is provided in the oxide 230bD. Similarly, as illustrated in FIG. 11A, the oxide 230E (the oxide 230aE and the oxide 230bE) is formed in contact with the side surface of the insulator 225 on the A4 side, and a channel formation region is provided in the oxide 230bE.

With the structure illustrated in FIG. 10A to FIG. 10D and FIG. 11A and FIG. 11B, twice as many memory cells can be formed without a significant increase in the area. Thus, the memory device can be miniaturized or highly integrated. In addition, the memory capacity of the memory device can be increased.

### <Component Materials of Memory Device>

Component materials that can be used for the memory device are described below. Note that each layer included in the memory device may have a single-layer structure or a stacked-layer structure.

### <<Substrate>>

As a substrate where the transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is the above-described semiconductor substrate including an insulator region, e.g., an SOI (Silicon On Insulator) substrate. Examples of the conductor substrate include a graphite substrate, a metal substrate, an alloy substrate, and a conductive resin substrate. Other examples of substrates include a substrate including a metal nitride, a substrate including a metal oxide, an insulator substrate provided with a conductor or a semiconductor, a semiconductor substrate provided with a conductor or an insulator, and a conductor substrate provided with a semiconductor or an insulator. Alternatively, these substrates provided with one or more kinds of elements may be used. Examples of the element provided for the substrate include a capacitor, a resistor, a switching element, a light-emitting element, and a memory element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. In contrast, when a material with a low relative permittivity is used for the insulator functioning as an interlayer film, parasitic capacitance generated between wirings can be reduced. Thus, a material is preferably selected depending on the function of the insulator.

Examples of the insulator with a high relative permittivity include gallium oxide, hafnium oxide, zirconium oxide, an oxide including aluminum and hafnium, an oxynitride including aluminum and hafnium, an oxide including silicon and hafnium, an oxynitride including silicon and hafnium, and a nitride including silicon and hafnium.

Examples of the insulator with a low relative permittivity include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator including, for example, one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum can be used. Specific examples of the insulator having a function of inhibiting passage of oxygen and impurities such as hydrogen include a metal oxide such as aluminum oxide, magnesium oxide, gallium oxide, germanium oxide, yttrium oxide, zirconium oxide, lanthanum oxide, neodymium oxide, hafnium oxide, or tantalum oxide and a metal nitride such as aluminum nitride, silicon nitride oxide, or silicon nitride.

The insulator functioning as the gate insulator is preferably an insulator including a region including oxygen to be released by heating. For example, when a structure is employed in which silicon oxide or silicon oxynitride including a region including oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy including any of the above metal elements; an alloy including a combination of the above metal elements; or the like. Examples of the conductor include tantalum nitride, titanium nitride, tungsten, a nitride including titanium and aluminum, a nitride including tantalum and aluminum, ruthenium oxide, ruthenium nitride, an oxide including strontium and ruthenium, and an oxide including lanthanum and nickel. Tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are conductive materials that are less likely to be oxidized or materials that maintain their conductivity even after absorbing oxygen. Alternatively, a semiconductor having high electrical conductivity, typified by polycrystalline silicon including an impurity element such as phosphorus, or silicide such as nickel silicide may be used.

In the case of using a conductor having a stacked-layer structure, for example, a stacked-layer structure combining a material including the above metal element and a conductive material including oxygen, a stacked-layer structure combining a material including the above metal element and a conductive material including nitrogen, or a stacked-layer structure combining a material including the above metal element, a conductive material including oxygen, and a conductive material including nitrogen may be employed.

In the case where an oxide is used for the channel formation region of the transistor, the conductor functioning as the gate electrode preferably employs a stacked-layer structure combining a material including the above-described metal element and a conductive material including oxygen. In that case, the conductive material including oxygen is preferably provided on the channel formation region side. When the conductive material including oxygen is provided on the channel formation region side, oxygen released from the conductive material is easily supplied to the channel formation region.

It is particularly preferable to use, for the conductor functioning as the gate electrode, a conductive material including oxygen and a metal element included in the metal oxide where the channel is formed. A conductive material including the above metal element and nitrogen may be used. For example, a conductive material including nitrogen, such as titanium nitride or tantalum nitride, may be used. One or more of indium tin oxide, indium oxide including tungsten oxide, indium zinc oxide including tungsten oxide, indium oxide including titanium oxide, indium tin oxide including titanium oxide, indium zinc oxide, and indium tin oxide to which silicon is added may be used. Indium gallium zinc oxide including nitrogen may be used. With the use of such a material, hydrogen included in the metal oxide where the channel is formed can be captured in some cases. Alternatively, hydrogen entering from an external insulator or the like can be captured in some cases.

### <<Metal Oxide>>

For the oxide 230, a metal oxide functioning as a semiconductor (an oxide semiconductor) is preferably used. A metal oxide that can be used for the oxide 230 of one embodiment of the present invention will be described below.

The metal oxide preferably includes at least indium or zinc. In particular, indium and zinc are preferably included. Moreover, aluminum, gallium, yttrium, tin, antimony, or the like is preferably included in addition to them. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be included.

Here, the case where the metal oxide is an In-M-Zn oxide including indium, an element M, and zinc is considered. The element M is aluminum, gallium, yttrium, tin, or antimony. Examples of other elements that can be used as the element M include boron, titanium, iron, nickel, germanium, zirconium, molybdenum, lanthanum, cerium, neodymium, hafnium, tantalum, tungsten, magnesium, and cobalt. Note that a combination of two or more of the above elements may be used as the element M. In particular, the element M is preferably one or more kinds selected from gallium, aluminum, yttrium, and tin.

Note that in this specification and the like, a metal oxide including nitrogen is also collectively referred to as a metal oxide in some cases. A metal oxide including nitrogen may be referred to as a metal oxynitride.

Hereinafter, an In—Ga—Zn oxide is described as an example of the metal oxide.

Examples of crystal structures of an oxide semiconductor include amorphous (including completely amorphous), CAAC (c-axis-aligned crystalline), nc (nanocrystalline), CAC (cloud-aligned composite), single crystal, and polycrystalline structures.

Note that oxide semiconductors might be classified in a manner different from the above-described one when classified in terms of the structure. For example, oxide semiconductors are classified into a single crystal oxide semiconductor and a non-single-crystal oxide semiconductor. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. Note that as illustrated in FIG. 3B and the like, in a region where the oxide 230 is in contact with the insulator 225, the c-axis is preferably aligned in the normal direction of the surface of the film of the insulator 225. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter of less than 10 nm). In the case where the crystal region is formed of one minute crystal, the maximum diameter of the crystal region is less than nm. In the case where the crystal region is formed of a large number of minute crystals, the maximum diameter of the crystal region may be approximately several tens of nanometers.

The CAAC-OS is an oxide semiconductor with high crystallinity in which no clear grain boundary is observed. Thus, in the CAAC-OS, a reduction in electron mobility due to the grain boundary is less likely to occur. Moreover, since the crystallinity of an oxide semiconductor might be decreased by entry of impurities, formation of defects, or the like, the CAAC-OS can also be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperatures in the manufacturing process (what is called thermal budget). Accordingly, the use of the CAAC-OS for an OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

[a-like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter also referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

In a material composition of a CAC-OS in an In—Ga—Zn oxide that includes In, Ga, Zn, and O, there are regions including In as a main component (first regions) in part of the CAC-OS and regions including Ga as a main component (second regions) in another part of the CAC-OS. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. In the case of forming the CAC-OS by a sputtering method, one or more selected from an inert gas (typically, argon), an oxygen gas, and a nitrogen gas can be used as a deposition gas. The proportion of the flow rate of an oxygen gas in the total flow rate of the deposition gas during deposition is preferably as low as possible. For example, the proportion of the flow rate of an oxygen gas in the total flow rate of the deposition gas during deposition is higher than or equal to 0% and lower than 30%, preferably higher than or equal to 0% and lower than or equal to 10%.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. That is, when the second regions are distributed in a metal oxide, a leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), a high field-effect mobility (μ), and favorable switching operation can be achieved.

A transistor using the CAC-OS has high reliability. Thus, the CAC-OS is most suitable for a variety of memory devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <<Other Semiconductor Materials>>

A semiconductor material that has a band gap (a semiconductor material that is not a zero-gap semiconductor) may be used for the semiconductor layer of the transistor. For example, a single-element semiconductor such as silicon or a compound semiconductor such as gallium arsenide may be used.

For the semiconductor layer of the transistor, transition metal chalcogenide functioning as a semiconductor is preferably used, for example. Specific examples of the transition metal chalcogenide that can be used for the semiconductor layer of the transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer of the transistor can provide a memory device with a high on-state current.

### Example of Method for Manufacturing Memory Device

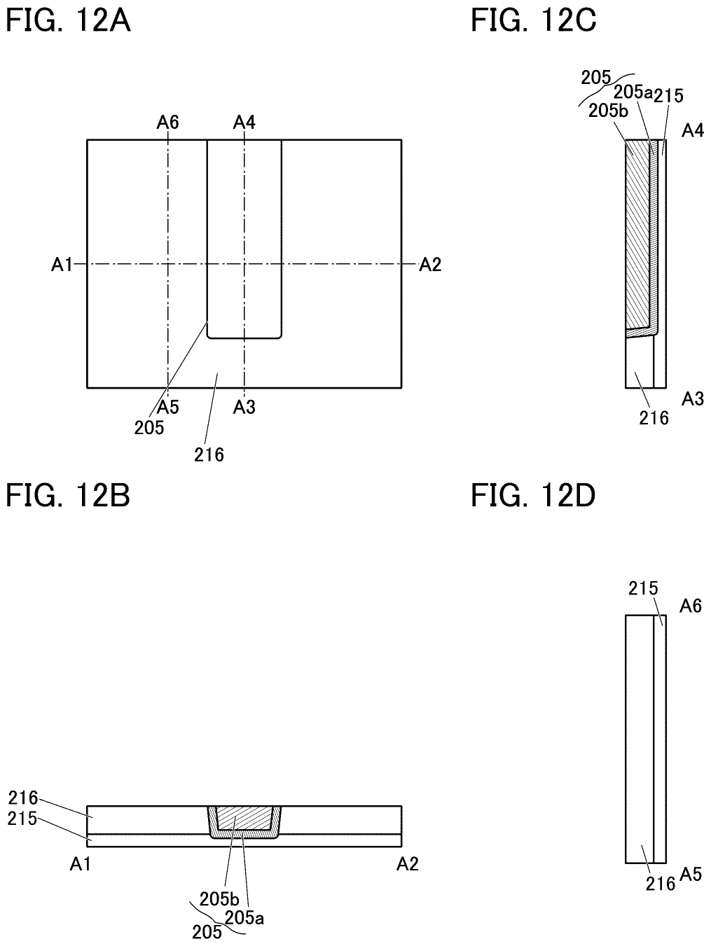

An example of a method for manufacturing the memory device of one embodiment of the present invention will be described with reference to FIG. 12A to FIG. 22D. Here, the case of manufacturing the memory device illustrated in FIG. 1A to FIG. 1D is described as an example.

Note that A of each drawing is a top view. Moreover, B of each drawing is a cross-sectional view corresponding to a portion indicated by the dashed-dotted line A1-A2 in A of each drawing, and is also a cross-sectional view in the channel length direction of the transistor 200. Furthermore, C of each drawing is a cross-sectional view corresponding to a portion indicated by the dashed-dotted line A3-A4 in A of each drawing, and is also a cross-sectional view in the channel width direction of the transistor 200. Moreover, D of each drawing is a cross-sectional view corresponding to a portion indicated by the dashed-dotted line A5-A6 in A of each drawing, and is also a cross-sectional view in the channel width direction of the transistor 200. Note that for clarity of the drawing, some components are omitted in the top view of A of each drawing.

Hereinafter, an insulating material for forming an insulator, a conductive material for forming a conductor, or a semiconductor material for forming a semiconductor can be deposited by a sputtering method, a chemical vapor deposition (CVD) method, a molecular beam epitaxy (MBE) method, a pulsed laser deposition (PLD) method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that CVD methods can be classified into a plasma CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method depending on a source gas to be used.

A high-quality film can be obtained at a relatively low temperature by the plasma CVD method. Furthermore, the thermal CVD method is a deposition method that does not use plasma and thus enables less plasma damage to an object to be processed. For example, a wiring, an electrode, an element (a transistor, a capacitor, or the like), or the like included in a memory device may be charged up by receiving electric charge from plasma. In that case, accumulated electric charge may break the wiring, the electrode, the element, or the like included in the memory device. By contrast, such plasma damage is not caused in the case of the thermal CVD method, which does not use plasma, and thus the yield of the memory device can be increased. In addition, the thermal CVD method does not cause plasma damage during deposition, so that a film with few defects can be obtained.

As an ALD method, a thermal ALD method, in which a precursor and a reactant react with each other only by a thermal energy, a PEALD method, in which a reactant excited by plasma is used, and the like can be used.

The CVD method and the ALD method are different from the sputtering method in which particles ejected from a target or the like are deposited. Thus, the CVD method and the ALD method are deposition methods that enable good step coverage almost regardless of the shape of an object to be processed. In particular, an ALD method enables excellent step coverage and excellent thickness uniformity and thus is suitable for covering a surface of an opening portion with a high aspect ratio, for example. On the other hand, the ALD method has a relatively low deposition rate, and thus is preferably used in combination with another deposition method with a high deposition rate, such as the CVD method, in some cases.

By the CVD method, a film with a certain composition can be deposited depending on the flow rate ratio of the source gases. For example, by the CVD method, a film whose composition is continuously changed can be deposited by changing the flow rate ratio of the source gases during deposition. In the case where the film is deposited while the flow rate ratio of the source gases is changed, as compared with the case where the film is deposited using a plurality of deposition chambers, the time taken for the deposition can be shortened because the time taken for transfer or pressure adjustment is not required. Thus, the productivity of the memory device can be increased in some cases.

By the ALD method, a film with a certain composition can be deposited by concurrently introducing different kinds of precursors. In the case where different kinds of precursors are introduced, a film with a certain composition can be deposited by controlling the number of cycles for each of the precursors.

First, a substrate (not illustrated) is prepared, and the insulator 215 is deposited over the substrate (see FIG. 12A to FIG. 12D). As described above, the insulator 215 can be formed using an insulator similar to either one of the insulator 282 and the insulator 283 or a stack including more than one thereof. As the deposition method for the insulator 215, a sputtering method, a CVD method, an MBE method, a PLD method, or an ALD method can be used, for example. It is preferable to use a sputtering method that does not need to use a molecule including hydrogen as a deposition gas, in which case the hydrogen concentration in the insulator 215 can be reduced.

Next, the insulator 216 is deposited over the insulator 215. The insulator 216 is preferably deposited by a sputtering method. With the use of a sputtering method that does not need to use a molecule including hydrogen as a deposition gas, the hydrogen concentration in the insulator 216 can be reduced. Meanwhile, without limitation to a sputtering method, the insulator 216 may be deposited by a CVD method, an MBE method, a PLD method, an ALD method, or the like as appropriate. In this embodiment, for the insulator 216, silicon oxide is deposited by a sputtering method.

The insulator 215 and the insulator 216 are preferably deposited successively without exposure to the air. For example, a multi-chamber film formation apparatus is used. As a result, the amount of hydrogen in the deposited insulator 215 and insulator 216 can be reduced, and furthermore, entry of hydrogen into the films in intervals between deposition steps can be inhibited.

Then, an opening reaching the insulator 215 is formed in the insulator 216. Wet etching may be used for the formation of the opening; however, dry etching is preferably used for microfabrication. As the insulator 215, it is preferable to select an insulator that functions as an etching stopper film at the time of forming a groove by etching the insulator 216. For example, in the case where silicon oxide or silicon oxynitride is used for the insulator 216 in which the groove is to be formed, silicon nitride, aluminum oxide, hafnium oxide, or the like is preferably used for the insulator 215.

After the formation of the opening, a conductive film to be the conductor 205a is formed. The conductive film to be the conductor 205a desirably includes a conductor having a function of inhibiting passage of oxygen. For example, tantalum nitride, tungsten nitride, or titanium nitride can be used. Alternatively, a stacked film of the conductor having a function of inhibiting passage of oxygen and tantalum, tungsten, titanium, molybdenum, aluminum, copper, or a molybdenum-tungsten alloy can be used. The conductive film to be the conductor 205a can be formed by a sputtering method, a CVD method, an MBE method, a PLD method, an ALD method, or the like.

In this embodiment, titanium nitride is deposited for the conductive film to be the conductor 205a. When such a metal nitride is used for a layer below the conductor 205b, oxidation of the conductor 205b by the insulator 216 or the like can be inhibited. Furthermore, even when a metal that is likely to diffuse, such as copper, is used for the conductor 205b, the metal can be prevented from diffusing to the outside through the conductor 205a.

Next, a conductive film to be the conductor 205b is deposited. Tantalum, tungsten, titanium, molybdenum, aluminum, copper, a molybdenum-tungsten alloy, or the like can be used for the conductive film to be the conductor 205b. The conductive film can be deposited by a plating method, a sputtering method, a CVD method, an MBE method, a PLD method, an ALD method, or the like. In this embodiment, tungsten is deposited for the conductive film to be the conductor 205b.

Then, CMP treatment is performed to remove parts of the conductive film to be the conductor 205a and the conductive film to be the conductor 205b, so that the insulator 216 is exposed (see FIG. 12A to FIG. 12D). As a result, the conductor 205a and the conductor 205b remain only in the opening portion. Note that the insulator 216 is partly removed by the CMP treatment in some cases.

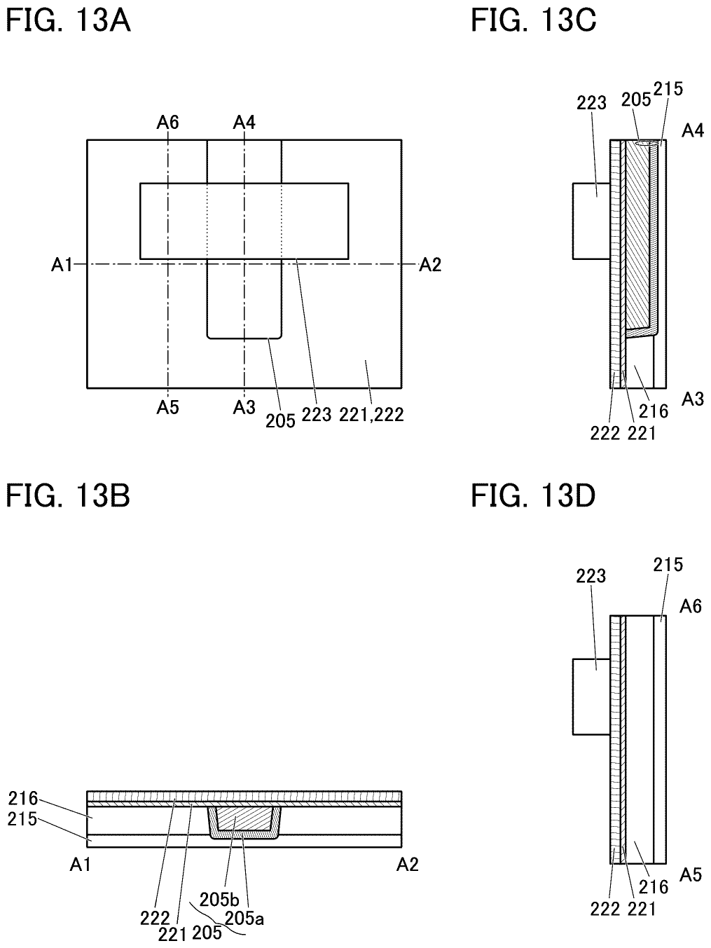

Next, the insulator 221 is deposited over the insulator 216 and the conductor 205 (see FIG. 13A to FIG. 13D).

An insulator having a barrier property against oxygen, hydrogen, and water is used as the insulator 221. The insulator 221 can be deposited by a sputtering method, a CVD method, an MBE method, a PLD method, or an ALD method, for example. In this embodiment, for the insulator 221, silicon nitride is deposited by a PEALD method.

Next, the insulator 222 is deposited over the insulator 221 (see FIG. 13A to FIG. 13D).

An insulator including an oxide of one or both of aluminum and hafnium is preferably deposited as the insulator 222. Note that as the insulator including an oxide of one or both of aluminum and hafnium, for example, aluminum oxide, hafnium oxide, or an oxide including aluminum and hafnium (hafnium aluminate) is preferably used. Alternatively, hafnium-zirconium oxide is preferably used. The insulator including an oxide of one or both of aluminum and hafnium has a barrier property against oxygen, hydrogen, and water. When the insulator 222 has a barrier property against hydrogen and water, hydrogen and water included in components provided around the transistor are inhibited from diffusing into the transistor through the insulator 222, and generation of oxygen vacancies in the oxide 230 can be inhibited.

The insulator 222 can be deposited by a sputtering method, a CVD method, an MBE method, a PLD method, or an ALD method, for example. In this embodiment, for the insulator 222, hafnium oxide is deposited by an ALD method.

Subsequently, an insulating film is deposited over the insulator 222 and the insulating film is subjected to etching, so that an insulator 223 is formed (see FIG. 13A to FIG. 13D). The insulator 223 functions as a sacrificial layer for forming the insulator 225. As the insulator 223, an insulator than can be used as the insulator 216 is used, for example.

The insulator 223 can be deposited by a sputtering method, a CVD method, an MBE method, a PLD method, or an ALD method, for example. In this embodiment, for the insulator 223, silicon oxide is deposited by a sputtering method.

The insulator 223 is processed into an island shape by a lithography method. A dry etching method or a wet etching method can be used for the processing. Processing by a dry etching method is suitable for microfabrication.

As illustrated in FIG. 13B, the insulator 223 may have a side surface that is perpendicular or substantially perpendicular to the top surface of the insulator 222. With such a structure, a plurality of transistors can be provided with high density in a small area.

Note that heat treatment may be performed before the insulator 223 is deposited. The heat treatment may be performed under reduced pressure, and the insulator 223 may be successively deposited without exposure to the air. Such treatment can remove moisture and hydrogen adsorbed onto the surface of the insulator 222 and can reduce the moisture concentration and the hydrogen concentration in the insulator 222. The insulator 221 is provided in contact with the bottom surface of the insulator 222, whereby entry of moisture or impurities such as hydrogen from the component below the insulator 221, which is caused by the heat treatment, can be prevented. The heat treatment temperature is preferably higher than or equal to 100° C. and lower than or equal to 400° C. In this embodiment, the heat treatment is performed at 250° C.

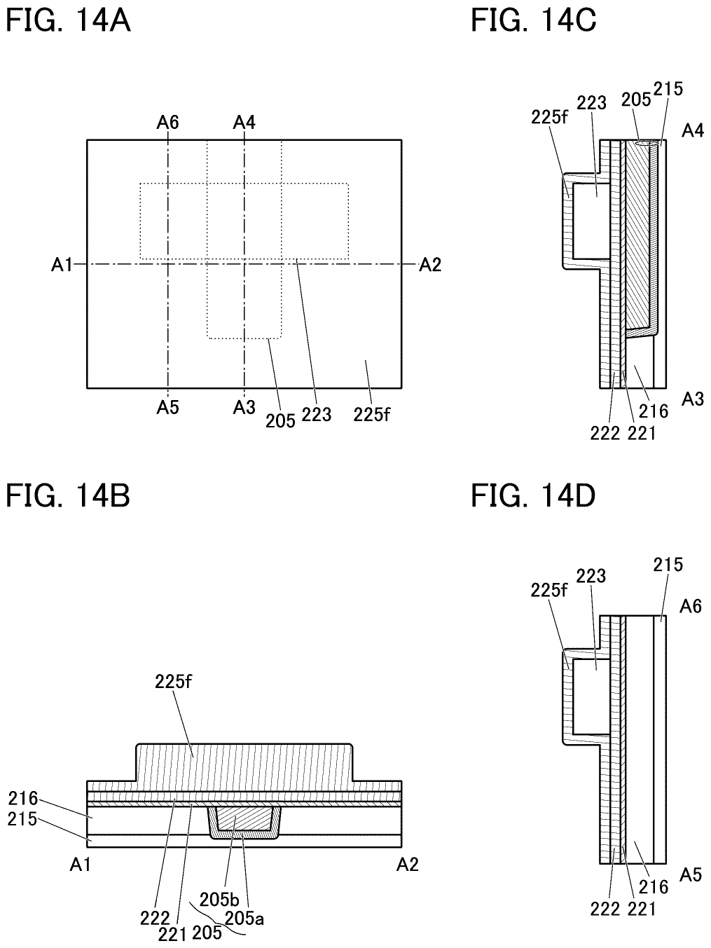

Next, an insulating film 225f to be the insulator 225 is deposited to cover the insulator 223 (see FIG. 14A to FIG. 14D). The insulating film 225f is an insulating film to be the insulator 225 in a later step, and the insulator described above can be used. The insulating film 225f can be deposited by a sputtering method, a CVD method, an MBE method, a PLD method, or an ALD method.

The insulating film 225f preferably has good coverage so that the insulating film 225f is deposited along the insulator 223. Thus, the insulating film 225f is preferably deposited by an ALD method or the like that offers good coverage. Since the insulator 225 preferably has a high aspect ratio, the insulating film 225f preferably has a small thickness. Thus, the insulating film 225f is preferably deposited by an ALD method enabling adjustment of a small thickness. As the insulating film 225f, for example, hafnium oxide is preferably deposited by a thermal ALD method. When the insulating film 225f is deposited in this manner, the insulating film 225f is formed in contact with the top surface and the side surface of the insulator 223.

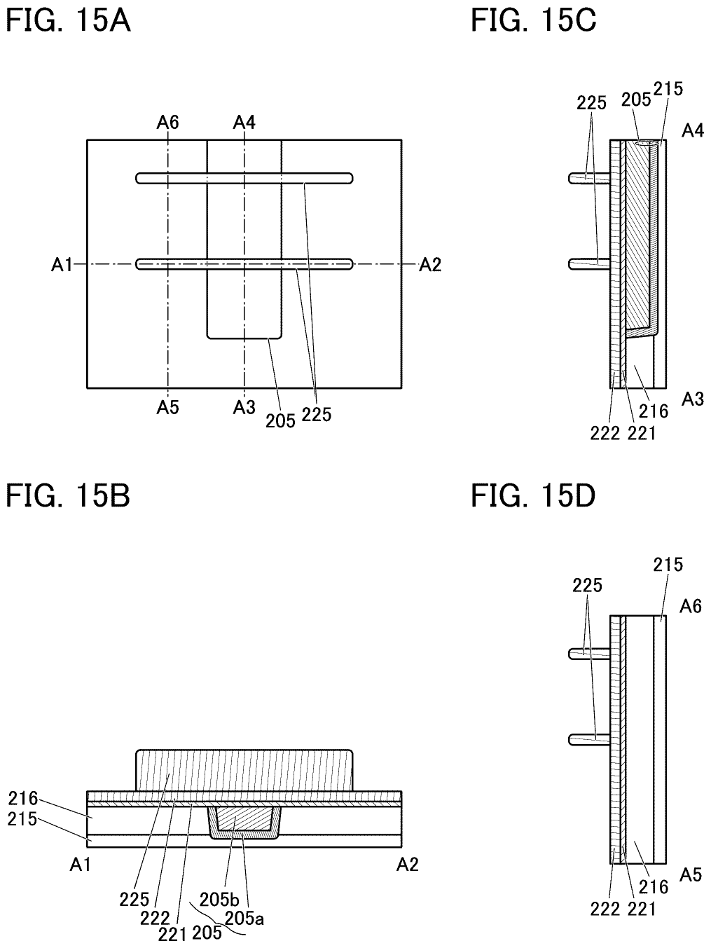

Next, part of the insulating film 225f is removed by anisotropic etching, and the insulator 223 is further removed (see FIG. 15A to FIG. 15D). Thus, the insulator 225 having a high aspect ratio can be formed. The use of the insulator 225 enables the transistor 200 to have a larger channel width without an increase in the area occupied by the transistor 200, so that the on-state current, field-effect mobility, and frequency characteristics of the transistor 200 can be improved. Since the area of the capacitor 100 can be increased without increasing the area occupied by the capacitor 100, the capacitance of the capacitor 100 can be increased.

When the two insulators 225 are formed as illustrated in FIG. 15A to FIG. 15D, the distance between the two insulators 225 can be set in accordance with the size of the insulator 223. Thus, the distance between the insulators 225 can be shortened, and the area occupied by the transistor 200a, the transistor 200b, the capacitor 100a, and the capacitor 100b can be reduced, leading to high integration of the memory device.

A dry etching method is preferably employed for the anisotropic etching of the insulating film 225f.

An etching gas including a halogen can be used as an etching gas for dry etching treatment; specifically, an etching gas including one or more of fluorine, chlorine, and bromine can be used. As the etching gas, for example, a C₄F₆ gas, a CsF₆ gas, a C₄F₈ gas, a CF₄ gas, a SF₆ gas, a CHF₃ gas, a CH₂F₂ gas, a Cl₂ gas, a BCl₃ gas, a SiCl₄ gas, a BBr₃ gas, or the like can be used alone or two or more of the gases can be mixed and used. Furthermore, an oxygen gas, a carbonic acid gas, a nitrogen gas, a helium gas, an argon gas, a hydrogen gas, a hydrocarbon gas, or the like can be added to the above etching gas as appropriate. Depending on an object to be subjected to the dry etching treatment, a gas that includes a hydrocarbon gas or a hydrogen gas and does not include a halogen gas can be used as the etching gas. As the hydrocarbon used for the etching gas, one or more of methane (CH₄), ethane (C₂H₆), propane (C₃H₈), butane (C₄H₁₀), ethylene (C₂H₄), propylene (C₃H₆), acetylene (C₂H₂), and propyne (C₃H₄) can be used. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example. The etching apparatus can be set as appropriate depending on an object to be etched.

For example, in the case where hafnium oxide is used for the insulating film 225f, with the use of a CCP etching apparatus, a mixed gas of C₄F₈, H₂, and Ar is used as an etching gas.

Note that for the removal of the insulator 223, a dry etching method or a wet etching method can be used for the above processing. For example, the insulator 223 is removed by a wet etching method.

At the time of forming the insulator 225 by anisotropic etching, the insulator 225 is formed in a sidewall shape in contact with the side surface of the insulator 223. That is, the insulator 225 is formed perimetrically to surround the insulator 223. When the memory device is manufactured while the insulator 225 is maintained to be formed perimetrically, the insulator 225 is a single component in the transistor 200a and the transistor 200b as illustrated in FIG. 6A to FIG. 6D.

Here, in the structure illustrated in FIG. 15, the insulator 225 is formed by removing part of the sidewall-shaped insulator that is unnecessary in the structure of the memory device. In the case where the insulator 225 is formed in such a manner, unnecessary part of the insulator 225 may be etched first before the anisotropic etching of the insulating film 225f is performed.

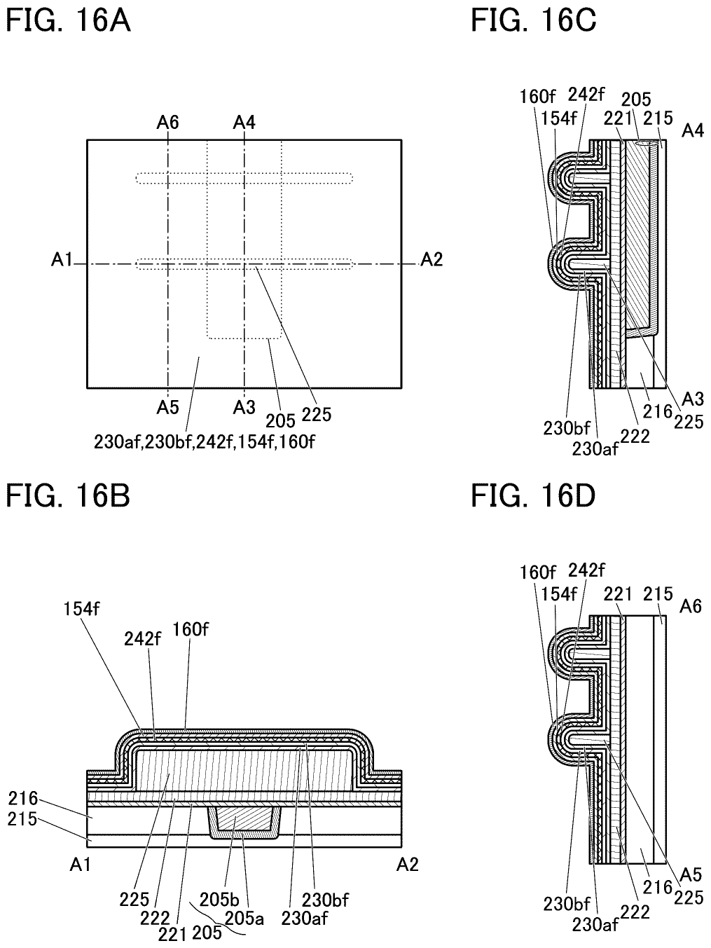

Next, an oxide film 230af is deposited over the insulator 222 and the insulator 225, and an oxide film 230bf is deposited over the oxide film 230af (see FIG. 16A to FIG. 16D). A metal oxide corresponding to the oxide 230a is used for the oxide film 230af, and a metal oxide corresponding to the oxide 230b is used for the oxide film 230bf. Note that the oxide film 230af and the oxide film 230bf are preferably formed successively without being exposed to an atmospheric environment. By the deposition without exposure to the air, impurities or moisture from the atmospheric environment can be prevented from being attached onto the oxide film 230af and the oxide film 230bf, so that the interface between the oxide film 230af and the oxide film 230bf or the vicinity of the interface can be kept clean.

The oxide film 230af and the oxide film 230bf can each be formed by a sputtering method, a CVD method, an MBE method, a PLD method, or an ALD method, for example.

The oxide film 230af and the oxide film 230bf are preferably deposited by an ALD method or the like that offers good coverage. Thus, the oxide film 230af and the oxide film 230bf can be deposited along the side surface of the insulator 225 with good coverage by an ALD method. Thus, the channel formation region of the transistor 200 can also be formed along the side surface on the A3 side and the side surface on the A4 side of the insulator 225; thus, the channel width of the transistor 200 can be increased. Accordingly, the transistor 200 can have a favorable field-effect mobility, a favorable on-state current, and favorable frequency characteristics.

As the oxide film 230af, a metal oxide layer having an atomic ratio of In:Ga:Zn=1:3:2, a metal oxide layer having an atomic ratio of In:Ga:Zn=1:3:4, or a metal oxide layer having an atomic ratio of In:Ga:Zn=1:1:1 is deposited by an ALD method. As the oxide film 230bf, a metal oxide layer having an atomic ratio of In:Ga:Zn=1:1:1 or a metal oxide layer having an atomic ratio of In:Zn=4:1 is deposited by an ALD method. The oxide film 230af and the oxide film 230bf may each have a stacked-layer structure of the above metal oxide layers. The oxide film 230bf may be, for example, a stacked-layer film in which a metal oxide layer having an atomic ratio of In:Zn=4:1 and a metal oxide layer having an atomic ratio of In:Ga:Zn=1:1:1 are stacked in this order. Note that in the oxide film 230bf, a metal oxide layer having an atomic ratio of In:Ga:Zn=1:3:2 or a metal oxide layer having an atomic ratio of In:Ga:Zn=1:3:4 may be used instead of a metal oxide layer having an atomic ratio of In:Ga:Zn=1:1:1.

The oxide film 230af and the oxide film 230bf may be deposited by a sputtering method. For example, in the case where the oxide film 230af and the oxide film 230bf are deposited by a sputtering method, oxygen or a mixed gas of oxygen and a noble gas is used as a sputtering gas. Increasing the proportion of oxygen included in the sputtering gas can increase the amount of excess oxygen in the deposited oxide films. In the case where the oxide films are deposited by a sputtering method, an In-M-Zn oxide target or the like can be used.

In the case where the oxide film 230bf is formed by a sputtering method and the proportion of oxygen included in the sputtering gas for deposition is higher than 30% and lower than or equal to 100%, preferably higher than or equal to 70% and lower than or equal to 100%, an oxygen-excess oxide semiconductor is formed. In a transistor using an oxygen-excess oxide semiconductor for its channel formation region, relatively high reliability can be obtained. Note that one embodiment of the present invention is not limited thereto. In the case where the oxide film 230bf is formed by a sputtering method and the proportion of oxygen included in the sputtering gas for deposition is higher than or equal to 1% and lower than or equal to 30%, preferably higher than or equal to 5% and lower than or equal to 20%, an oxygen-deficient oxide semiconductor is formed. In a transistor using an oxygen-deficient oxide semiconductor in its channel formation region, relatively high field-effect mobility can be obtained. Furthermore, when the deposition is performed while the substrate is being heated, the crystallinity of the oxide film can be improved.

In this embodiment, the oxide film 230af is deposited by a sputtering method using an oxide target having an atomic ratio of In:Ga:Zn=1:3:2, an oxide target having an atomic ratio of In:Ga:Zn=1:3:4, an oxide target having an atomic ratio of In:Ga:Zn=1:1:1, or an oxide target having an atomic ratio of In:Ga:Zn=1:1:1.2. In addition, the oxide film 230bf is deposited by a sputtering method using an oxide target having an atomic ratio of In:Ga:Zn=1:1:1, an oxide target having an atomic ratio of In:Ga:Zn=1:1:1.2, an oxide target having an atomic ratio of In:Ga:Zn=4:2:4.1, an oxide target having an atomic ratio of In:Ga:Zn=1:1:2, or an oxide target having an atomic ratio of In:Zn=4:1. Note that each of the oxide films is preferably formed so as to have characteristics required for the oxide 230a and the oxide 230b by selecting the deposition conditions and the atomic ratios as appropriate.

In addition, for example, the oxide film 230af may be deposited by a sputtering method and the oxide film 230bf may be deposited by an ALD method. Here, one or both of the oxide film 230af and the oxide film 230bf may have a stacked-layer structure. For example, the oxide film 230af is deposited by a sputtering method using any of an oxide target having an atomic ratio of In:Ga:Zn=1:1:1, an oxide target having an atomic ratio of In:Ga:Zn=1:1:1.2, an oxide target having an atomic ratio of In:Ga:Zn=1:3:2, and an oxide target having an atomic ratio of In:Ga:Zn=1:3:4.

For the oxide film 230bf, the above-described metal oxide layer deposited by an ALD method can be used. As the oxide film 230bf, for example, a stacked-layer film in which a metal oxide layer having an atomic ratio of In:Zn=4:1 and a metal oxide layer having an atomic ratio of In:Ga:Zn=1:1:1 are stacked in this order is deposited.

When the oxide film 230af is deposited by a sputtering method, the crystallinity can be increased. For example, the crystallinity of the oxide film 230af is increased and then the oxide film 230bf is deposited over the oxide film 230af, whereby part or the whole of the oxide film 230bf can be crystallized. That is, when the crystallinity of the oxide film 230af is increased, the crystallinity of the oxide film 230bf can also be increased. For example, in the case where the oxide film 230af is an oxide semiconductor film having a CAAC structure, the oxide film 230bf formed over the oxide film 230af can also be an oxide semiconductor having a CAAC structure.

The oxide film 230bf is deposited by an ALD method, which allows deposition of a thin film with good controllability. Accordingly, the oxide film 230bf can have a small thickness as designed. With the use of such an oxide film 230af and an oxide film 230bf, the transistor 200 can have electrical characteristics and reliability improved.

Note that the oxide film 230af and the oxide film 230bf are preferably deposited without exposure to the air. For example, a multi-chamber deposition apparatus is preferably used. Thus, entry of hydrogen into the oxide film 230af and the oxide film 230bf in intervals between deposition steps can be inhibited.

Next, heat treatment is preferably performed. The heat treatment is performed in a temperature range where the oxide film 230af and the oxide film 230bf do not become polycrystals. The temperature of the heat treatment is preferably higher than or equal to 100° C., higher than or equal to 250° C., or higher than or equal to 350° C. and lower than or equal to 650° C., lower than or equal to 600° C., or lower than or equal to 550° C.

Note that the heat treatment is performed in a nitrogen gas or inert gas atmosphere, or an atmosphere including an oxidizing gas at higher than or equal to 10 ppm, higher than or equal to 1%, or higher than or equal to 10%. For example, in the case where the heat treatment is performed in a mixed atmosphere of a nitrogen gas and an oxygen gas, the proportion of the oxygen gas is preferably approximately 20%. Alternatively, the heat treatment may be performed under reduced pressure. Alternatively, heat treatment may be performed in a nitrogen gas or inert gas atmosphere, and then another heat treatment may be performed in an atmosphere including an oxidizing gas at higher than or equal to 10 ppm, higher than or equal to 1%, or higher than or equal to 10% in order to compensate for released oxygen.

The gas used in the above heat treatment is preferably highly purified. For example, the amount of moisture included in the gas used in the above heat treatment is preferably lower than or equal to 1 ppb, further preferably lower than or equal to 0.1 ppb, still further preferably lower than or equal to 0.05 ppb. The heat treatment using a highly purified gas can prevent entry of moisture or the like into the oxide film 230af, the oxide film 230bf, and the like as much as possible.

In this embodiment, the heat treatment is performed at 450° C. for one hour with the flow rate ratio of nitrogen gas to oxygen gas being 4:1. Through such heat treatment using the oxygen gas, impurities such as carbon, water, and hydrogen in the oxide film 230af and the oxide film 230bf can be reduced. The reduction of impurities in the films in this manner improves the crystallinity of the oxide film 230af and the oxide film 230bf, thereby offering a dense structure with a higher density. Thus, crystalline regions in the oxide film 230af and the oxide film 230bf are expanded, so that in-plane variations of the crystalline regions in the oxide film 230af and the oxide film 230bf can be reduced. Accordingly, an in-plane variation of electrical characteristics of transistors can be reduced.

By performing the heat treatment, hydrogen in the insulator 216, the oxide film 230af, and the oxide film 230bf is absorbed by the insulator 225 and the insulator 222. In other words, hydrogen in the insulator 216, the oxide film 230af, and the oxide film 230bf diffuses into the insulator 225 and the insulator 222. Accordingly, the hydrogen concentrations in the insulator 225 and the insulator 222 increase, while the hydrogen concentrations in the insulator 216, the oxide film 230af, and the oxide film 230bf decrease. Note that the insulator 221 is provided in contact with the bottom surface of the insulator 222, whereby entry of moisture or impurities such as hydrogen from below the insulator 221, which is caused by the heat treatment, can be prevented.

In particular, the oxide film 230af and the oxide film 230bf (to be the oxide 230a and the oxide 230b later) function as a channel formation region of the transistor 200. The transistor 200 formed using the oxide film 230af and the oxide film 230bf with reduced hydrogen concentrations is preferable because of its favorable reliability.

Next, a conductive film 242f is deposited over the oxide film 230bf (see FIG. 16A to FIG. 16D). As the conductive film 242f, a conductor corresponding to the conductors 242a and 242b is used. After the deposition of the oxide film 230bf, the conductive film 242f is deposited over and in contact with the oxide film 230bf without inserting an etching step or the like, so that the top surface of the oxide film 230bf can be protected by the conductive film 242f. Thus, diffusion of impurities into the oxide 230 included in the transistor can be reduced, whereby the electrical characteristics and reliability of the memory device can be improved.

The conductive film 242f can be deposited by a sputtering method, a CVD method, an MBE method, a PLD method, or an ALD method, for example. By an ALD method, the conductive film 242f can be deposited along the side surface of the insulator 225 with good coverage. For example, as the conductive film 242f, tantalum nitride is deposited by an ALD method.

Next, an insulating film 154f is deposited over the conductive film 242f (see FIG. 16A to FIG. 16D). As the insulating film 154f, a high-k material corresponding to the insulators 154a and 154b can be used.

The insulating film 154f can be deposited by a sputtering method, a CVD method, an MBE method, a PLD method, or an ALD method, for example. By an ALD method, the insulating film 154f can be deposited along the side surface of the insulator 225 with good coverage. As the insulating film 154f, a stacked film of a zirconium oxide film, an aluminum oxide film over the zirconium oxide film, and a zirconium oxide film over the aluminum oxide film is deposited by a thermal ALD method, for example.

In the case where the insulating film 154f is formed by stacking films, the films are preferably deposited successively without exposure to the atmospheric environment. By the deposition without exposure to the air, an interface between the stacked films of the insulating film 154f or the vicinity of the interface can be kept clean.

Next, a conductive film 160f is deposited over the insulating film 154f (see FIG. 16A to FIG. 16D). As the conductive film 160f, a conductor corresponding to the conductors 160a and 160b is used.

The conductive film 160f can be deposited by a sputtering method, a CVD method, an MBE method, a PLD method, an ALD method, or the like. By an ALD method, the conductive film 160f can be deposited along the side surface of the insulator 225 with good coverage. For example, as the conductive film 160f, titanium nitride is deposited by an ALD method.

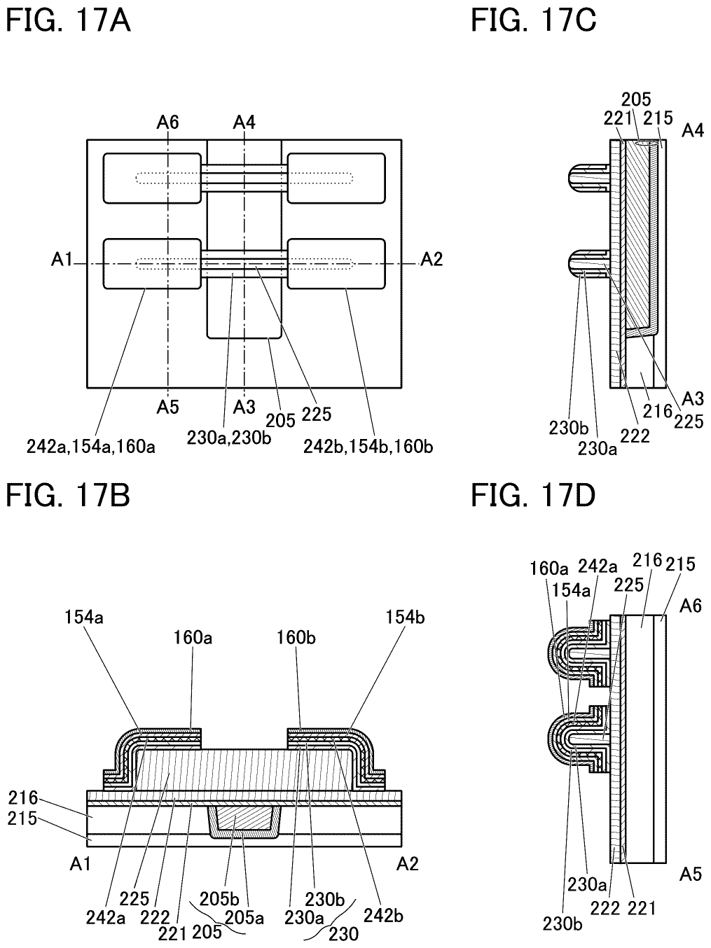

Next, the oxide film 230af, the oxide film 230bf, the conductive film 242f, the insulating film 154f, and the conductive film 160f are processed into island shapes by a lithography method to form the oxide 230a, the oxide 230b, the conductor 242a, the conductor 242b, the insulator 154a, the insulator 154b, the conductor 160a, and the conductor 160b (see FIG. 17A to FIG. 17D). A dry etching method or a wet etching method can be used for the processing. Processing by a dry etching method is suitable for microfabrication. Note that the above description can be referred to for the conditions and an apparatus for the dry etching method. The oxide film 230af, the oxide film 230bf, the conductive film 242f, the insulating film 154f, and the conductive film 160f may be processed under different conditions.

By the above processing, the oxide 230a, the oxide 230b, the conductor 242a, the conductor 242b, the insulator 154a, the insulator 154b, the conductor 160a, and the conductor 160b that form the transistor 200a and the capacitor 100a are separated from the oxide 230a, the oxide 230b, the conductor 242a, the conductor 242b, the insulator 154a, the insulator 154b, the conductor 160a, and the conductor 160b that form the transistor 200b and the capacitor 100b. At this time, it is preferable that the oxide 230a, the oxide 230b, the conductor 242a, the conductor 242b, the insulator 154a, the insulator 154b, the conductor 160a, and the conductor 160b be formed to each cover at least part of the insulator 225 which constitutes part of the transistor 200a and at least part of the insulator 225 which constitutes part of the transistor 200b.

Furthermore, as illustrated in FIG. 17A, the conductor 242a, the insulator 154a, and the conductor 160a are provided to face the conductor 242b, the insulator 154b, and the conductor 160b with the dashed-dotted line A3-A4 therebetween. Thus, the conductor 242a functioning as one of a source electrode and a drain electrode and the conductor 242b functioning as the other of the source electrode and the drain electrode in the transistor 200a and the transistor 200b are formed. The capacitor 100a and the capacitor 100b each including the conductor 242a, the insulator 154a over the conductor 242a, and the conductor 160a over the insulator 154a are formed. Here, it is preferable that side end portions of two or more of the conductor 242a, the insulator 154a, and the conductor 160a be aligned or substantially aligned with each other, and side end portions of two or more of the conductor 242b, the insulator 154b, and the conductor 160b be aligned or substantially aligned with each other.

The oxide 230a and the oxide 230b are formed to at least partly overlap with the conductor 205. The insulator 222 is exposed in a region not overlapping with the oxide 230a or the oxide 230b. Part of the oxide 230a and part of the oxide 230b overlap with the conductor 242a, the insulator 154a, the conductor 160a, the conductor 242b, the insulator 154b, and the conductor 160b. Here, in portions of the oxide 230a and the oxide 230b that overlap with the conductor 242a, the conductor 242b, or the like, it is preferable that side end portions of two or more of the oxide 230a, the oxide 230b, the conductor 242a, the insulator 154a, and the conductor 160a be aligned or substantially aligned with each other and that side end portions of two or more of the oxide 230a, the oxide 230b, the conductor 242b, the insulator 154b, and the conductor 160b be aligned or substantially aligned with each other.

Portions of the oxide 230a and the oxide 230b that do not overlap with the conductor 242a, the conductor 242b, or the like (also referred to as portions of the oxide 230a and the oxide 230b that are positioned between the conductor 242a and the conductor 242b) are formed in a sidewall shape along the side surface of the insulator 225. Thus, as illustrated in FIG. 17C, the side surface of the oxide 230a is in contact with the insulator 225, the bottom surface of the oxide 230a is in contact with the insulator 222, the side surface and the bottom surface of the oxide 230b are in contact with the oxide 230a, and the oxide 230a and the oxide 230b are not in contact with the top surface of the insulator 225.

In order to form the oxide 230a and the oxide 230b in the above-described sidewall shape, the oxide film 230af and the oxide film 230bf are preferably processed by anisotropic etching. A dry etching method is preferably used for anisotropic etching of the oxide film 230af and the oxide film 230bf. Note that the above description can be referred to for the conditions and an apparatus for the dry etching method.

For example, a mask is formed by a lithography method, and the conductive film 242f, the insulating film 154f, and the conductive film 160f are processed into island shapes to form the conductor 242a, the conductor 242b, the insulator 154a, the insulator 154b, the conductor 160a, and the conductor 160b. With the same mask, anisotropic etching is performed on the oxide film 230af and the oxide film 230bf. In this manner, the oxide 230a and the oxide 230b are formed to overlap with the conductor 242a, the conductor 242b, or the like and, in the region not overlapping with the conductor 242a, the conductor 242b, or the like, to have a sidewall shape on the side surface of the insulator 225. In this manner, the oxide 230a, the oxide 230b, the conductor 242a, the conductor 242b, the insulator 154a, the insulator 154b, the conductor 160a, and the conductor 160b are preferably processed at a time. This can reduce the number of steps of the memory device of one embodiment of the present invention. Thus, a method for manufacturing a memory device with high productivity can be provided.

As illustrated in FIG. 17B, the side surfaces of the oxide 230a, the oxide 230b, the conductor 242a, the conductor 242b, the insulator 154a, the insulator 154b, the conductor 160a, and the conductor 160b may be perpendicular or substantially perpendicular to the top surface of the insulator 222. With this structure, a plurality of transistors can be provided with a higher density in a smaller area.

Without limitation to the above, the side surfaces of the oxide 230a, the oxide 230b, the conductor 242a, the conductor 242b, the insulator 154a, the insulator 154b, the conductor 160a, and the conductor 160b may have tapered shapes. The taper angles of the side surfaces of the oxide 230a, the oxide 230b, the conductor 242a, the conductor 242b, the insulator 154a, the insulator 154b, the conductor 160a, and the conductor 160b may be greater than or equal to 60° and less than 90°, for example. With such tapered shapes of the side surfaces, the coverage with the insulator 275 and the like can be improved in a later step, so that defects such as voids can be reduced.

Note that in a lithography method, first, a resist is exposed to light through a mask. Next, a region exposed to light is removed or left using a developing solution, so that a resist mask is formed. Then, etching treatment through the resist mask is performed, whereby a conductor, a semiconductor, an insulator, or the like can be processed into a desired shape. The resist mask can be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that the use of a mask may be unnecessary in the case of using an electron beam or an ion beam.

Note that the resist mask that is no longer needed after the processing can be removed by dry etching treatment such as ashing using oxygen plasma (hereinafter, referred to oxygen plasma treatment in some cases) or the like, wet etching treatment, wet etching treatment after dry etching treatment, or dry etching treatment after wet etching treatment.

In addition, a hard mask formed of an insulator or a conductor may be used under the resist mask. In the case of using a hard mask, a hard mask with a desired shape can be formed in the following manner: an insulating film or a conductive film that is the material of the hard mask is formed over the conductive film 160f, a resist mask is formed thereover, and then the hard mask material is etched. The etching of the conductive film 160f and the like may be performed after removing the resist mask or with the resist mask remaining. In the latter case, the resist mask sometimes disappears during the etching. The hard mask may be removed by etching after the etching of the oxide film 230bf and the like. Meanwhile, the hard mask is not necessarily removed when the hard mask material does not affect later steps or can be utilized in later steps.

A spin on carbon (SOC) film and a spin on glass (SOG) film may be formed between an object to be processed and the resist mask. Using the SOC film and the SOG film as masks can improve the adhesion between the object to be processed and the resist mask, resulting in enhancement of the durability of a mask pattern. For example, the SOC film, the SOG film, and the resist mask are formed in this order over the object to be processed and lithography can be performed.

Although the oxide film 230af and the oxide film 230bf are subjected to anisotropic etching in the above description, the present invention is not limited thereto. For example, in addition to the oxide film 230af and the oxide film 230bf, the conductive film 242f may also be subjected to anisotropic etching. In this case, the conductive film 242f processed into a sidewall shape is formed in contact with the side surface of the oxide 230b. Similarly, the insulating film 154f and the conductive film 160f may also be subjected to anisotropic etching.

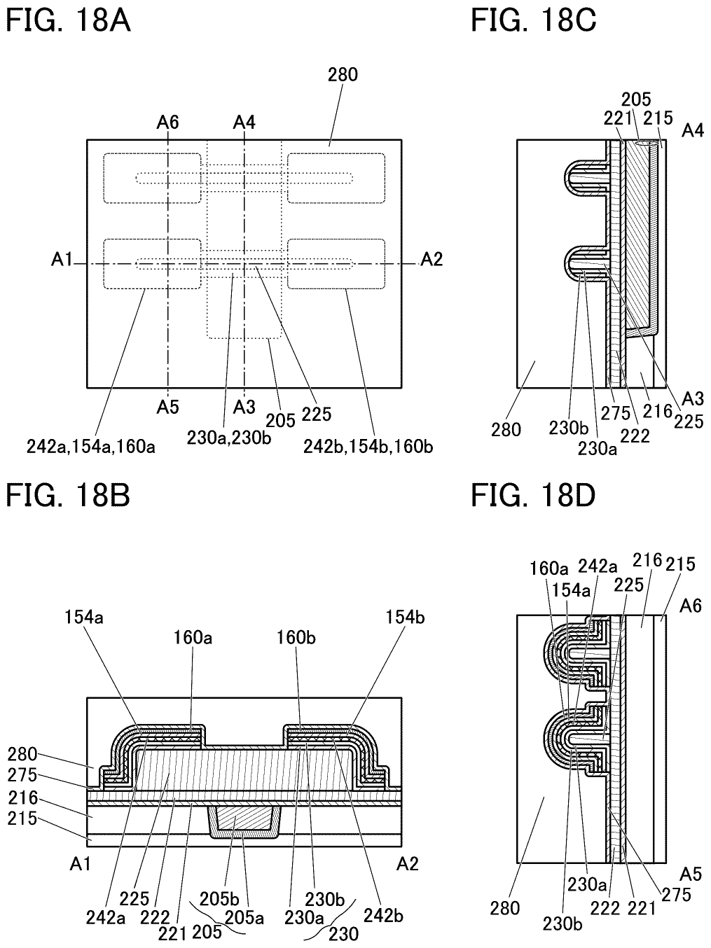

Next, the insulator 275 is deposited to cover the oxide 230a, the oxide 230b, the conductor 242a, the conductor 242b, the insulator 154a, the insulator 154b, the conductor 160a, and the conductor 160b, and the insulator 280 is deposited over the insulator 275 (see FIG. 18A to FIG. 18D). The above-described insulators can be used for the insulator 275 and the insulator 280.

Here, it is preferable that the insulator 275 be in contact with the top surface of the insulator 222.

As the insulator 280, an insulator having a flat top surface is preferably formed by forming an insulating film to be the insulator 280 and then performing CMP treatment on the insulating film. Note that, for example, silicon nitride may be deposited over the insulator 280 by a sputtering method and CMP treatment may be performed on the silicon nitride until the insulator 280 is reached.

The insulator 275 and the insulator 280 can each be deposited by a sputtering method, a CVD method, an MBE method, a PLD method, or an ALD method, for example.

For the insulator 275, an insulator having a function of inhibiting passage of oxygen is preferably used. For example, for the insulator 275, silicon nitride is preferably deposited by a PEALD method. Alternatively, for the insulator 275, it is preferable that aluminum oxide be deposited by a sputtering method and silicon nitride be deposited thereover by a PEALD method. When the insulator 275 has the above-described structure, the function of inhibiting diffusion of oxygen and impurities such as water or hydrogen can be improved.

In this manner, the oxide 230a, the oxide 230b, the conductor 242a, and the conductor 242b can be covered with the insulator 275, which has a function of inhibiting diffusion of oxygen. This can suppress direct diffusion of oxygen from the insulator 280 or the like into the oxide 230a, the oxide 230b, the conductor 242a, and the conductor 242b in a later step.

For the insulator 280, silicon oxide is preferably deposited by a sputtering method. When the insulating film to be the insulator 280 is deposited by a sputtering method in an oxygen-including atmosphere, the insulator 280 including excess oxygen can be formed. With the use of a sputtering method that does not need to use a molecule including hydrogen as a deposition gas, the hydrogen concentration in the insulator 280 can be reduced. Note that heat treatment may be performed before the deposition of the insulating film. The heat treatment may be performed under reduced pressure, and the insulating film may be successively deposited without exposure to the air. Such treatment can remove moisture and hydrogen adsorbed onto the surface of the insulator 275 and the like, and further can reduce the moisture concentrations and the hydrogen concentrations in the oxide 230a and the oxide 230b. For the heat treatment, the above heat treatment conditions can be used.

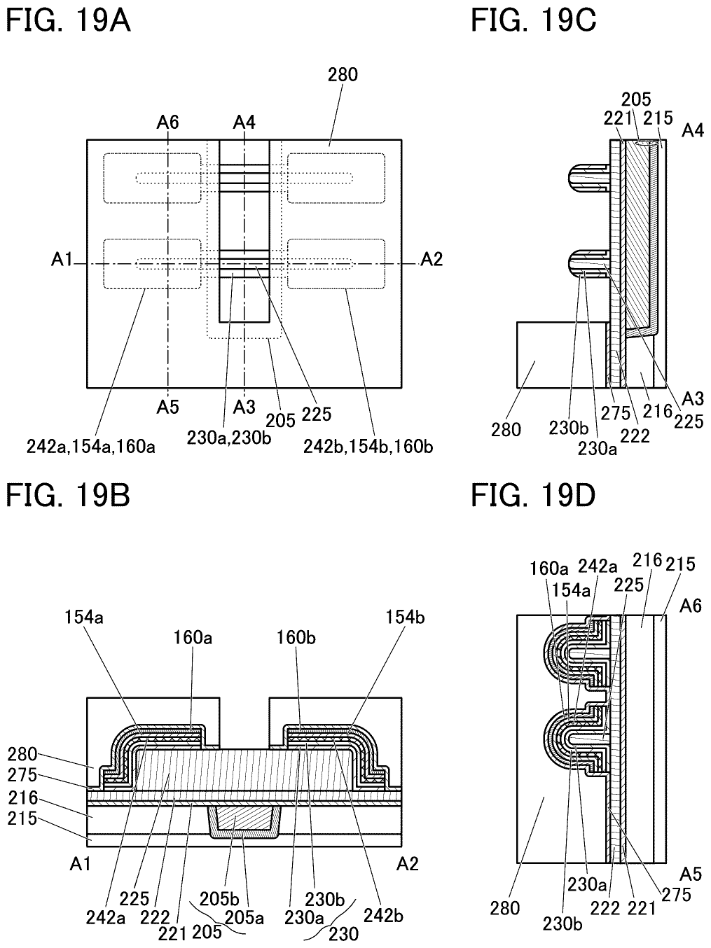

Next, the insulator 280 and the insulator 275 are processed by a lithography method to form an opening reaching the insulator 225, the oxide 230a, the oxide 230b, and the insulator 222 (see FIG. 19A to FIG. 19D). The opening is formed in a region where the insulator 225, the oxide 230a, and the oxide 230b overlap with the conductor 205. The opening is preferably formed between the conductor 240a and the conductor 240b.

The above-described method can be used as appropriate as the lithography method. In order to process the opening in the insulator 280 and the insulator 275 minutely, a lithography method using an electron beam or short-wavelength light such as EUV light is preferably employed.

The above processing is preferably performed by a dry etching method. A dry etching method enables anisotropic etching and thus is suitable for forming an opening with a high aspect ratio. Note that the above description can be referred to for the conditions and an apparatus for the dry etching method.

In the case where the conductive film 242f is also subjected to anisotropic etching in the step illustrated in FIG. 17A to FIG. 17D, the conductor 242a and the conductor 242b are preferably formed by etching the remaining portion of the conductive film 242f in the step illustrated in FIG. 19A to FIG. 19D. In this case, as illustrated in FIG. 9A to FIG. 9D, part of the conductor 242a and part of the conductor 242b are formed in regions not overlapping with the conductor 160a, the conductor 160b, or the like. Thus, the conductor 242a and the conductor 242b are formed in a sidewall shape in contact with the side surface of the oxide 230b between the conductor 242 and the conductor 160.

Note that ashing treatment using oxygen plasma may be performed after the formation of the opening in the insulator 280 and the insulator 275. Such oxygen plasma treatment can remove impurities generated by the above etching treatment and diffused into the oxide 230 or the like. The impurities are generated from a component of the object processed by the above etching treatment and a component contained in a gas or the like used for the etching. Examples of the impurities include chlorine, fluorine, tantalum, silicon, and hafnium. In particular, when a chlorine gas is used in the above etching treatment, the oxide 230 is exposed to the atmosphere containing the chlorine gas, in which case chlorine attached to the oxide 230 is preferably removed. Removal of impurities attached to the oxide 230 in this manner can improve the electrical characteristics and reliability of the transistor.

In order to remove impurities and the like attached to the surface of the oxide 230b in the above etching step, cleaning treatment may be performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which one or more of ammonia water, oxalic acid, phosphoric acid, and hydrofluoric acid is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a memory device to be cleaned, or the like. The concentration of ammonia in the diluted ammonia water is preferably higher than or equal to 0.01% and lower than or equal to 5%, further preferably higher than or equal to 0.1% and lower than or equal to 0.5%. The concentration of hydrogen fluoride in the diluted hydrofluoric acid is preferably higher than or equal to 0.01 ppm and lower than or equal to 100 ppm, further preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced with such a frequency.

The cleaning treatment may be performed a plurality of times, and the cleaning solution may be changed in every cleaning treatment. For example, first cleaning treatment may use diluted hydrofluoric acid or diluted ammonia water, and second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Furthermore, the crystallinity of the oxide 230a, the oxide 230b, or the like can be increased.

After the etching or the cleaning, heat treatment is preferably performed. The temperature of the heat treatment is preferably higher than or equal to 100° C., higher than or equal to 250° C., or higher than or equal to 350° C. and lower than or equal to 650° C., lower than or equal to 600° C., lower than or equal to 550° C., or lower than or equal to 400° C. Note that the heat treatment is performed in a nitrogen gas or inert gas atmosphere, or an atmosphere including an oxidizing gas at higher than or equal to 10 ppm, higher than or equal to 1%, or higher than or equal to 10%. For example, it is preferable that the flow rate ratio of a nitrogen gas to an oxygen gas be 4:1 and the heat treatment be performed at a temperature of 350° C. for one hour in an atmosphere including oxygen. Accordingly, oxygen can be supplied to the oxide 230a and the oxide 230b to reduce oxygen vacancies. In addition, the crystallinity of the oxide 230b can be improved by such heat treatment. Furthermore, hydrogen remaining in the oxide 230a and the oxide 230b reacts with supplied oxygen, so that the hydrogen can be removed in the form of H₂O (dehydration). This can inhibit recombination of hydrogen remaining in the oxide 230a and the oxide 230b with oxygen vacancies and formation of VoH. Accordingly, the transistor including the oxide 230 can have favorable electrical characteristics and higher reliability. In addition, variations in electrical characteristics among a plurality of transistors formed over the same substrate can be reduced. Note that the heat treatment may be performed under reduced pressure. Alternatively, heat treatment may be performed in an oxygen atmosphere, and then heat treatment may be successively performed in a nitrogen atmosphere without exposure to the air.

In the case where heat treatment is performed in the state where the conductor 242a and the conductor 242b are in contact with the oxide 230b, the sheet resistance of the oxide 230b in a region overlapping with the conductor 242a and a region overlapping with the conductor 242b is decreased in some cases. Furthermore, the carrier concentration is sometimes increased. Thus, the resistance of the oxide 230b in the region overlapping with the conductor 242a and the region overlapping with the conductor 242b can be lowered in a self-aligned manner.

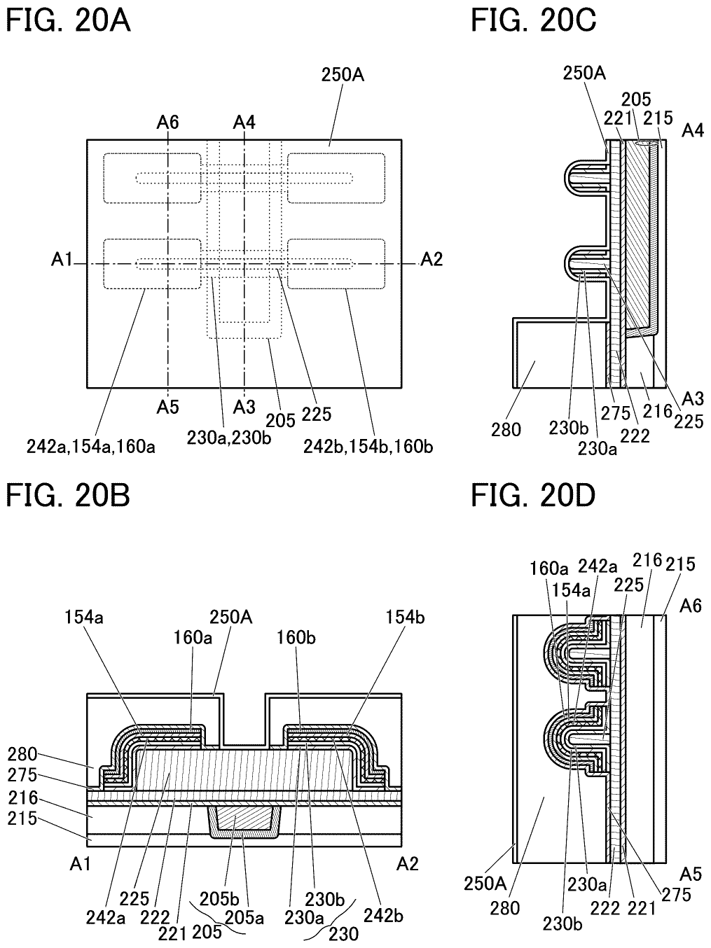

Next, an insulating film 250A to be the insulator 250 is deposited to fill the opening formed in the insulator 280 and the like (see FIG. 20A to FIG. 20D). Here, the insulating film 250A is in contact with the insulator 280, the insulator 275, the insulator 222, the insulator 225, the oxide 230a, and the oxide 230b.

The insulating film 250A can be formed by a sputtering method, a CVD method, an MBE method, a PLD method, or an ALD method. The insulating film 250A is preferably deposited by an ALD method, for example. Like the insulator 250 described above, the insulating film 250A is preferably formed to have a small thickness, and a variation in the film thickness needs to be reduced. Since an ALD method is a deposition method in which a precursor and a reactant (e.g., oxidizer) are alternately introduced and the film thickness can be adjusted with the number of cycles repeated, accurate control of the film thickness is possible. Furthermore, the insulator film 250A needs to be deposited to favorably cover the bottom surface and the side surface of the opening. By an ALD method, atomic layers can be deposited one by one along the bottom surface and the side surface of the opening, whereby the insulator film 250A can be formed in the opening with good coverage.

In the case where the insulating film 250A is formed by an ALD method, ozone (O₃), oxygen (O₂), water (H₂O), or the like can be used as the oxidizer. When an oxidizer without including hydrogen, such as ozone (O₃) or oxygen (O₂), is used, the amount of hydrogen diffusing into the oxide 230b can be reduced.

The insulator 250 can have a stacked-layer structure as illustrated in FIG. 3 and the like. For example, as illustrated in FIG. 3A, the insulator 250 can have a stacked-layer structure of the insulator 250a to the insulator 250d. In that case, aluminum oxide can be deposited by a thermal ALD method as the insulator 250a, silicon oxide can be deposited by a PEALD method as the insulator 250b, hafnium oxide can be deposited by a thermal ALD method as the insulator 250c, and silicon nitride can be deposited by a PEALD method as the insulator 250d.

Microwave treatment is preferably performed in an oxygen-including atmosphere after the deposition of the insulating film 250A or after the deposition of any of the insulators included in the insulating film 250A. Here, the microwave treatment refers to, for example, treatment using an apparatus including a power source that generates high-density plasma with the use of a microwave. In this specification and the like, a microwave refers to an electromagnetic wave having a frequency higher than or equal to 300 MHz and lower than or equal to 300 GHz.

The microwave treatment is preferably performed with a microwave treatment apparatus including a power source for generating high-density plasma using microwaves, for example. Here, the frequency of the microwave treatment apparatus is preferably set to higher than or equal to 300 MHz and lower than or equal to 300 GHz, further preferably higher than or equal to 2.4 GHz and lower than or equal to 2.5 GHZ, and can be set to 2.45 GHz, for example. Oxygen radicals at a high density can be generated with high-density plasma. The electric power of the power source that applies microwaves of the microwave treatment apparatus is preferably set to higher than or equal to 1000 W and lower than or equal to 10000 W, further preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently.

The microwave treatment is preferably performed under reduced pressure, and the pressure is preferably set to higher than or equal to 10 Pa and lower than or equal to 1000 Pa, further preferably higher than or equal to 300 Pa and lower than or equal to 700 Pa. The treatment temperature is preferably set to lower than or equal to 750° C., further preferably lower than or equal to 500° C., and can be approximately 250° C., for example. The oxygen plasma treatment may be followed successively by heat treatment without exposure to the external air. The temperature of the heat treatment is preferably higher than or equal to 100° C. and lower than or equal to 750° C., further preferably higher than or equal to 300° C. and lower than or equal to 500° C., for example.

The microwave treatment can be performed using an oxygen gas and an argon gas, for example. Here, the oxygen flow rate ratio (O₂/(O₂+Ar)) is higher than 0% and lower than or equal to 100%. The oxygen flow rate ratio (O₂/(O₂+Ar)) is preferably higher than 0% and lower than or equal to 50%. The oxygen flow rate ratio (O₂/(O₂+Ar)) is further preferably higher than or equal to 10% and lower than or equal to 40%. The oxygen flow rate ratio (02/(O₂+Ar)) is still further preferably higher than or equal to 10% and lower than or equal to 30%. The carrier concentration in the oxide 230b can be reduced by thus performing the microwave treatment in an oxygen-including atmosphere. In addition, the carrier concentrations in the oxide 230b can be prevented from being excessively reduced by preventing an excess amount of oxygen from being introduced into the chamber in the microwave treatment.

The microwave treatment in an oxygen-including atmosphere can convert an oxygen gas into plasma using a high-frequency wave such as a microwave or RF, and apply the oxygen plasma to a region of the oxide 230b which is between the conductor 242a and the conductor 242b. By the effect of the plasma, the microwave, or the like, VoH in the region can be separated into an oxygen vacancy and hydrogen, and hydrogen can be removed from the region. Here, in the case of employing the structure illustrated in FIG. 3A and the like, an insulating film having a function of capturing or fixing hydrogen (e.g., aluminum oxide) is preferably used as the insulator 250a. With such a structure, hydrogen generated by the microwave treatment can be captured or fixed in the insulator 250a. Accordingly, VoH included in the channel formation region can be reduced. In the above manner, oxygen vacancies and VoH in the channel formation region can be reduced to lower the carrier concentration. In addition, oxygen radicals generated by the oxygen plasma can be supplied to oxygen vacancies in the channel formation region, thereby further reducing oxygen vacancies in the channel formation region and lowering the carrier concentration.

The oxygen implanted into the channel formation region has any of a variety of forms such as an oxygen atom, an oxygen molecule, an oxygen ion, and an oxygen radical (also referred to as O radical, which is an atom, a molecule, or an ion having an unpaired electron). Note that the oxygen implanted into the channel formation region has any one or more of the above forms, particularly suitably an oxygen radical. Furthermore, the film quality of the insulator 250 can be improved, leading to higher reliability of the transistor.

Furthermore, the microwave treatment can remove impurities such as carbon in the oxide 230b. With the removal of carbon, which is an impurity in the oxide 230b, the crystallinity of the oxide 230b can be improved. Accordingly, the oxide 230b can be a CAAC-OS. Particularly in the case where the oxide 230b is deposited by an ALD method, carbon included in a precursor is sometimes taken into the oxide 230b; thus, carbon is preferably removed by the microwave treatment.

Meanwhile, the oxide 230b includes a region overlapping with the conductor 242a or 242b. The region can function as a source region or a drain region. Here, the conductors 242a and 242b preferably function as blocking films preventing the effect caused by the high-frequency wave such as a microwave or RF, the oxygen plasma, or the like in the microwave treatment in an oxygen-including atmosphere. Therefore, the conductors 242a and 242b preferably have a function of blocking an electromagnetic wave higher than or equal to 300 MHz and lower than or equal to 300 GHz, for example, higher than or equal to 2.4 GHz and lower than or equal to 2.5 GHz.

The effect of the high-frequency wave such as a microwave or RF, the oxygen plasma, or the like is blocked by the conductors 242a and 242b and does not affect the region of the oxide 230b overlapping with the conductor 242a or 242b. Hence, a reduction in VoH and supply of an excess amount of oxygen do not occur in the source region and the drain region in the microwave treatment, preventing a decrease in carrier concentration.

In the above manner, oxygen vacancies and VoH can be selectively removed from the channel formation region in the oxide semiconductor, whereby the channel formation region can be an i-type or substantially i-type region. Furthermore, supply of an excess amount of oxygen to the regions functioning as the source region and the drain region can be inhibited, and the conductivity (the state of the low-resistance regions) before the microwave treatment is performed can be maintained. As a result, a change in the electrical characteristics of the transistor can be inhibited, and thus a variation in the electrical characteristics of transistors in the substrate plane can be inhibited.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an oxygen-including atmosphere, an effect equivalent to that of oxygen annealing is sometimes obtained. In the case where hydrogen is included in the oxide 230b, it is probable that the thermal energy is transmitted to the hydrogen in the oxide 230b and the hydrogen activated by the energy is released from the oxide 230b.

Furthermore, the microwave treatment improves the film quality of the insulator 250, thereby inhibiting diffusion of hydrogen, water, impurities, and the like. Accordingly, hydrogen, water, impurities, and the like can be inhibited from diffusing into the oxide 230b, the oxide 230a, and the like through the insulator 250 in a later step such as deposition of a conductive film to be the conductor 260 or later treatment such as heat treatment. By thus improving the film quality of the insulator 250, the reliability of the transistor can be improved.

After the microwave treatment, heat treatment may be performed with the reduced pressure being maintained. Such treatment enables hydrogen in the insulating film, the oxide 230b, and the oxide 230a to be removed efficiently. Part of hydrogen is gettered by the conductors 242a and 242b in some cases. Alternatively, the step of performing microwave treatment and then performing heat treatment with the reduced pressure being maintained may be repeated a plurality of cycles. The repetition of the heat treatment enables hydrogen in the insulating film, the oxide 230b, and the oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

In the case where the insulator 250 has a stacked-layer structure of the insulator 250a to the insulator 250d, microwave treatment is preferably performed after the deposition of the insulator 250b. Furthermore, after the insulator 250c is deposited, microwave treatment may be performed one more time. In the above manner, the microwave treatment in an oxygen-including atmosphere may be performed multiple times (at least two or more times).

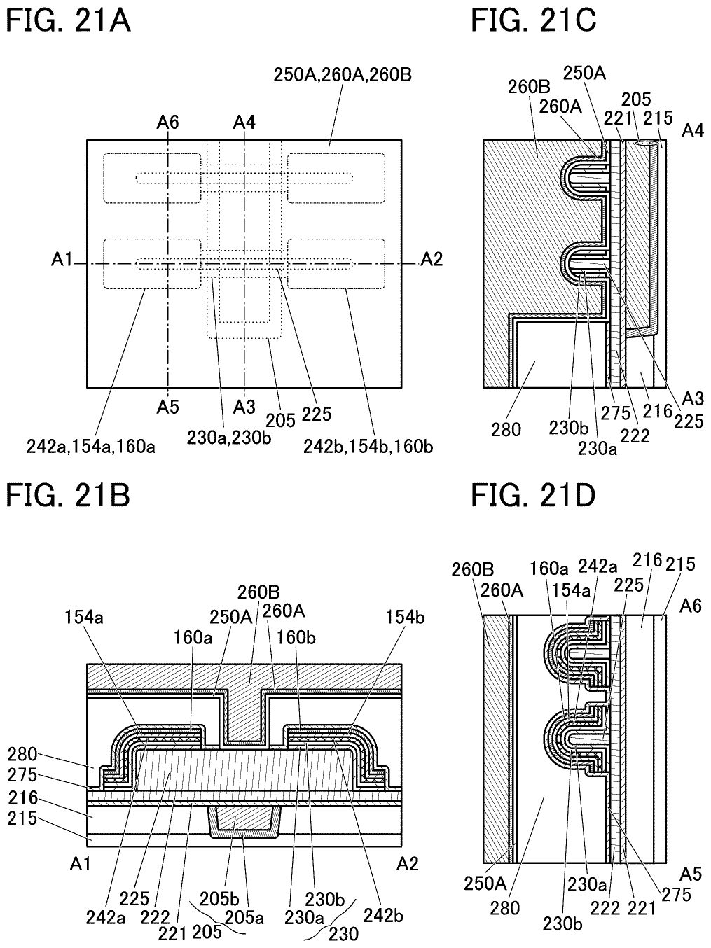

Next, a conductive film 260A to be the conductor 260a and a conductive film 260B to be the conductor 260b are formed in this order (see FIG. 21A to FIG. 21D). The conductive film 260A and the conductive film 260B can each be formed by a sputtering method, a CVD method, an MBE method, a PLD method, a plating method, or an ALD method, for example. In this embodiment, titanium nitride is deposited by an ALD method for the conductive film 260A, and tungsten is deposited by a CVD method for the conductive film 260B.

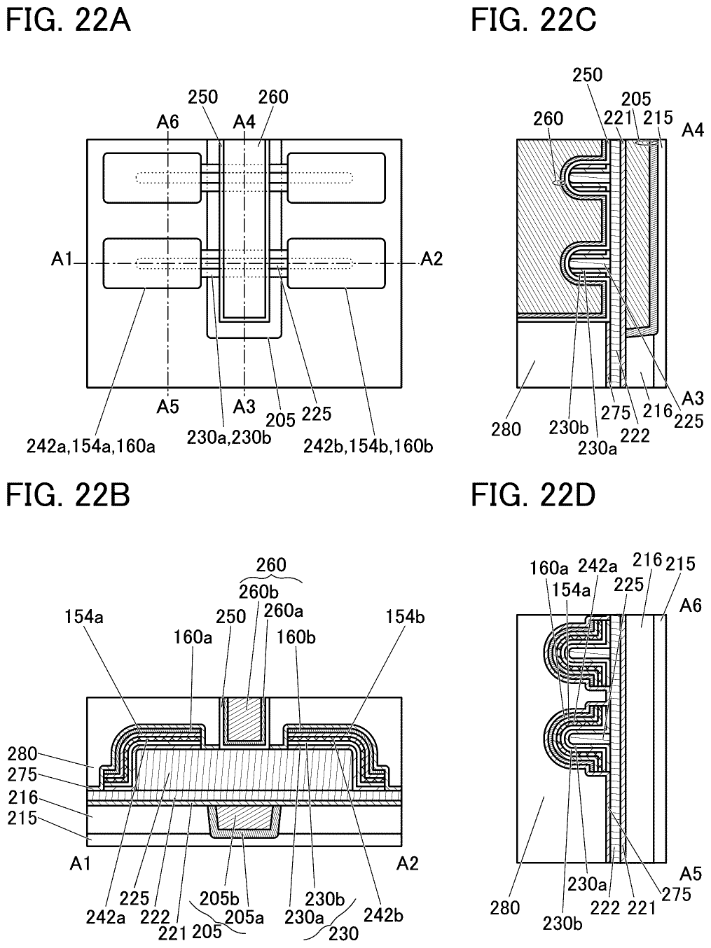

Then, the insulating film 250A, the conductive film 260A, and the conductive film 260B are polished by CMP treatment until the insulator 280 is exposed. That is, portions of the insulating film 250A, the conductive film 260A, and the conductive film 260B exposed at the opening are removed. Thus, the insulator 250 and the conductor 260 (the conductor 260a and the conductor 260b) are formed in the opening overlapping with the conductor 205 (see FIG. 22A to FIG. 22D).

Thus, the insulator 250 is provided in contact with the insulator 280, the insulator 275, the insulator 225, the oxide 230b, the oxide 230a, and the insulator 222 in the opening. The conductor 260 is placed to fill the opening with the insulator 250 therebetween. In this manner, the transistor 200 is formed.

Next, the insulator 282 is formed over the insulator 250, the conductor 260, and the insulator 280. The insulator 282 can be deposited by a sputtering method, a CVD method, an MBE method, a PLD method, or an ALD method, for example. The insulator 282 is preferably deposited by a sputtering method. With the use of a sputtering method that does not need to use a molecule including hydrogen as a deposition gas, the hydrogen concentration in the insulator 282 can be reduced.

When the insulator 282 is deposited by a sputtering method in an oxygen-including atmosphere, oxygen can be added to the insulator 280 during the deposition. Thus, excess oxygen can be included in the insulator 280. At this time, the insulator 282 is preferably deposited while the substrate is being heated. With the deposition of the insulator 282 in such a manner, a suitable amount of oxygen can be supplied to the oxide 230b by diffusion from the insulator 280 to the oxide 230b through the insulator 250. When the insulator 250a is provided in the insulator 250, an excess amount of oxygen can be prevented from being supplied to the insulator 250 and the conductors 242a and 242b in the vicinity of the insulator 250 can be prevented from being excessively oxidized.

In this embodiment, for the insulator 282, aluminum oxide is deposited by a sputtering method using an aluminum target in an atmosphere including an oxygen gas. The amount of oxygen implanted, by a sputtering method, into a layer below the insulator 282 can be controlled depending on the amount of RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases. With low RF power, the amount of oxygen implanted into the insulator 280 can be reduced. Alternatively, the insulator 282 may have a stacked-layer structure of two layers. In this case, for example, the lower layer of the insulator 282 is deposited with no RF power applied to the substrate, and the upper layer of the insulator 282 is deposited with an RF power applied to the substrate.

The RF frequency is preferably higher than or equal to 10 MHz. The typical frequency is 13.56 MHz. The higher the RF frequency is, the less damage the substrate receives.

Note that heat treatment may be performed before the deposition of the insulator 282. The heat treatment may be performed under reduced pressure, and the insulator 282 may be successively deposited without exposure to the air. Such treatment can remove moisture and hydrogen adsorbed onto the surface of the insulator 280, and further can reduce the moisture concentration and the hydrogen concentration in the insulator 280. The heat treatment temperature is preferably higher than or equal to 100° C. and lower than or equal to 400° C. In this embodiment, the heat treatment is performed at 250° C.

Subsequently the insulator 283 is formed over the insulator 282. The insulator 283 can be deposited by a sputtering method, a CVD method, an MBE method, a PLD method, or an ALD method, for example. The insulator 283 is preferably deposited by a sputtering method. With the use of a sputtering method that does not need to use a molecule including hydrogen as a deposition gas, the hydrogen concentration in the insulator 283 can be reduced. In this embodiment, for the insulator 283, silicon nitride is deposited by a sputtering method.

Here, it is preferable that the insulator 282 and the insulator 283 be successively deposited without being exposed to the atmospheric environment. By the deposition without exposure to the air, impurities or moisture from the atmospheric environment can be prevented from being attached onto the insulator 282 and the insulator 283, so that the interface between the insulator 282 and the insulator 283 or the vicinity of the interface can be kept clean.

Heat treatment may be performed after the insulator 283 is deposited. The heat treatment temperature is preferably higher than or equal to 100° C. and lower than or equal to 400° C. By the heat treatment, hydrogen included in the insulator 280, the insulator 250, and the oxide 230 is absorbed by the insulator 282. In other words, hydrogen included in the insulator 280, the insulator 250, and the oxide 230 diffuses into the insulator 282. Accordingly, the hydrogen concentration in the insulator 282 increases, and the hydrogen concentrations in the insulator 280, the insulator 250, and the oxide 230 decrease. Note that the insulator 283 is provided in contact with the top surface of the insulator 282, which can prevent entry of moisture or impurities such as hydrogen from a component above the insulator 283 in the heat treatment. By the heat treatment, hydrogen included in the oxide 230 is absorbed by the insulator 222. In other words, hydrogen included in the oxide 230 diffuses into the insulator 222. Accordingly, the hydrogen concentration in the insulator 222 increases; meanwhile, the hydrogen concentration in the oxide 230 decreases. Note that the insulator 221 is provided in contact with the bottom surface of the insulator 222, whereby entry of moisture or impurities such as hydrogen from below the insulator 221, which is caused by the heat treatment, can be prevented.

Next, an opening reaching the conductor 160a is formed in the insulator 275, the insulator 280, the insulator 282, and the insulator 283, and an opening reaching the conductor 242b is formed in the insulator 154b, the conductor 160b, the insulator 275, the insulator 280, the insulator 282, and the insulator 283 (see FIG. 1A to FIG. 1D). The openings are formed by a lithography method. Note that the openings in the top view in FIG. 1A each have a circular shape; however, the shapes of the openings are not limited thereto. For example, the openings in the top view may have an almost circular shape such as an elliptical shape, a polygonal shape such as a quadrangular shape, or a polygonal shape with rounded corners such as a quadrangular shape with rounded corners.

Next, an insulating film to be the insulator 241 is deposited and then subjected to anisotropic etching, so that the insulator 241a is formed in the opening reaching the conductor 160a and the insulator 241b is formed in the opening reaching the conductor 242b (see FIG. 1A to FIG. 1D). The insulating film to be the insulator 241 can be deposited by a sputtering method, a CVD method, an MBE method, a PLD method, an ALD method, or the like. As the insulating film to be the insulator 241, an insulating film having a function of inhibiting passage of oxygen is preferably used. For example, preferably, aluminum oxide is deposited by an ALD method and silicon nitride is deposited thereover by a PEALD method. Silicon nitride is preferable because it has a high blocking property against hydrogen.

As an anisotropic etching for the insulating film to be the insulator 241, a dry etching method may be employed, for example. When the insulator 241 is provided on the sidewall portions of the openings, passage of oxygen from the outside can be inhibited and oxidation of the conductor 240a and the conductor 240b to be formed next can be prevented. Furthermore, impurities such as water and hydrogen included in the insulator 280 or the like can be prevented from diffusing into the conductor 240a and the conductor 240b.

Next, a conductive film to be the conductor 240a and the conductor 240b is deposited. The conductive film to be the conductor 240a and the conductor 240b desirably has a stacked-layer structure which includes a conductor having a function of inhibiting passage of impurities such as water and hydrogen. For example, a stacked layer of tantalum nitride, titanium nitride, or the like and tungsten, molybdenum, copper, or the like can be employed. The conductive film to be the conductor 240a and the conductor 240b can be deposited by a sputtering method, a CVD method, an MBE method, a PLD method, an ALD method, or the like.

Then, part of the conductive film to be the conductor 240a and the conductor 240b is removed by CMP treatment to expose the top surface of the insulator 283. As a result, the conductive film remains only in the openings, so that the conductor 240a and the conductor 240b having flat top surfaces can be formed (see FIG. 1A to FIG. 1D). Note that the top surface of the insulator 283 is partly removed by the CMP treatment in some cases.

When the conductor 240a in contact with the conductor 160a is provided as described above, the conductor 160a functioning as one terminal of the capacitor 100 can be electrically connected to a wiring.

When the conductor 240b is provided in contact with the conductor 242b, the conductor 240b functioning as the one of the source and the drain of the transistor 200 can be electrically connected to a wiring. Here, the conductor 240b is preferably electrically insulated from the conductor 160b with the insulator 241b therebetween.

Note that a conductive film functioning as a wiring or a conductive film functioning as a plug can be formed over the conductor 240a and the conductor 240b.

Through the above steps, the memory device illustrated in FIG. 1 can be manufactured.

This embodiment can be combined with the other embodiments as appropriate. In this specification, in the case where a plurality of structure examples are shown in one embodiment, the structure examples can be combined as appropriate.

### Embodiment 2

In this embodiment, the comparison between the OS transistor described in the above embodiment and a transistor including silicon in a channel formation region (also referred to as a Si transistor) will be described.

### [OS Transistor]

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet still further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

Accordingly, in order to obtain stable electrical characteristics of the transistor, reducing the concentration of impurities in the oxide semiconductor is effective. In order to reduce the impurity concentration in the oxide semiconductor, the impurity concentration in a film that is adjacent to the oxide semiconductor is preferably reduced. As examples of the impurity, hydrogen, nitrogen, and the like are given. Note that an impurity in an oxide semiconductor refers to, for example, elements other than the main components of the oxide semiconductor. For example, an element with a concentration lower than 0.1 atomic % is regarded as an impurity.

When impurities and oxygen vacancies are in a channel formation region of an oxide semiconductor in an OS transistor, electrical characteristics of the OS transistor easily vary and the reliability thereof might worsen. In the OS transistor, a defect that is an oxygen vacancy in the oxide semiconductor into which hydrogen enters (hereinafter sometimes referred to as VoH) may be formed and may generate an electron serving as a carrier. When VoH is formed in the channel formation region, the donor concentration in the channel formation region increases in some cases. As the donor concentration in the channel formation region increases, the threshold voltage might vary. Therefore, when the channel formation region in the oxide semiconductor includes oxygen vacancies, the transistor is likely to have normally-on characteristics (characteristics with which, even when no voltage is applied to the gate electrode, the channel exists and a current flows through the transistor). Therefore, impurities, oxygen vacancies, and VoH are preferably reduced as much as possible in the channel formation region in the oxide semiconductor.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. Thus, it is difficult to miniaturize the Si transistor. One factor that causes the short-channel effect is a small band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

The short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometimes also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. When the characteristic length is shorter, the potential rises more sharply, which means that the resistance to a short-channel effect is high.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Therefore, an OS transistor has higher resistance to a short-channel effect than a Si transistor. That is, in the case where a transistor with a short channel length is to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region might decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions in the OS transistor.

An OS transistor having the above-described structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to nm. By contrast, it is sometimes difficult for the Si transistor to have a gate length less than or equal to 20 nm or less than or equal to 15 nm because of the appearance of the short-channel effect. Therefore, an OS transistor can be suitably used as a transistor having a short channel length as compared with a Si transistor. Note that the gate length refers to the length of a gate electrode in a direction in which carriers move inside a channel formation region during operation of the transistor and to the width of the bottom surface of the gate electrode in a top view of the transistor.

Miniaturization of an OS transistor can improve the frequency characteristics of the transistor. Specifically, the cutoff frequency of the transistor can be improved. When the gate length of the OS transistor is within the above-described range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

The configuration, structure, method, or the like described in this embodiment can be used in combination with the configuration, structure, method, or the like described in the other embodiments and the like as appropriate.

### Embodiment 3

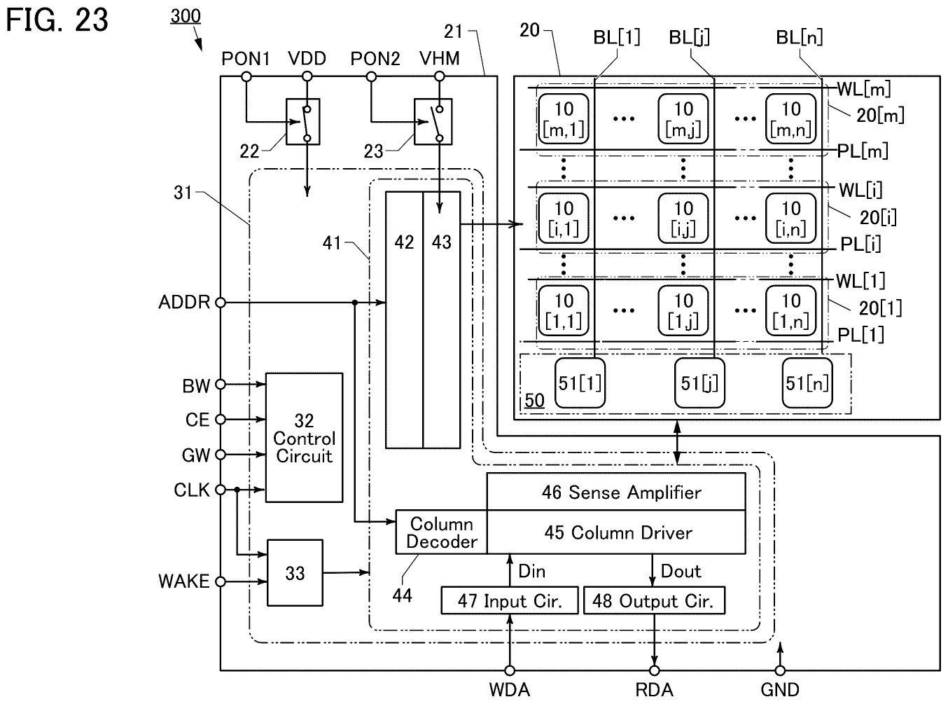

In this embodiment, a memory device using one embodiment of the present invention will be described with reference to FIG. 23 to FIG. 28.

In this embodiment, a structure example of a memory device using a memory cell having the structure described in the above embodiment will be described. In this embodiment, a structure example of a memory device provided with stacked layers including memory cells and a layer including a functional circuit having functions of amplifying and outputting a data potential retained in a memory cell will be described.

### Structure Example of Memory Device

FIG. 23 is a block diagram of the memory device of one embodiment of the present invention.

A memory device 300 illustrated in FIG. 23 includes a driver circuit 21 and a memory array 20. The memory array 20 includes a plurality of memory cells 10 and a functional layer 50 including a plurality of functional circuits 51.

FIG. 23 illustrates an example in which the memory array 20 includes the plurality of memory cells 10 placed in a matrix of m rows and n columns (each of m and nis an integer greater than or equal to 2). In the example illustrated in FIG. 23, the functional circuit 51 is provided for each wiring BL functioning as a bit line, and the functional layer 50 includes n functional circuits 51 that are provided to correspond to n wirings BL.

In FIG. 23, the memory cell 10 in the first row and the first column is referred to as a memory cell 10[1,1], and the memory cell 10 in the m-th row and the n-th column is referred to as a memory cell 10[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 10 in the i-th row and the j-th column is denoted as a memory cell 10[i,j]. Note that in this embodiment and the like, “i+a” (a is a positive or negative integer) is not below 1 and does not exceed m. Similarly, “j+a” is not below 1 and does not exceed n.

The memory array 20 includes m wirings WL extending in the row direction, m wirings PL extending in the row direction, and the n wirings BL extending in the column direction. In this embodiment and the like, a first wiring WL (provided in the first row) is denoted as a wiring WL[1], and an m-th wiring WL (provided in the m-th row) is denoted as a wiring WL[m]. Similarly, a first wiring PL (provided in the first row) is denoted as a wiring PL [1], and an m-th wiring PL (provided in the m-th row) is denoted as a wiring PL [m]. Similarly, a first wiring BL (provided in the first column) is denoted as a wiring BL [1], and an n-th wiring BL (provided in the n-th column) is denoted as a wiring BL [n].

A plurality of the memory cells 10 provided in the i-th row are electrically connected to the wiring WL in the i-th row (wiring WL[i]) and the wiring PL in the i-th row (wiring PL [i]). A plurality of the memory cells 10 provided in the j-th column are electrically connected to the wiring BL in the j-th column (wiring BL [j]).

A DOSRAM (registered trademark) (Dynamic Oxide Semiconductor Random Access Memory) can be used for the memory array 20. A DOSRAM is a RAM including a 1T (transistor) 1C (capacitor) memory cell and refers to a memory in which an access transistor is an OS transistor. A current flowing between a source and a drain in an off state, that is, a leakage current, is extremely low in an OS transistor. A DOSRAM can retain electric charges corresponding to data stored in a capacitor for a long time by turning off an access transistor (by bringing the access transistor into a non-conducting state). For this reason, the refresh operation frequency of a DOSRAM can be lower than that of a DRAM formed with a transistor containing silicon in its channel formation region (a Si transistor). As a result, power consumption can be reduced. The OS transistor also has excellent frequency characteristics and thus enables high-speed reading and writing of the memory device. Hence, a memory device that can operate at high speed can be provided.

In the memory array 20 illustrated in FIG. 23, a plurality of memory arrays 20[1] to [m] can be stacked. When the memory arrays 20[1] to 20[m] included in the memory array 20 are placed in the direction perpendicular to the surface of a substrate provided with the driver circuit 21, the memory density of the memory cells 10 can be increased.

The wiring BL functions as a bit line for writing and reading data. The wiring WL functions as a word line for controlling the on and off state (conducting and non-conducting state) of an access transistor functioning as a switch. The wiring PL has a function of a constant potential line connected to a capacitor. Note that a wiring CL (not illustrated) can be additionally provided as a wiring having a function of supplying a back gate potential to a back gate of an OS transistor serving as the access transistor. Alternatively, the wiring PL may also have a function of supplying the back gate potential.

The memory cell 10 included in each of the memory arrays 20[1] to 20[m] is connected to the functional circuit 51 through the wiring BL. The wiring BL can be placed in the direction perpendicular to the surface of the substrate provided with the driver circuit 21. Since the wiring BL provided to extend from the memory cells 10 included in the memory arrays 20[1] to 20[m] is provided in the direction perpendicular to the surface of the substrate, the length of the wiring between the memory array 20 and the functional circuit 51 can be shortened. Accordingly, a signal transmission distance between the two circuits connected to the bit line can be shortened, and the resistance and parasitic capacitance of the bit line can be significantly reduced; thus, power consumption and signal delays can be reduced. Moreover, even when the capacitance of the capacitors included in the memory cells 10 is reduced, the memory device can be made to operate.

The functional circuit 51 has functions of amplifying a data potential retained in the memory cell 10 and outputting the amplified data potential to a sense amplifier 46 included in the driver circuit 21 through a later-described wiring GBL (not illustrated). With this structure, a slight difference in the potential of the wiring BL can be amplified at the time of data reading. Like the wiring BL, the wiring GBL can be placed in the direction perpendicular to the surface of the substrate provided with the driver circuit 21. Since the wiring BL and the wiring GBL provided to extend from the memory cells 10 included in the memory arrays 20[1] to 20[m] are provided in the direction perpendicular to the surface of the substrate, the length of the wiring between the functional circuit 51 and the sense amplifier 46 can be shortened. Accordingly, a signal transmission distance between the two circuits connected to the wiring GBL can be shortened, and the resistance and parasitic capacitance of the wiring GBL can be significantly reduced; thus, power consumption and signal delays can be reduced.

Note that the wiring BL is provided in contact with a semiconductor layer of the transistor included in the memory cell 10. Alternatively, the wiring BL is provided in contact with a region functioning as a source or a drain in the semiconductor layer of the transistor included in the memory cell 10. Alternatively, the wiring BL is provided in contact with a conductor provided in contact with the region functioning as the source or the drain in the semiconductor layer of the transistor included in the memory cell 10. That is, the wiring BL is a wiring for electrically connecting one of the source and the drain of the transistor included in the memory cell 10 in each layer of the memory array 20 to the functional circuit 51 in the perpendicular direction.

The memory array 20 can be provided over the driver circuit 21 to overlap therewith. When the driver circuit 21 and the memory array 20 are provided to overlap with each other, a signal transmission distance between the driver circuit 21 and the memory array 20 can be shortened. Accordingly, resistance and parasitic capacitance between the driver circuit 21 and the memory array 20 are reduced, so that power consumption and signal delays can be reduced. In addition, the memory device 300 can be downsized.

The functional circuit 51 can be placed at any desired position, e.g., over a circuit that is formed using Si transistors in a manner similar to that of the memory arrays 20[1] to 20[m] when being formed with an OS transistor like the transistor included in the memory cell 10 of the DOSRAM, whereby integration can be easily performed. With the structure in which a signal is amplified by the functional circuit 51, a circuit in a subsequent stage, such as the sense amplifier 46, can be downsized; hence, the memory device 300 can be downsized.

The driver circuit 21 includes a PSW 22 (power switch), a PSW 23, and a peripheral circuit 31. The peripheral circuit 31 includes a peripheral circuit 41, a control circuit 32, and a voltage generation circuit 33.

In the memory device 300, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 300. For example, the control circuit performs a logical operation on the signal CE, the signal GW, and the signal BW to determine an operation mode (e.g., a writing operation or a reading operation) of the memory device 300. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for performing writing and reading of data to/from the memory cells 10. Moreover, the peripheral circuit 41 is a circuit that outputs signals for controlling the functional circuits 51. The peripheral circuit 41 includes a row decoder 42, a column decoder 44, a row driver 43, a column driver 45, an input circuit 47 (Input Cir.), an output circuit 48 (Output Cir.), and the sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 10, a function of reading data from the memory cells 10, a function of retaining the read data, and the like.

The input circuit 47 has a function of retaining the signal WDA. Data retained by the input circuit 47 is output to the column driver 45. Data output from the input circuit 47 is data (Din) to be written to the memory cells 10. Data (Dout) read from the memory cells 10 by the column driver 45 is output to the output circuit 48. The output circuit 48 has a function of retaining Dout. In addition, the output circuit 48 has a function of outputting Dout to the outside of the memory device 300. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 300, a high power supply voltage is VDD and a low power supply voltage is GND (a ground potential). In addition, VHM is a high power supply voltage used to set the word line at high level and is higher than VDD. The on/off state of the PSW 22 is controlled by the signal PON1, and the on/off state of the PSW 23 is controlled by the signal PON2. The number of power domains to which VDD is supplied is one in the peripheral circuit 31 in FIG. 23 but can be more than one. In that case, a power switch is provided for each power domain.

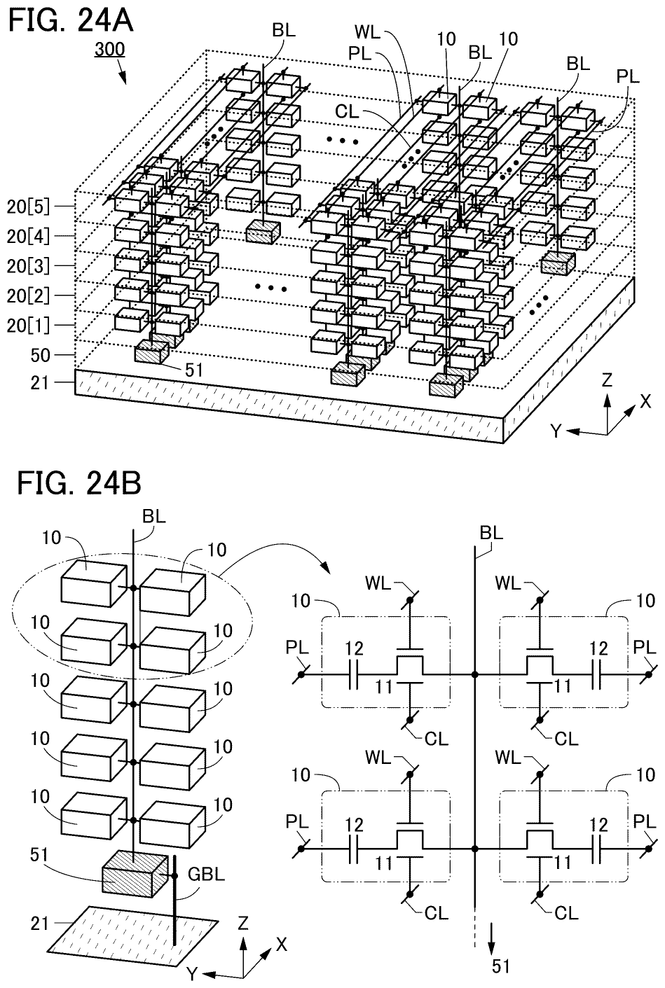

In the memory array 20 including the memory arrays 20[1] to 20[m] (m is an integer greater than or equal to 2) and the functional layer 50, the plurality of layers of memory arrays 20 can be stacked over the driver circuit 21. Stacking the plurality of layers of memory arrays 20 can increase the memory density of the memory cells 10. FIG. 24A is a perspective view of the memory device 300 that includes the functional layer 50 and five layers (m=5) of memory arrays [1] to 20[5], which overlap with each other, over the driver circuit 21.

In FIG. 24A, the memory array 20 provided in the first layer is denoted as the memory array 20[1], the memory array 20 provided in the second layer is denoted as the memory array [2], and the memory array 20 provided in the fifth layer is denoted as the memory array 20[5]. FIG. 24A also shows the wiring WL, the wiring PL, and the wiring CL provided to extend in the X direction and the wiring BL provided to extend in the Z direction (the direction perpendicular to the surface of the substrate provided with the driver circuit). For easy viewing of the drawing, some of the wirings WL and the wirings PL included in the memory arrays 20 are not illustrated.

FIG. 24B is a schematic view for describing a structure example of the functional circuit 51, which is connected to the wiring BL, and the memory cells 10 included in the memory arrays 20[1] to 20[5], which are connected to the wiring BL, illustrated in FIG. 24A. FIG. 24B illustrates the wiring GBL provided between the functional circuit 51 and the driver circuit 21. Note that a structure in which a plurality of memory cells (memory cells 10) are electrically connected to one wiring BL is also referred to as “memory string”. In the drawings, the wiring GBL is sometimes represented by a bold line for higher visibility.

FIG. 24B illustrates an example of a circuit structure of the memory cell 10 connected to the wiring BL. The memory cell 10 includes a transistor 11 and a capacitor 12. As for the transistor 11, the capacitor 12, and the wirings (e.g., the wiring BL and the wiring WL), for example, the wiring BL [1] and the wiring WL[1] are referred to as the wiring BL and the wiring WL in some cases. Here, the transistor 11 corresponds to the transistor 200 described in Embodiment 1. The capacitor 12 corresponds to the capacitor 100 described in Embodiment 1.

In the memory cell 10, one of a source and a drain of the transistor 11 is connected to the wiring BL. The other of the source and the drain of the transistor 11 is connected to one electrode of the capacitor 12. The other electrode of the capacitor 12 is connected to the wiring PL. A gate of the transistor 11 is connected to the wiring WL. A back gate of the transistor 11 is connected to the wiring CL.

The wiring PL is a wiring for supplying a constant potential for retaining the potential of the capacitor 12. The wiring CL is a wiring for supplying a constant potential for controlling the threshold voltage of the transistor 11. The wiring PL and the wiring CL may have the same potential. In that case, the number of wirings connected to the memory cell 10 can be reduced by connecting the two wirings.

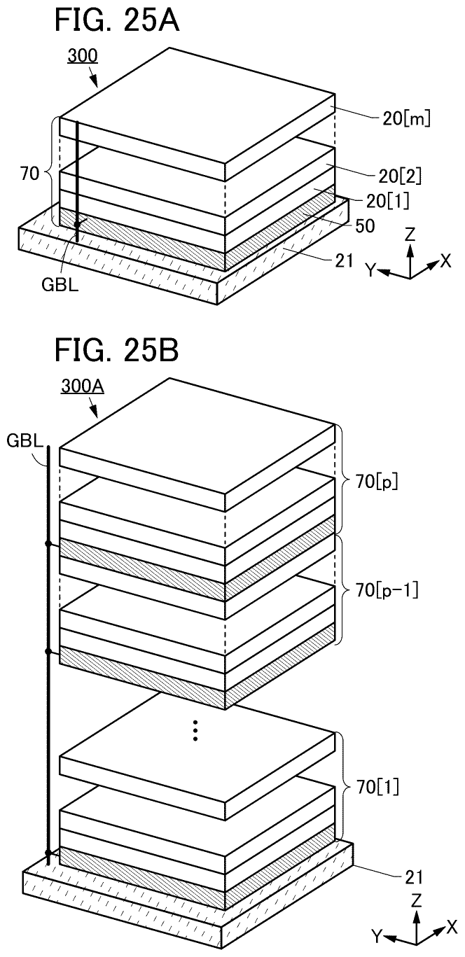

The wiring GBL illustrated in FIG. 24B is provided to electrically connect the driver circuit 21 and the functional layer 50. FIG. 25A is a schematic view of the memory device 300 in which the functional circuit 51 and the memory arrays 20[1] to 20[m] are regarded as a repeating unit 70. Although FIG. 25A illustrates one wiring GBL, the wiring GBL is provided as appropriate depending on the number of functional circuits 51 provided in the functional layer 50.

Note that the wiring GBL is provided in contact with a semiconductor layer of a transistor included in the functional circuit 51. Alternatively, the wiring GBL is provided in contact with a region functioning as a source or a drain in the semiconductor layer of the transistor included in the functional circuit 51. Alternatively, the wiring GBL is provided in contact with a conductor provided in contact with the region functioning as the source or the drain in the semiconductor layer of the transistor included in the functional circuit 51. That is, the wiring GBL can be regarded as a wiring for electrically connecting the driver circuit 21 and one of the source and the drain of the transistor included in the functional circuit 51 in the functional layer 50 in the perpendicular direction.

The repeating unit 70 including the functional circuit 51 and the memory arrays 20[1] to [m] may have a stacked-layer structure. A memory device 300A of one embodiment of the present invention can include repeating units 70[1] to 70[p] (p is an integer greater than or equal to 2) as illustrated in FIG. 25B. The wiring GBL is connected to the functional layers 50 included in the repeating units 70. The wiring GBL is provided as appropriate depending on the number of functional circuits 51.

In one embodiment of the present invention, OS transistors are provided in stacked layers and a wiring functioning as a bit line is placed in the direction perpendicular to the surface of the substrate provided with the driver circuit 21. Since the wiring that is provided to extend from the memory array 20 and functions as a bit line is provided in the direction perpendicular to the surface of the substrate, the length of the wiring between the memory array 20 and the driver circuit 21 can be shortened. Thus, the parasitic capacitance of the bit line can be significantly reduced.

In one embodiment of the present invention, the functional layer 50 including the functional circuit 51 having functions of amplifying and outputting a data potential retained in the memory cell 10 is provided in a layer where the memory array 20 is provided. With this structure, a slight difference in the potential of the wiring BL functioning as a bit line can be amplified at the time of data reading to drive the sense amplifier 46 included in the driver circuit 21. A circuit such as a sense amplifier can be downsized, so that the memory device 300 can be downsized. Moreover, even when the capacitance of the capacitors 12 included in the memory cells 10 is reduced, the memory device 300 can be made to operate.

### Structure Examples of Memory Array 20 and Functional Circuit 51

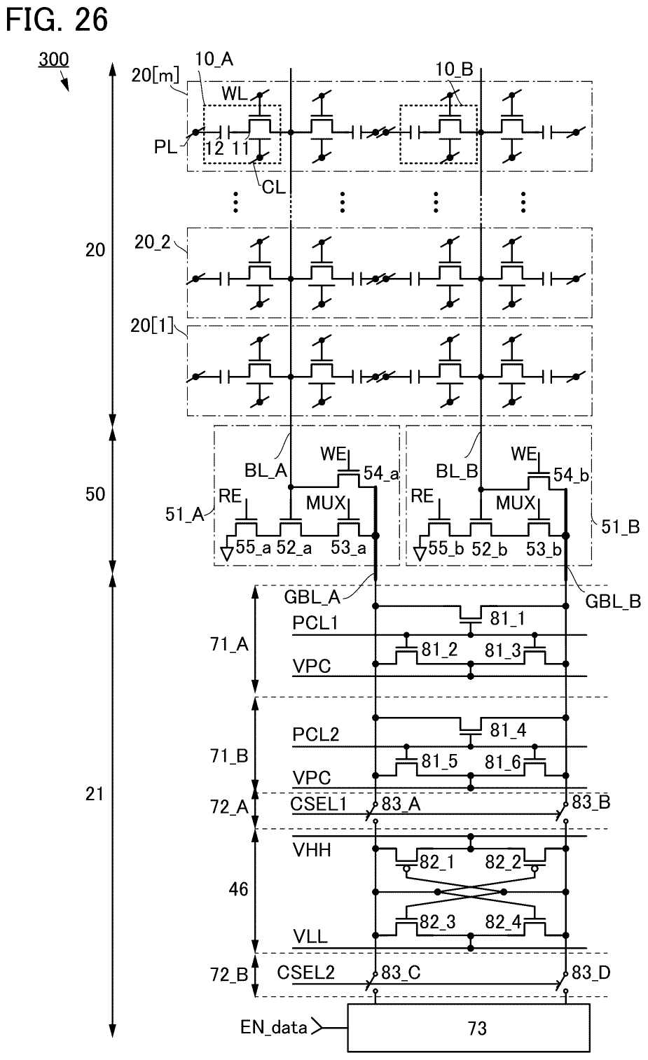

A structure example of the functional circuit 51 and structure examples of the memory array 20 and the sense amplifier 46 included in the driver circuit 21, which are described with reference to FIG. 23 to FIG. 25, are described with reference to FIG. 26. FIG. 26 illustrates the driver circuit 21 connected to the wirings GBL (a wiring GBL_A and a wiring GBL_B) connected to the functional circuits 51 (a functional circuit 51_A and a functional circuit 51_B) connected to the memory cells 10 (a memory cell 10_A and a memory cell 10_B) connected to different wirings BL (a wiring BL_A and a wiring BL_B). FIG. 26 also illustrates, as the driver circuit 21, a precharge circuit 71_A, a precharge circuit 71_B, a switch circuit 72_A, a switch circuit 72_B, and a write/read circuit 73 in addition to the sense amplifier 46.

As the functional circuits 51_A and 51_B, transistors 52_a, 52_b, 53_a, 53_b, 54_a, 54_b, 55_a, and 55_b are illustrated. The transistors 52_a, 52_b, 53_a, 53_b, 54_a, 54_b, 55_a, and 55_b illustrated in FIG. 26 are OS transistors like the transistor 11 included in the memory cell 10. The functional layer 50 including the functional circuits 51 can be provided in layers stacked over the driver circuit 21 like the memory arrays 20[1] to 20[m].

The wiring BL_A is connected to a gate of the transistor 52_a, and the wiring BL_B is connected to a gate of the transistor 52_b. One of a source and a drain of each of the transistors 53_a and 54_a is connected to the wiring GBL_A. One of a source and a drain of each of the transistors 53_b and 54_b is connected to the wiring GBL_B. The wirings GBL_A and GBL_B are provided in the perpendicular direction like the wirings BL_A and BL_B and connected to transistors included in the driver circuit 21. As illustrated in FIG. 26, a selection signal MUX, a control signal WE, or a control signal RE is supplied to gates of the transistors 53_a, 53_b, 54_a, 54_b, 55_a, and 55_b.

Transistors 81_1 to 81_6 and 82_1 to 82_4 included in the sense amplifier 46, the precharge circuit 71_A, and the precharge circuit 71_B illustrated in FIG. 26 are Si transistors. Switches 83_A to 83_D included in the switch circuit 72_A and the switch circuit 72_B can also be Si transistors. The one of the source and the drain of each of the transistors 53_a, 53_b, 54_a, and 54_b is connected to the transistor or switch included in the precharge circuit 71_A, the precharge circuit 71_B, the sense amplifier 46, or the switch circuit 72_A.

The precharge circuit 71_A includes the n-channel transistors 81_1 to 81_3. The precharge circuit 71_A is a circuit for precharging the wiring BL_A and the wiring BL_B with an intermediate potential VPC corresponding to a potential VDD/2 between a high power supply potential (VDD) and a low power supply potential (VSS) in accordance with a precharge signal supplied to a precharge line PCL1.

The precharge circuit 71_B includes the n-channel transistors 81_4 to 81_6. The precharge circuit 71_B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 46 includes the p-channel transistors 82_1 and 82_2 and the n-channel transistors 82_3 and 82_4, which are connected to a wiring VHH or a wiring VLL. The wiring VHH or the wiring VLL is a wiring having a function of supplying VDD or VSS. The transistors 82_1 to 82_4 are transistors that form an inverter loop. The potentials of the wiring BL_A and the wiring BL_B precharged are changed by selecting the memory cells 10_A and 10_B, and the potentials of the wiring GBL_A and the wiring GBL_B are set to VDD or VSS in accordance with the changes. The potentials of the wiring GBL_A and the wiring GBL_B can be output to the outside through the switch 83_C, the switch 83_D, and the write/read circuit 73. The wiring BL_A and the wiring BL_B correspond to a bit line pair, and the wiring GBL_A and the wiring GBL_B correspond to a bit line pair. Data signal writing of the write/read circuit 73 is controlled in accordance with a signal EN_data.

The switch circuit 72_A is a circuit for controlling electrical continuity between the sense amplifier 46 and each of the wiring GBL_A and the wiring GBL_B. The switch circuit 72_A is switched on or off under the control of a switch signal CSEL1. In the case where the switches 83_A and 83_B are n-channel transistors, the switches 83_A and 83_B are turned on and off when the switch signal CSEL1 is at high level and low level, respectively. The switch circuit 72_B is a circuit for controlling electrical continuity between the write/read circuit 73 and the bit line pair connected to the sense amplifier 46. The switch circuit 72_B is switched on or off under the control of a switching signal CSEL2. The switches 83_C and 83_D may operate in a manner similar to those of the switches 83_A and 83_B.

As illustrated in FIG. 26, the memory device 300 can have a structure where the memory cell 10, the functional circuit 51, and the sense amplifier 46 are connected to each other in the shortest distance through the wiring BL and the wiring GBL provided in the perpendicular direction. Even with addition of the functional layer 50 including transistors included in the functional circuits 51, the loads of the wirings BL are reduced, whereby the writing time can be shortened and data reading can be facilitated.

As illustrated in FIG. 26, the transistors included in the functional circuits 51_A and 51_B are controlled in accordance with the control signals WE and RE and the selection signal MUX. The transistors can output the potential of the wiring BL through the wiring GBL to the driver circuit 21 in accordance with the control signals and the selection signal. The functional circuits 51_A and 51_B can each function as a sense amplifier that consists of OS transistors. With this structure, a slight difference in the potential of the wiring BL can be amplified at the time of reading to drive the sense amplifier 46 formed using Si transistors.

### Structure Example of Memory Cell

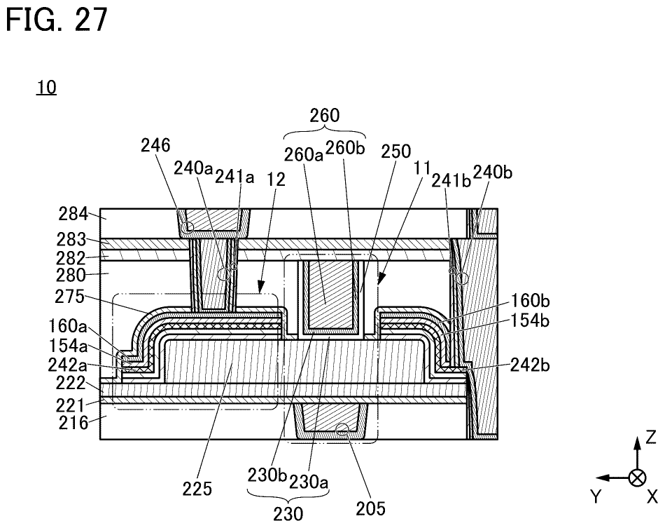

A structure example of the memory cell 10 used in the above-described memory device will be described with reference to FIG. 27.

Note that in FIG. 27, the X direction is parallel to the channel length direction of an illustrated transistor, the Y direction is perpendicular to the X direction, and the Z direction is perpendicular to the X direction and the Y direction.

As illustrated in FIG. 27, the memory cell 10 includes the transistor 11 and the capacitor 12. An insulator 284 is provided over the transistor 11. For the insulator 284, an insulator that can be used for the insulator 216 can be used. Note that the transistor 11 has the same structure as the transistor 200 described in the above embodiment, and the same components are denoted by the same reference numerals. The above embodiment can be referred to for the details of the transistor 200. The conductor 240b is provided in contact with one of the source and the drain of the transistor 11 (the conductor 242b). The conductor 240 is provided to extend in the Z direction and functions as the wiring BL. The capacitor 12 has a structure similar to that of the capacitor 100 described in the above embodiment, and the same components are denoted by the same reference numerals. The above embodiment can be referred to for the details of the capacitor 100.

The conductor 242b provided over the oxide 230 to overlap with the oxide 230 functions as a wiring electrically connected to the conductor 240b. In FIG. 27, for example, the top surface and a side end portion of the conductor 242b are electrically connected to the conductor 240b extending in the Z direction. Specifically, in FIG. 27, the top surface and the side end portion of the conductor 242b are in contact with the conductor 240b.

When the conductor 240b is in direct contact with at least one of the top surface and the side end portion of the conductor 242b, an electrode for connection does not need to be provided additionally, so that the area occupied by the memory arrays can be reduced. In addition, the integration degree of the memory cells is increased, and the memory capacity of the memory device can be increased. Note that the conductor 240b is preferably in contact with the side end portion and part of the top surface of the conductor 242b. When the conductor 240b is in contact with a plurality of surfaces of the conductor 242b, the contact resistance between the conductor 240b and the conductor 242b can be reduced.

The conductor 240b is provided in an opening formed in the insulator 216, the insulator 221, the insulator 222, the insulator 154b, the conductor 160b, the insulator 275, the insulator 280, the insulator 282, the insulator 283, and the insulator 284.

As illustrated in FIG. 27, an insulator 241b is preferably provided in contact with a side surface of the conductor 240b. Specifically, the insulator 241b is provided in contact with the inner wall of an opening in the insulator 216, the insulator 221, the insulator 222, the insulator 154b, the conductor 160b, the insulator 275, the insulator 280, the insulator 282, the insulator 283, and the insulator 284. The insulator 241 is formed also on the side surface of the oxide 230 that is formed to protrude in the opening. Here, at least part of the conductor 242b is exposed from the insulator 241b and is in contact with the conductor 240b. That is, the conductor 240b is provided to fill the opening with the insulator 241b therebetween.

As illustrated in FIG. 27, the uppermost portion of the insulator 241b formed below the conductor 242b is preferably positioned below the top surface of the conductor 242b. With this structure, the conductor 240b can be in contact with at least part of the side end portion of the conductor 242b. Note that the insulator 241 formed below the conductor 242b preferably includes a region in contact with a side surface of the oxide 230. With this structure, impurities such as water or hydrogen contained in the insulator 280 and the like can be inhibited from entering the oxide 230 through the conductor 240b.

Note that the sidewall of the opening portion in which the conductor 240b and the insulator 241b are placed may be perpendicular or substantially perpendicular to the top surface of the insulator 222 or may be tapered. The tapered sidewall can improve the coverage with the insulator 241b and the like provided in the opening portion.

A conductor 246 functioning as a wiring is preferably provided in contact with a top surface of the conductor 240a. The conductor 246 is provided to be embedded in the insulator 284. The conductor 246 functions as the wiring PL illustrated in FIG. 24A and FIG. 24B. The conductor 246 can have a structure similar to that of the conductor 205, for example.

### Structure Example of Memory Device 300

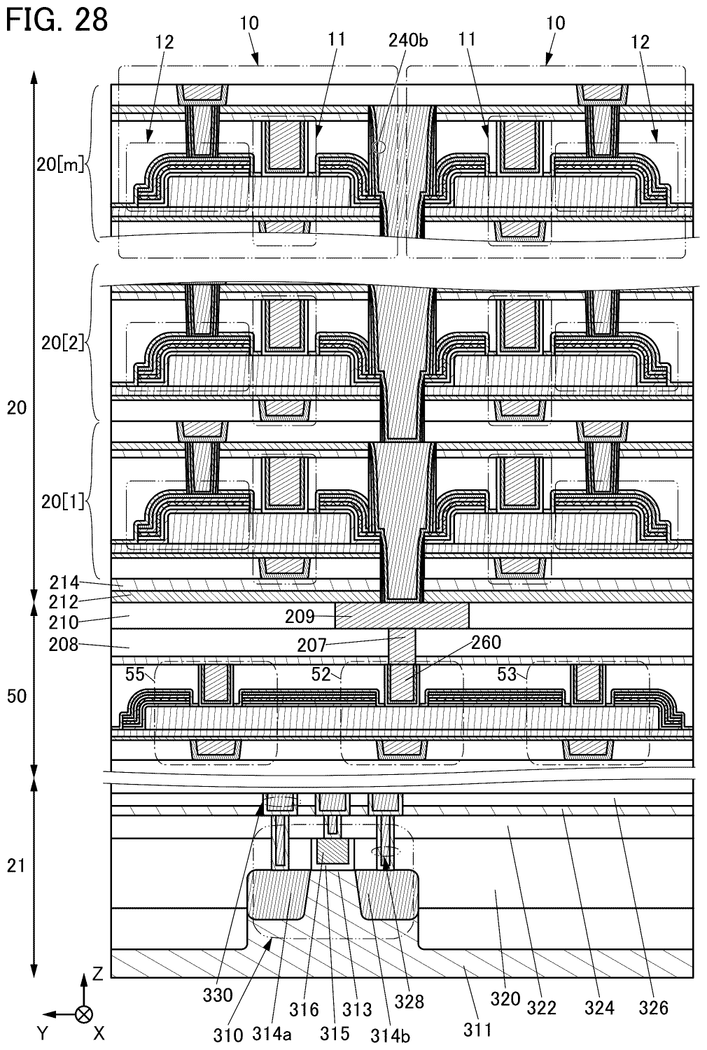

A structure example of the memory device 300 will be described with reference to FIG. 28.

The memory device 300 includes the driver circuit 21 that is a layer including a transistor 310 and the like, the functional layer 50 that is over the driver circuit 21 and is a layer including transistors 52, 53, 54, and 55 and the like, and the memory arrays 20[1] to 20[m] over the functional layer 50. Note that the transistor 52 corresponds to the transistors 52_a and 52_b, the transistor 53 corresponds to the transistors 53_a and 53_b, the transistor 54 corresponds to the transistors 54_a and 54_b, and the transistor 55 corresponds to the transistors 55_a and 55_b.

FIG. 28 illustrates the transistor 310 included in the driver circuit 21 as an example. The transistor 310 is provided on a substrate 311 and includes a conductor 316 functioning as a gate, an insulator 315 functioning as a gate insulator, a semiconductor region 313 including part of the substrate 311, and a low-resistance region 314a and a low-resistance region 314b functioning as a source region and a drain region. The transistor 310 can be a p-channel transistor or an n-channel transistor. As the substrate 311, a single crystal silicon substrate can be used, for example.

Here, in the transistor 310 illustrated in FIG. 28, the semiconductor region 313 (part of the substrate 311) in which a channel is formed has a protruding shape. Furthermore, the conductor 316 is provided to cover the side and top surfaces of the semiconductor region 313 with the insulator 315 therebetween. Note that the conductor 316 may be formed using a material for adjusting the work function. Such a transistor 310 is also referred to as a FIN-type transistor because it utilizes a protruding portion of a semiconductor substrate. An insulator functioning as a mask for forming the protruding portion may be provided in contact with an upper portion of the protruding portion. Although the case where the protruding portion is formed by processing part of the semiconductor substrate is described here, a semiconductor film having a protruding shape may be formed by processing an SOI (Silicon on Insulator) substrate.

Note that the transistor 310 illustrated in FIG. 28 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with the design. Furthermore, in this specification and the like, a wiring and a plug electrically connected to the wiring may be a single component. That is, part of a conductor functions as a wiring in some cases and part of the conductor functions as a plug in other cases.

For example, an insulator 320, an insulator 322, an insulator 324, and an insulator 326 are sequentially stacked over the transistor 310 as interlayer films. A conductor 328 and the like are embedded in the insulator 320 and the insulator 322. A conductor 330 or the like is embedded in the insulator 324 and the insulator 326. Note that the conductor 328 and the conductor 330 function as a contact plug or a wiring.

The insulator functioning as an interlayer film may function as a planarization film that covers an uneven shape thereunder. For example, the top surface of the insulator 322 may be planarized by planarization treatment using a chemical mechanical polishing (CMP) method or the like to have improved planarity.

FIG. 28 illustrates the transistors 52, 53, and 55 included in the functional layer 50 as an example. Each of the transistors 52, 53, and 55 has the same structure as the transistor 11 included in the memory cell 10. Sources and drains of the transistors 52, 53, and 55 are connected in series.

An insulator 208 is provided over the transistors 52, 53, and 55, and a conductor 207 is provided in an opening formed in the insulator 208. Furthermore, an insulator 210 is provided over the insulator 208, and a conductor 209 is provided in an opening formed in the insulator 210. Moreover, an insulator 212 is provided over the insulator 210, and the insulator 214 is provided over the insulator 212. Part of the conductor 240 provided in the memory array 20[1] is embedded in an opening formed in the insulator 212 and the insulator 214. Here, for the insulator 208 and the insulator 210, an insulator that can be used for the insulator 216 can be used. For the insulator 212, an insulator that can be used for the insulator 283 can be used. For the insulator 214, an insulator that can be used for the insulator 282 can be used.

The bottom surface of the conductor 207 is provided in contact with the top surface of the conductor 260 of the transistor 52. The top surface of the conductor 207 is provided in contact with the bottom surface of the conductor 209. The top surface of the conductor 209 is provided in contact with the bottom surface of the conductor 240 provided in the memory array 20[1]. With such a structure, the conductor 240 corresponding to the wiring BL and a gate of the transistor 52 can be electrically connected to each other.

Each of the memory arrays 20[1] to 20[m] includes a plurality of the memory cells 10. The conductor 240 included in each memory cell 10 is electrically connected to the conductor 240 in an upper layer and the conductor 240 in a lower layer.

As illustrated in FIG. 28, the conductor 240b is shared between the adjacent memory cells 10. In the adjacent memory cells 10, the components in the right memory cell and the components in the left memory cell are placed symmetrically about the conductor 240b.

In the above-described memory array 20, the plurality of memory arrays 20[1] to 20[m] can be provided to be stacked. When the memory arrays 20[1] to 20[m] included in the memory array 20 are placed in the direction perpendicular to the surface of a substrate provided with the driver circuit 21, the memory density of the memory cells 10 can be increased. Moreover, the memory array 20 can be formed by repeating the same manufacturing process in the perpendicular direction. The manufacturing cost of the memory array 20 in the memory device 300 can be reduced.

This embodiment can be combined with the other embodiments as appropriate.

### Embodiment 4

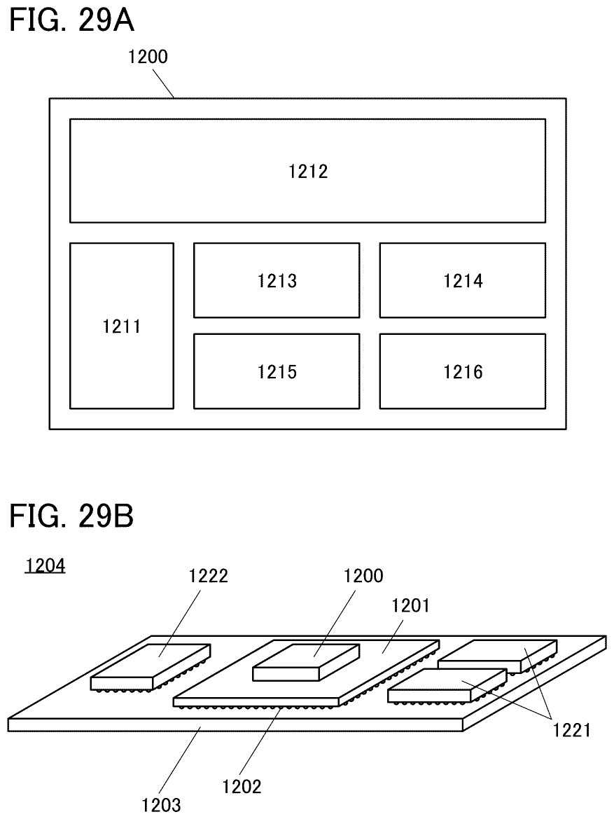

In this embodiment, an example of a chip on which the memory device of one embodiment of the present invention is mounted will be described with reference to FIG. 29.

A plurality of circuits (systems) are mounted on a chip 1200 illustrated in FIG. 29A and FIG. 29B. A technique for integrating a plurality of circuits (systems) into one chip is referred to as system on chip (SoC) in some cases.

As illustrated in FIG. 29A, the chip 1200 includes a CPU 1211, a GPU 1212, one or a plurality of analog arithmetic units 1213, one or a plurality of memory controllers 1214, one or a plurality of interfaces 1215, one or a plurality of network circuits 1216, and the like.

A bump (not illustrated) is provided on the chip 1200, and as illustrated in FIG. 29B, the chip 1200 is connected to a first surface of a package substrate 1201. A plurality of bumps 1202 are provided on a rear side of the first surface of the package substrate 1201, and the package substrate 1201 is connected to a motherboard 1203.

Memory devices such as a DRAM 1221 and a flash memory 1222 may be provided over the motherboard 1203. For example, the DOSRAM described in the above embodiment can be used as the DRAM 1221. This can make the DRAM 1221 have low power consumption, operate at high speed, and have a large capacity.

The CPU 1211 preferably includes a plurality of CPU cores. The GPU 1212 preferably includes a plurality of GPU cores. The CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a number of data and thus can be used for image processing or product-sum operation.

Since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a circuit for connecting a network such as a LAN (Local Area Network). The network circuit 1216 may also include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can execute a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with the other embodiments as appropriate.

### Embodiment 5

In this embodiment, electronic components, electronic devices, a large computer, space equipment, and a data center (also referred to as DC) in which the memory device described in the above embodiment can be used will be described. Electronic components, electronic devices, a large computer, space equipment, and a data center in which the memory device of one embodiment of the present invention is used are effective in improving performance, e.g., reducing power consumption.

### [Electronic Component]

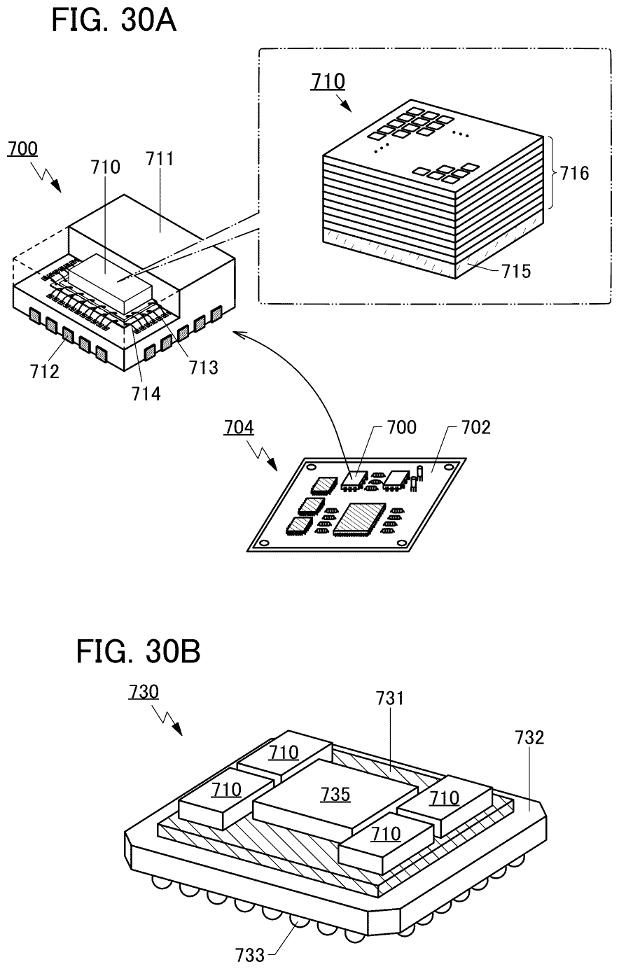

FIG. 30A is a perspective view of a substrate (a circuit board 704) on which an electronic component 700 is mounted. The electronic component 700 illustrated in FIG. 30A includes a semiconductor device 710 in a mold 711. Some components are omitted in FIG. 30A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase the bandwidth of the memory (also referred to as a memory bandwidth).

It is preferable that each of the plurality of memory cell arrays included in the memory layer 716 be formed using the memory device described in the above embodiment and be monolithically stacked. Monolithically stacking the plurality of memory cell arrays can improve one or both of the memory bandwidth and the memory access latency. Note that the bandwidth refers to the data transfer volume per unit time, and the access latency refers to a time from the access to the start of data transmission. In the case where the memory layer 716 is formed using Si transistors, it is difficult to obtain the monolithic stacked-layer structure as compared with the case where the memory layer 716 is formed using OS transistors. Thus, an OS transistor is superior to a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

FIG. 30B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 that includes the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are placed side by side on the interposer.

Meanwhile, in the case where a plurality of integrated circuits with different terminal pitches are electrically connected to each other using a silicon interposer and TSV, a space for the width of the terminal pitches and the like is needed. Thus, in the case where the size of the electronic component 730 is to be reduced, the width of the terminal pitches causes a problem; it sometimes becomes difficult to provide a large number of wirings for a wide memory bandwidth. For this reason, the above-described monolithic stacked-layer structure using OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 30B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by any of various mounting methods not limited to BGA and PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

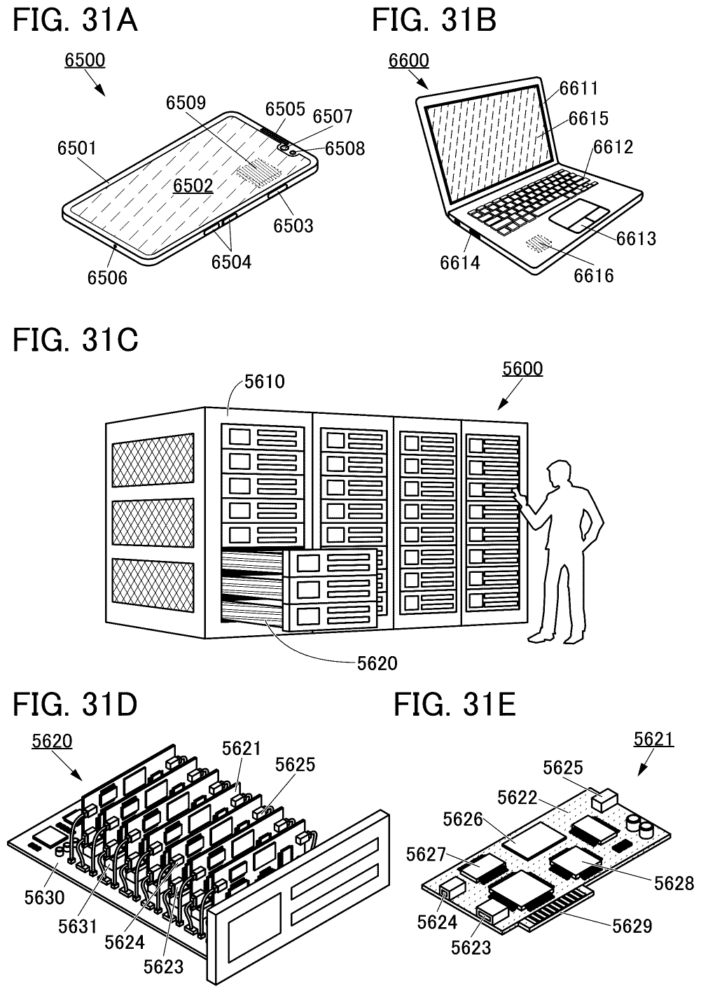

FIG. 31A is a perspective view of an electronic device 6500. The electronic device 6500 illustrated in FIG. 31A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The memory device of one embodiment of the present invention can be used for the control device 6509 and the like, for example.

An electronic device 6600 illustrated in FIG. 31B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The memory device of one embodiment of the present invention can be used for the control device 6616 and the like. Note that the memory device of one embodiment of the present invention is preferably used for the control device 6509 and the control device 6616, in which case power consumption can be reduced.

### [Large Computer]

FIG. 31C is a perspective view of a large computer 5600. In the large computer 5600 illustrated in FIG. 31C, a plurality of rack mount computers 5620 are stored in a rack 5610. Note that the large computer 5600 may be referred to as a supercomputer.

The computer 5620 can have a structure in a perspective view of FIG. 31D, for example. In FIG. 31D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 31E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 31E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. For another example, they can serve as an interface for outputting a signal calculated by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not shown) for inputting and outputting signals, and when the terminal is inserted in a socket (not shown) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The memory device of one embodiment of the present invention can be suitably used as space equipment such as equipment that processes and stores information.

The memory device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

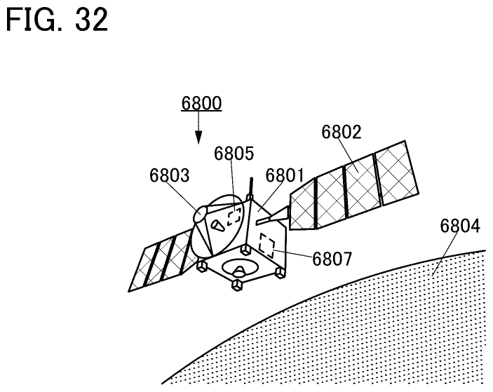

FIG. 32 illustrates an artificial satellite 6800 as an example of space equipment. The artificial satellite 6800 includes a body 6801, a solar panel 6802, an antenna 6803, a secondary battery 6805, and a control device 6807. FIG. 32 illustrates a planet 6804 in outer space, for example. Note that outer space refers to, for example, space at an altitude greater than or equal to 100 km, and outer space in this specification may also include thermosphere, mesosphere, and stratosphere.

Although not illustrated in FIG. 32, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is more than or equal to 100 times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for an operation of the artificial satellite 6800 is generated. However, for example, in the situation where the solar panel is not irradiated with sunlight or the amount of sunlight with which the solar panel is irradiated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed with one or more selected from a CPU, a GPU, and a memory device, for example. Note that the memory device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The memory device of one embodiment of the present invention can be suitably used for a device for space, such as a spacecraft, a space capsule, or a space probe, for example.

As described above, an OS transistor has excellent effects of achieving a wide memory bandwidth and being highly resistant to radiation as compared with a Si transistor.

### [Data Center]

The memory device of one embodiment of the present invention can be suitably used for a storage system in a data center, for example. Long-term management of data, such as guarantee of data immutability, is required for the data center. The long-term management of data needs an increase in building size owing to installation of storages and servers for storing an enormous amount of data, stable electric power for data retention, cooling equipment necessary for data retention, and the like.

With use of the memory device of one embodiment of the present invention for the storage system used in the data center, electric power required for data retention can be reduced and the size of a memory device retaining data can be downsized. Thus, downsizing of the storage system, downsizing of the power supply for retaining data, downscaling of the cooling equipment, and the like can be achieved, for example. This can reduce the space of the data center.

Since the memory device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the memory device of one embodiment of the present invention enables a data center that operates stably even in a high-temperature environment. Thus, the reliability of the data center can be increased.

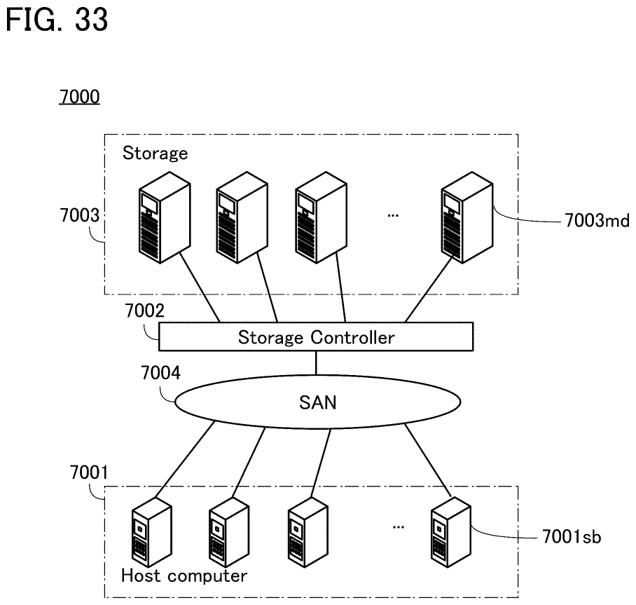

FIG. 33 illustrates a storage system that can be used in a data center. A storage system 7000 illustrated in FIG. 33 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated mode, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in the storage 7003. In the storage system, in order to solve the problem of low access speed of the storage 7003, a cache memory is normally provided in the storage 7003 to shorten data storage and output.

The above-described cache memory is used in the storage control circuit 7002 and the storage 7003. The data transmitted between the host 7001 and the storage 7003 is stored in the cache memory in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downsizing of the storage is possible by stacking memory cell arrays.

The use of the memory device of one embodiment of the present invention for one or more selected from an electronic component, an electronic device, a large computer, space equipment, and a data center will produce an effect of reducing power consumption. While the demand for energy is expected to increase with higher performance or higher integration of memory devices, the emission amount of greenhouse effect gases typified by carbon dioxide (CO₂) can be reduced with use of the memory device of one embodiment of the present invention. The memory device of one embodiment of the present invention can be effectively used as one of the global warming countermeasures because of its low power consumption.

The configuration, structure, method, or the like described in this embodiment can be used in combination with the configuration, structure, method, or the like described in the other embodiments and the like as appropriate.

### REFERENCE NUMERALS

ADDR: signal, BL [1]: wiring, BL [j]: wiring, BL [n]: wiring, BL_A: wiring, BL_B: wiring, BL: wiring, BW: signal, CE: signal, CLK: signal, EN_data: signal, GBL_A: wiring, GBL_B: wiring, GBL: wiring, GW: signal, MUX: selection signal, PL [1]: wiring, PL [i]: wiring, PL [m]: wiring, PL: wiring, RDA: signal, RE: control signal, VHH: wiring, VLL: wiring, VPC: intermediate potential, WAKE: signal, WDA: signal, WE: control signal, WL[1]: wiring, WL[i]: wiring, WL[m]: wiring, WL: wiring, 10[1,1]: memory cell, 10[i,j]: memory cell, 10[m,n]: memory cell, 10_A: memory cell, 10_B: memory cell, 10: memory cell, 11: transistor, 12: capacitor, 20[1]: memory array, 20[2]: memory array, 20[5]: memory array, 20[m]: memory array, 20: memory array, 21: driver circuit, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: functional layer, 51_A: functional circuit, 51_B: functional circuit, 51: functional circuit, 52_a: transistor, 52_b: transistor, 52: transistor, 53_a: transistor, 53_b: transistor, 53: transistor, 54_a: transistor, 54_b: transistor, 54: transistor, 55_a: transistor, 55_b: transistor, 55: transistor, 70[1]: repeating unit, 70: repeating unit, 71_A: precharge circuit, 71_B: precharge circuit, 72_A: switch circuit, 72_B: switch circuit, 73: write/read circuit, 81_1: transistor, 81_3: transistor, 81_4: transistor, 81_6: transistor, 82_1: transistor, 82_2: transistor, 82_3: transistor, 82_4: transistor, 83_A: switch, 83_B: switch, 83_C: switch, 83_D: switch, 100a: capacitor, 100aD: capacitor, 100aE: capacitor, 100b: capacitor, 100: capacitor, 154a: insulator, 154aD: insulator, 154aE: insulator, 154b: insulator, 154bD: insulator, 154bE: insulator, 154f: insulating film, 154: insulator, 160a: conductor, 160aD: conductor, 160aE: conductor, 160b: conductor, 160bD: conductor, 160bE: conductor, 160f: conductive film, 160: conductor, 200a: transistor, 200aD: transistor, 200aE: transistor, 200b: transistor, 200: transistor, 205a: conductor, 205b: conductor, 205: conductor, 207: conductor, 208: insulator, 209: conductor, 210: insulator, 212: insulator, 214: insulator, 215: insulator, 216: insulator, 221: insulator, 222: insulator, 223: insulator, 225f: insulating film, 225: insulator, 230a: oxide, 230aD: oxide, 230aE: oxide, 230af: oxide film, 230b: oxide, 230bD: oxide, 230bE: oxide, 230bf: oxide film, 230D: oxide, 230E: oxide, 230: oxide, 240a: conductor, 240aD: conductor, 240aE: conductor, 240b: conductor, 240bD: conductor, 240bE: conductor, 240: conductor, 241a: insulator, 241aD: insulator, 241aE: insulator, 241b: insulator, 241bD: insulator, 241bE: insulator, 241: insulator, 242a: conductor, 242aD: conductor, 242aE: conductor, 242b: conductor, 242bD: conductor, 242bE: conductor, 242f: conductive film, 242: conductor, 246: conductor, 250a: insulator, 250A: insulating film, 250b: insulator, 250c: insulator, 250d: insulator, 250: insulator, 260a: conductor, 260A: conductive film, 260b: conductor, 260B: conductive film, 260: conductor, 275: insulator, 280: insulator, 282: insulator, 283: insulator, 284: insulator, 300A: memory device, 300: memory device, 310: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: circuit board, 710: semiconductor device, 711: mold, 712: land, 713: electrode pad, 714: wire, 715: driver circuit layer, 716: memory layer, 730: electronic component, 731: interposer, 732: package substrate, 733: electrode, 735: semiconductor device, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 7000: storage system, 7001sb: server, 7001: host, 7002: storage control circuit, 7003md: memory device, 7003: storage

1. A memory device comprising:
a first insulator over a substrate;
an oxide semiconductor covering at least part of the first insulator;
a first conductor and a second conductor over the oxide semiconductor;
a second insulator over the first conductor;
a third insulator over the second conductor;
a third conductor over the second insulator;
a fourth conductor over the third insulator;
a fourth insulator placed over the third conductor and the fourth conductor and having a first opening overlapping with an area between the first conductor, the second insulator, and the third conductor and the second conductor, the third insulator, and the fourth conductor;
a fifth insulator placed in the first opening and over the first insulator and the oxide semiconductor;
a fifth conductor placed in the first opening and over the fifth insulator;
a sixth conductor placed in a second opening formed in the fourth insulator and being in contact with a top surface of the third conductor; and
a seventh conductor placed in a third opening formed in the fourth insulator, the third insulator, and the fourth conductor and being in contact with a top surface of the second conductor,
wherein a height of the first insulator is longer than a width of the first insulator in a cross-sectional view in a channel width direction, and
wherein a top surface of the first insulator is in contact with the fifth insulator in a region overlapping with neither the first conductor nor the second conductor.

2. The memory device according to claim 1,
wherein in the cross-sectional view in the channel width direction, the height of the first insulator is larger than or equal to 2 times and smaller than or equal to 20 times the width of the first insulator.

3. The memory device according to claim 1,
wherein the first conductor is configured to be one of a source electrode and a drain electrode of a transistor,
wherein the second conductor is configured to be the other of the source electrode and the drain electrode of the transistor, and
wherein the fifth conductor is configured to be a gate electrode of the transistor.

4. The memory device according to claim 3,
wherein the first conductor is configured to be one of a pair of electrodes of a capacitor,
wherein the third conductor is configured to be the other of the pair of electrodes of the capacitor, and
wherein the second insulator is configured to be a dielectric of the capacitor.

5. The memory device according to claim 4,
wherein the second insulator has a stacked structure in which a zirconium oxide film, an aluminum oxide film, and a zirconium oxide film are stacked in this order.

6. The memory device according to claim 4,
wherein a sixth insulator is placed between the seventh conductor and the fourth insulator, and
wherein the seventh conductor and the fourth conductor are insulated from each other by the sixth insulator.

7. The memory device according to claim 4,
wherein in the cross-sectional view in the channel width direction, the oxide semiconductor and the fifth conductor face each other with the fifth insulator therebetween along one side surface of the first insulator, and
wherein, in the cross-sectional view in the channel width direction, the oxide semiconductor and the fifth conductor face each other with the fifth insulator therebetween along the other side surface of the first insulator.

8. The memory device according to claim 4,
wherein, in the cross-sectional view in the channel width direction, the first conductor and the third conductor face each other with the second insulator therebetween along one side surface of the first insulator, and
wherein, in the cross-sectional view in the channel width direction, the first conductor and the third conductor face each other with the second insulator therebetween along the other side surface of the first insulator.

9. The memory device according to claim 1,
wherein the oxide semiconductor comprises any one or more selected from In, Ga, and Zn.
